(19) United States
(12) Patent Application Publication
(10) Pub. No.: US 2026/0188968 A1
(43) Pub. Date: Jul. 2, 2026

(54) OPTICAL MODULE

(71) Applicant: HISENSE BROADBAND MULTIMEDIA TECHNOLOGIES CO., LTD., Qingdao (CN)

(72) Inventors: Jianying ZHOU, Qingdao (CN); Xuejin YAN, Qingdao (CN); Jin HONG, Qingdao (CN)

(21) Appl. No.: 19/435,202

(22) Filed: Dec. 29, 2025

Related U.S. Application Data
(63) Continuation of application No. PCT/CN2024/114832, filed on Aug. 27, 2024.

(30) Foreign Application Priority Data
Mar. 18, 2024 (CN) 202410308715.7
Mar. 18, 2024 (CN) 202410308726.5
Mar. 18, 2024 (CN) 202410308800.3
May 31, 2024 (CN) 202410702563.9
May 31, 2024 (CN) 202421234608.6

(51) Int. Cl. H01S 5/00; H01S 5/10; H01S 5/12; H01S 5/343; H01S 5/40

(52) U.S. Cl. CPC H01S 5/0085; H01S 5/1014; H01S 5/12; H01S 5/34306; H01S 5/4025

(57) ABSTRACT

An optical module includes a hybrid integrated optical chip electrically connected to a circuit board and configured to modulate and generate an optical signal. The hybrid integrated optical chip includes: a Si-based platform including a substrate layer, a cladding layer located above the substrate layer and embedded with a first heating part and a second heating part, and a Si waveguide layer located between the substrate layer and the cladding layer; an InP light-emitting region disposed on the Si-based platform, with multiple lasers arranged side by side; an InP modulation region located on a light output path of the InP light-emitting region, where a plurality of InP modulators are arranged side by side in the InP modulation region; each InP modulator includes a first modulation waveguide and a second modulation waveguide optically coupled to the lasers and perform signal modulation to generate an optical signal.

This disclosure is a continuation application of International Application No. PCT/CN2024/114832, filed on Aug. 27, 2024, and claims priority to Chinese Patent Application No. 202410308800.3, filed with the China National Intellectual Property Administration on Mar. 18, 2024; priority to Chinese Patent Application No. 202410308726.5, filed with the China National Intellectual Property Administration on Mar. 18, 2024; priority to Chinese Patent Application No. 202410308715.7, filed with the China National Intellectual Property Administration on Mar. 18, 2024; priority to Chinese Patent Application No. 202410702563.9, filed with the China National Intellectual Property Administration on May 31, 2024; and priority to Chinese Patent Application No. 202421234608.6, filed with the China National Intellectual Property Administration on May 31, 2024. The entire contents of each of the aforementioned applications are incorporated herein by reference in their entirety.

### FIELD OF THE INVENTION

The present disclosure relates to the field of optical communication technology, and in particular, to an optical module.

### BACKGROUND OF THE INVENTION

With the development of new services and application models such as cloud computing, mobile Internet, and video, advances in optical communication technology have become increasingly important. In optical communication technology, the optical module, as one of the key devices in optical communication equipment, enables the conversion between optical and electrical signals. During the development of optical communication technology, the data transmission rate of optical modules is required to continuously increase.

### SUMMARY OF THE INVENTION

An embodiment of the present disclosure provides an optical module, including:
a circuit board; and
a hybrid integrated optical chip, electrically connected to the circuit board and configured to modulate and generate an optical signal, where the hybrid integrated optical chip includes:
a Si-based platform, including a substrate layer, a cladding layer located above the substrate layer, and a Si waveguide layer located between the substrate layer and the cladding layer, where a first heating part and a second heating part are embedded in the cladding layer;
an InP light-emitting region, disposed on the Si-based platform, where a plurality of lasers are arranged side by side in the InP light-emitting region; the lasers each include an active quantum well layer and a grating layer; the active quantum well layer is configured to output light; and the grating layer is disposed on a surface of the Si waveguide layer and configured to perform wavelength selection on the light output by the active quantum well layer; and
an InP modulation region, disposed on the Si-based platform and located on a light output path of the InP light-emitting region to receive light output by the lasers, where a plurality of InP modulators are arranged side by side in the InP modulation region and are linear electro-optic modulators; the InP modulators are correspondingly connected to the lasers; the InP modulators each include a first modulation waveguide and a second modulation waveguide, where each of the first modulation waveguide and the second modulation waveguide is optically coupled to each of the lasers to receive the light output by each of the lasers and performs signal modulation to generate an optical signal;
the first modulation waveguide is disposed adjacent to the first heating part, such that a temperature of the first modulation waveguide is regulated via the first heating part; and the second modulation waveguide is disposed adjacent to the second heating part, such that a temperature of the second modulation waveguide is regulated via the second heating part.

### BRIEF DESCRIPTION OF THE DRAWINGS

To more clearly illustrate the technical solution in the embodiments of the present disclosure, the accompanying drawings that need to be used in the description of the embodiments or the prior art will be briefly introduced below. Apparently, the accompanying drawings in the description below merely illustrate some embodiments of the present disclosure. Those of ordinary skill in the art may also derive other accompanying drawings from these accompanying drawings without creative efforts.

FIG. 1 is a partial architecture diagram of an optical communication system according to some embodiments of the present disclosure;

FIG. 2 is a partial structural diagram of a host computer according to some embodiments of the present disclosure;

FIG. 3 is a structural diagram of an optical module according to some embodiments of the present disclosure;

FIG. 4 is an exploded view of an optical module according to some embodiments of the present disclosure;

FIG. 5 is a schematic diagram of an internal structure of an optical module according to some embodiments of the present disclosure;

FIG. 6 is a schematic diagram of the optical signal modulation principle of a hybrid integrated optical chip according to some embodiments of the present disclosure;

FIG. 7 is a schematic diagram of an internal structure of a hybrid integrated optical chip according to some embodiments of the present disclosure;

FIG. 8 is a structural diagram of a Si-based platform in a hybrid integrated optical chip according to some embodiments of the present disclosure;

FIG. 9 is a first schematic diagram of a connection between a Si-based platform and an InP modulator according to some embodiments of the present disclosure;

FIG. 10 is a schematic diagram of optical path transmission in a hybrid integrated optical chip according to some embodiments of the present disclosure;

FIG. 11 is a second schematic diagram of a connection between a Si-based platform and an InP modulator according to some embodiments of the present disclosure;

FIG. 12 is a third schematic diagram of a connection between a Si-based platform and an InP modulator according to some embodiments of the present disclosure;

FIG. 13 is a schematic top view of a hybrid integrated optical chip according to some embodiments of the present disclosure;

FIG. 14 is a schematic diagram of a process for fabricating a hybrid integrated optical chip according to some embodiments of the present disclosure;

FIG. 15 is a first structural diagram of a hybrid integrated optical chip according to some embodiments of the present disclosure;

FIG. 16 is a second structural diagram of a hybrid integrated optical chip according to some embodiments of the present disclosure;

FIG. 17 is a partial cross-sectional view of a hybrid integrated optical chip according to some embodiments of the present disclosure;

FIG. 18 is a schematic diagram of optical path transmission in a hybrid integrated optical chip according to some embodiments of the present disclosure;

FIG. 19 is a schematic diagram of an external electrical connection of a hybrid integrated optical chip according to some embodiments of the present disclosure;

FIG. 20 is a schematic diagram of an internal structure of an optical chip according to some embodiments of the present disclosure;

FIG. 21 is a first top view of an optical modulator according to some embodiments of the present disclosure;

FIG. 22 is a structural diagram of a silicon waveguide according to some embodiments of the present disclosure;

FIG. 23 is a perspective view of an optical modulator according to some embodiments of the present disclosure;

FIG. 24 is a cross-sectional view of an optical modulator according to some embodiments of the present disclosure;

FIG. 25 is a second top view of an optical modulator according to some embodiments of the present disclosure;

FIG. 26 is a first layered structure diagram of an optical modulator according to some embodiments of the present disclosure;

FIG. 27 is a second layered structure diagram of an optical modulator according to some embodiments of the present disclosure;

FIG. 28 is a schematic diagram of an optical path of an optical modulator according to some embodiments of the present disclosure;

FIG. 29 is a schematic diagram of tapering of a silicon waveguide according to some embodiments of the present disclosure;

FIG. 30 is a structural diagram of an N-type InP layer according to some embodiments of the present disclosure;

FIG. 31 is a structural diagram of a quantum well layer according to some embodiments of the present disclosure;

FIG. 32 is a structural diagram of a P-type InP layer according to some embodiments of the present disclosure;

FIG. 33 is a schematic structural diagram of an optical chip with internally integrated modulators according to some embodiments of the present disclosure;

FIG. 34 is a schematic cross-sectional view of a laser according to some embodiments of the present disclosure;

FIG. 35 is a schematic partial view of a laser according to some embodiments of the present disclosure;

FIG. 36 is a schematic structural diagram of an optical modulator with internally integrated heaters according to some embodiments of the present disclosure;

FIG. 37 is a schematic layout diagram of a hybrid InP/Si photonic chip according to some embodiments;

FIG. 38 is a schematic partial view of a hybrid InP/Si photonic chip according to some embodiments;

FIG. 39 is a first cross-sectional view of a hybrid InP/Si photonic chip according to some embodiments;

FIG. 40 shows relationship curves between quantum well absorption coefficient and wavelength according to some embodiments;

FIG. 41 shows a width of a depletion region of a PIN junction at a reverse bias voltage of 0 V according to some embodiments;

FIG. 42 shows a width of a depletion region of a PIN junction at a reverse bias voltage of −3 V according to some embodiments;

FIG. 43 is a second cross-sectional view of a hybrid InP/Si photonic chip according to some embodiments;

FIG. 44 is a third cross-sectional view of a hybrid InP/Si photonic chip according to some embodiments;

FIG. 45 is a top view of a first silicon coupled waveguide layer according to some embodiments;

FIG. 46 is a top view of a second silicon coupled waveguide layer according to some embodiments;

FIG. 47 is a top view of a quantum well coupled waveguide layer according to some embodiments;

FIG. 48 is a top view of a p-InP coupled waveguide layer according to some embodiments;

FIG. 49 is an overlap diagram of a first silicon coupled waveguide layer, a second silicon coupled waveguide layer, a quantum well coupled waveguide layer, and a p-InP coupled waveguide layer according to some embodiments;

FIG. 50 is a combination diagram of a first silicon coupled waveguide layer, a second silicon coupled waveguide layer, a quantum well coupled waveguide layer, and a p-InP coupled waveguide layer according to some embodiments;

FIG. 51 is a distribution diagram of light in an optical coupler according to some embodiments;

FIG. 52 is a diagram of FDTD simulation results for an optical coupler according to some embodiments; and

FIG. 53 is a schematic growth diagram of an optical coupler according to some embodiments.

### DETAILED DESCRIPTION OF THE EMBODIMENTS

The following describes some embodiments of the present disclosure clearly and in detail with reference to the drawings. However, the described embodiments are some but not all of the embodiments of the present disclosure. All other embodiments obtained by those of ordinary skill in the art based on the embodiments provided in the present disclosure fall within the scope of protection of the present disclosure.

Unless otherwise required by the context, throughout the specification and the claims, the term “include/comprise” is interpreted as open and inclusive, meaning “including/comprising, but not limited to”; the terms “first” and “second” should not be construed as indicating or implying relative importance or indicating an upper limit on quantity; the term “a plurality of” means two or more; the term “connection” should be understood broadly, for example, “connection” may be a fixed connection, a detachable connection, or an integral connection, or may be directly connected, or indirectly connected via an intermediate medium; the term “adapted to” or “configured to” is open and inclusive language, and does not exclude devices adapted or configured to perform additional tasks or steps; and the terms “parallel,” “vertical,” “same,” “consistent,” “flush,” etc. are not limited to absolute mathematical theoretical relationships, but also include acceptable error ranges arising in practice, as well as differences formed due to manufacturing reasons based on the same design concept.

In optical communication technology, in order to establish information transmission between information processing devices, it is necessary to load information onto light and use the propagation of light to achieve the transmission of information. Here, the light loaded with information is an optical signal. When the optical signal is transmitted in the information transmission devices, the loss of optical power can be reduced, such that high-speed, long-distance, and low-cost information transmission can be achieved. The signals that the information processing devices are able to recognize and process are electrical signals. The information processing devices usually include optical network units (ONUs), gateways, routers, switches, mobile phones, computers, servers, tablet computers, televisions, etc. The information transmission devices usually include optical fibers and optical waveguides.

The optical modules enable the conversion between optical signals and electrical signals from the information processing devices and the information transmission devices. For example, at least one of an optical signal input or an optical signal output of an optical module is connected to an optical fiber, and at least one of an electrical signal input or an electrical signal output of the optical module is connected to an optical network unit; a first optical signal from the optical fiber is transmitted to the optical module, and the optical module converts the first optical signal into a first electrical signal and transmits the first electrical signal to the optical network unit; and a second electrical signal from the optical network unit is transmitted to the optical module, and the optical module converts the second electrical signal into a second optical signal and transmits the second optical signal to the optical fiber. Since information can be transmitted through electrical signals between a plurality of information processing devices, at least one information processing device in the plurality of information processing devices is required to be directly connected to the optical module, and all information processing devices are not required to be directly connected to the optical module. Here, the information processing device directly connected to the optical module is referred to as a host computer of the optical module. In addition, the optical signal input or the optical signal output of the optical module can be referred to as an optical port, and the electrical signal input or the electrical signal output of the optical module can be referred to as an electrical port.

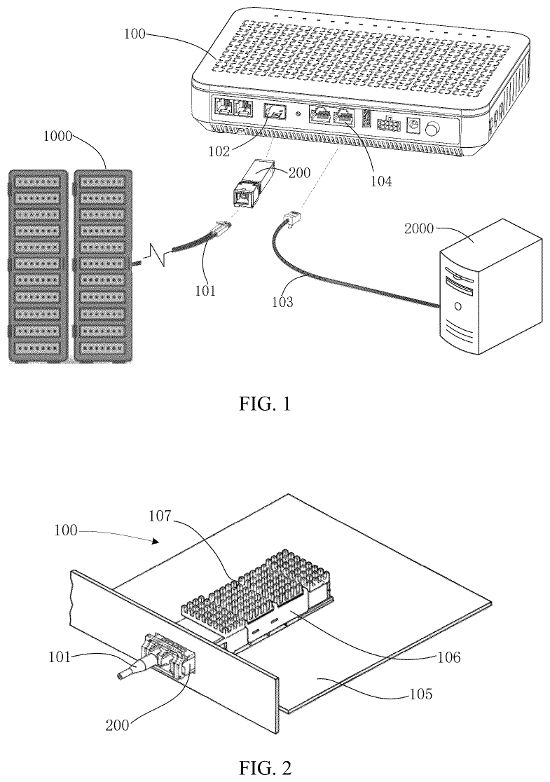

FIG. 1 is a partial structural diagram of an optical communication system according to some embodiments. As shown in FIG. 1, the optical communication system primarily includes a remote information processing device 1000, a local information processing device 2000, a host computer 100, an optical module 200, an optical fiber 101 and a network cable 103.

One end of the optical fiber 101 extends toward the remote information processing device 1000, and the other end of the optical fiber 101 is connected to the optical module 200 via an optical port of the optical module 200. An optical signal can undergo total reflection in the optical fiber 101, and the propagation of the optical signal in the total reflection direction can make it nearly maintain its original optical power. The optical signal undergoes multiple total reflections in the optical fiber 101 to transmit an optical signal from the remote information processing device 1000 to the optical module 200 or to transmit an optical signal from the optical module 200 to the remote information processing device 1000, thereby achieving long-distance and low-power-loss information transmission.

The optical communication system may include one or more optical fibers 101, and the optical fiber 101 is detachably or fixedly connected to the optical module 200. The host computer 100 is configured to provide a data signal to the optical module 200, receive a data signal from the optical module 200, or monitor or control a working state of the optical module 200.

The host computer 100 includes a generally cuboid-shaped housing and an optical module interface 102 disposed on the housing. The optical module interface 102 is configured to be connected to the optical module 200, enabling the host computer 100 to establish a one-way or two-way electrical signal connection with the optical module 200.

The host computer 100 further includes an external electrical interface that can be connected to an electrical signal network. For example, the external electrical interface includes a universal serial bus (USB) interface or a network cable interface 104. The network cable interface 104 is configured to be connected to the network cable 103, enabling the host computer 100 to establish a one-way or two-way electrical signal connection with the network cable 103. One end of the network cable 103 is connected to the local information processing device 2000, and the other end of the network cable 103 is connected to the host computer 100, thereby establishing an electrical signal connection between the local information processing device 2000 and the host computer 100 via the network cable 103. For example, a third electrical signal sent by the local information processing device 2000 is transmitted to the host computer 100 via the network cable 103. The host computer 100 generates a second electrical signal according to the third electrical signal. The second electrical signal from the host computer 100 is transmitted to the optical module 200. The optical module 200 converts the second electrical signal into a second optical signal and transmits the second optical signal to the optical fiber 101. The second optical signal is transmitted through the optical fiber 101 to the remote information processing device 1000. For example, a first optical signal from the remote information processing device 1000 is transmitted through the optical fiber 101. The first optical signal from the optical fiber 101 is transmitted to the optical module 200. The optical module 200 converts the first optical signal into a first electrical signal, and then the optical module 200 transmits the first electrical signal to the host computer 100. The host computer 100 generates a fourth electrical signal according to the first electrical signal and transmits the fourth electrical signal to the local information processing device 2000. It should be noted that the optical module is a tool to achieve the conversion between optical signals and electrical signals. In the conversion between the optical signals and the electrical signals, the information remains unchanged, and the encoding and decoding methods for the information may vary.

In addition to the optical network unit, the host computer 100 further includes an optical line terminal (OLT), an optical network terminal (ONT), or a data center server.

FIG. 2 is a partial structural diagram of a host computer according to some embodiments. To clearly show the connection relationship between the optical module 200 and the host computer 100, FIG. 2 shows only the structure of the host computer 100 related to the optical module 200. As shown in FIG. 2, the host computer 100 further includes a printed circuit board (PCB) 105 disposed in the housing, a cage 106 disposed on the surface of the PCB 105, a heat sink 107 disposed on the cage 106, and an electrical connector disposed inside the cage 106. The electrical connector is configured to be connected to the electrical port of the optical module 200. The heat sink 107 has protruding structures such as fins that enlarge the heat dissipation area.

The optical module 200 is inserted into the cage 106 of the host computer 100, and the optical module 200 is fixed by the cage 106. The heat generated by the optical module 200 is conducted to the cage 106 and then diffused through the heat sink 107. After the optical module 200 is inserted into the cage 106, the electrical port of the optical module 200 is connected to the electrical connector inside the cage 106, such that the optical module 200 establishes a two-way electrical signal connection with the host computer 100. In addition, the optical port of the optical module 200 is connected to the optical fiber 101, such that the optical module 200 establishes a two-way optical signal connection with the optical fiber 101.

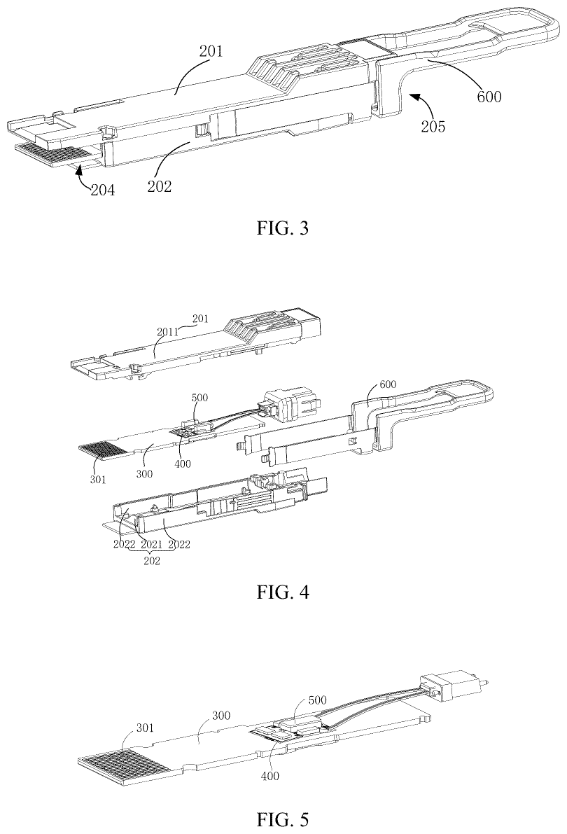

FIG. 3 is a structural diagram of an optical module according to some embodiments of the present disclosure. FIG. 4 is an exploded view of an optical module according to some embodiments of the present disclosure. As shown in FIG. 3 and FIG. 4, the optical module 200 includes a shell, and a circuit board 300, an optical chip 400 and a light source 500 that are disposed in the shell. By way of example, the optical chip 400 and the light source 500 are electrically connected to the circuit board 300 respectively, and a light output of the light source 500 is optically coupled to the optical chip 400. In some embodiments, the light output of the light source 500 is coupled to the optical chip 400 via the optical fiber.

The shell includes an upper shell 201 and a lower shell 202, where the upper shell 201 is covered on the lower shell 202 to form the shell with an opening 204 and an opening 205; and an outer contour of the shell is generally square.

In some embodiments, the lower shell 202 includes a bottom plate 2021 and two lower side plates 2022 located on two sides of the bottom plate 2021 and perpendicular to the bottom plate 2021; and the upper shell 201 includes a cover plate 2011, where the cover plate 2011 is covered on the two lower side plates 2022 of the lower shell 202 to form the shell.

In some embodiments, the lower shell 202 includes a bottom plate 2021 and two lower side plates 2022 located on two sides of the base plate 2021 and perpendicular to the bottom plate 2021; and the upper shell 201 includes a cover plate 2011 and two upper side plates located on two sides of the cover plate 2011 and perpendicular to the cover plate 2011, where the two upper side plates and the two lower side plates 2022 are combined to ensure that the upper shell 201 is covered on the lower shell 202.

The direction of a connecting line between the opening 204 and the opening 205 may be consistent with the length direction of the optical module 200 or may be inconsistent with the length direction of the optical module 200. For example, the opening 204 is located at an end of the optical module 200 (a left end of FIG. 3), and the opening 205 is also located at an end of the optical module 200 (a right end of FIG. 3). Alternatively, the opening 204 is located at the end of the optical module 200, and the opening 205 is located on the side of the optical module 200. The opening 204 is an electrical port. The gold finger 301 of the circuit board 300 extends out from the opening 204 and is inserted into the electrical connector of the host computer 100. The opening 205 is an optical port, which is configured to be connected to the external optical fiber 101 such that the optical fiber 101 is connected to the optical chip 400 in the optical module 200.

An assembly method of combining the upper shell 201 with the lower shell 202 is adopted, such that the circuit board 300, the optical chip, the light source, and other devices can be conveniently mounted in the shell, and these devices can be packaged by the upper shell 201 and the lower shell 202 for protection. In addition, when the circuit board 300, the optical chip 400, the light source, and other devices are assembled, positioning components, heat dissipation components, and electromagnetic shielding components for these devices can be deployed conveniently, thereby facilitating automated production.

In some embodiments, the upper shell 201 and the lower shell 202 are made of a metal material, which is conducive to electromagnetic shielding and heat dissipation.

In some embodiments, the optical module 200 further includes an unlocking component 600 located outside its shell. The unlocking component 600 is configured to achieve a fixed connection between the optical module 200 and the host computer, or to release the fixed connection between the optical module 200 and the host computer.

For example, the unlocking component 600 is located outside the two lower side plates 2022 of the lower shell 202, and includes an engaging component that matches the cage 106 of the host computer 100. When the optical module 200 is inserted into the cage 106, the optical module 200 is fixed in the cage 106 by the clamping component of the unlocking component 600; and when the unlocking component 600 is pulled, the clamping component of the unlocking component 600 moves accordingly, such that the connection relationship between the clamping component and the host computer is changed to release the fixation of the optical module 200 to the host computer, thereby pulling out the optical module 200 from the cage 106.

The circuit board 300 includes circuit traces, electronic components, and chips, where the electronic components and the chips are connected according to the circuit design through the circuit traces to implement the functions such as power supply, electrical signal transmission and grounding. The electronic components may include, for example, capacitors, resistors, transistors, and metal-oxide-semiconductor field-effect transistors (MOSFETs). The chips may include, for example, microcontroller units (MCUs), laser driving chips, transimpedance amplifiers (TIAs), limiting amplifiers (LAs), clock and data recovery (CDR) chips, power management chips, and digital signal processing (DSP) chips.

The circuit board 300 is generally a rigid circuit board. The rigid circuit board can also achieve the bearing effect because of its relatively hard material, for example, the rigid circuit board can smoothly carry the above-mentioned electronic components and chips. The rigid circuit board can also be inserted into the electrical connector in the cage 106 of the host computer 100.

The circuit board 300 further includes a gold finger 301 formed on an end surface thereof, where the gold finger 301 includes a plurality of independent pins. The circuit board 300 is inserted into the cage 106, and the gold finger 301 is connected to the electrical connector in the cage 106. The gold finger 301 may be arranged only on the surface of a side of the circuit board 300 (for example, the upper surface shown in FIG. 4), or may be arranged on the surfaces of the upper and lower sides of the circuit board 300 to provide more pins, so as to adapt to the occasion requiring a large number of pins. The gold finger 301 is configured to establish an electrical connection with the host computer to achieve power supply, grounding, two-wire inter-integrated circuit (I2C) signal transmission, data signal transmission, etc. Certainly, flexible circuit boards are also used in some optical modules. Flexible circuit boards are generally used in conjunction with rigid circuit boards as a supplement to rigid circuit boards.

FIG. 5 is a schematic diagram of an internal structure of an optical module according to some embodiments of the present disclosure. As shown in FIG. 5, in some embodiments, the light source 500 is disposed on a side edge of the optical chip 400, and the light source 500 emits light from a side surface and is coupled into the optical chip 400. The light source 500 is used as an external light source for the optical chip 400, and the light emitted by the light source 500 enters the optical chip 400. The light source 500 may be a laser box, in which a laser is packaged. The laser emits a laser beam. The light source 500 is configured to provide emitted laser light to the optical chip 400. Due to its excellent single-wavelength characteristics and superior wavelength tunability, the laser light becomes the preferred light source for optical modules and even optical fiber transmission, while other types of light such as LED light are generally not adopted in common optical communication systems. Even if such light sources are used in special optical communication systems, their characteristics and chip components differ significantly from those of the laser light, resulting in significant technical differences between optical modules using laser light and those using other light sources. Those skilled in the art will generally not consider that these two types of optical modules can give technical inspiration to each other.

When the light emitted by the light source 500 that does not carry data enters the optical chip 400, the optical chip 400 performs phase modulation on the light to load the electrical signal onto it, so as to obtain data-carrying light, namely, an optical emission signal, thereby achieving emission of the optical signal.

In some embodiments, the optical chip 400 is a silicon photonic chip, that is, the optical chip 400 is formed by packaging a silicon material. The silicon photonic chip includes a Mach-Zehnder modulator (MZM). A silicon photonic phase modulator is integrated into the MZ modulator and configured to modulate and demodulate the optical signal. Since the silicon photonic chip is easy to etch, other functional devices such as an optical splitter, an optical combiner, a frequency mixer, and an optical detector can be integrated therein, thereby achieving more functions. As an indirect bandgap semiconductor material, silicon does not have a linear electro-optic effect and only has a weak second-order electro-optic effect, resulting in a low modulation rate for the silicon photonic chip.

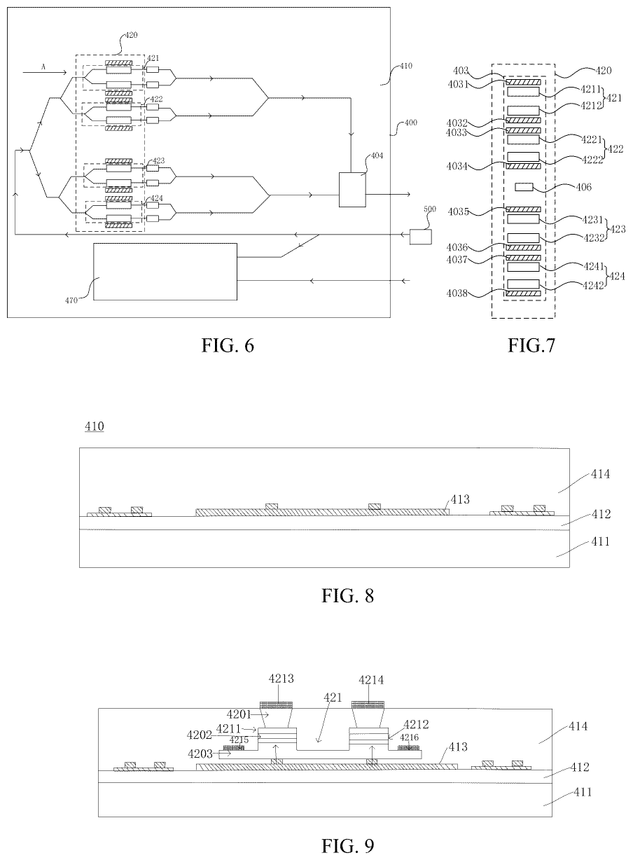

FIG. 6 is a schematic diagram of the optical signal modulation principle of a hybrid integrated optical chip according to some embodiments of the present disclosure. As shown in FIG. 6, the optical chip 400 is optically connected to the light source 500.

The optical chip 400 may be a monolithically integrated optical chip, such as a silicon photonic chip. Since the surface of the silicon photonic chip is easy to etch, other functional devices such as an optical splitter, an optical combiner, a frequency mixer, and an optical detector can be integrated therein, thereby achieving more functions. A silicon-based optical modulator is integrated into the silicon photonic chip. The silicon-based optical modulator uses a plasma dispersion effect of the silicon material to regulate and control an optical field, thereby achieving modulation of the optical signal. However, the basic characteristics of the silicon material result in defects such as low modulation efficiency, large capacitance, limited bandwidth, and high optical loss in the implementation of the optical modulator.

The optical chip 400 may be a hybrid integrated optical chip. The hybrid integrated optical chip refers to an optical chip in which a growth platform for the optical modulator is different from that for other functional devices such as an optical splitter, an optical combiner, a frequency mixer, and an optical detector. By way of example, since the silicon-based platform is easy to etch, it is used as the growth platform for the optical splitter, the optical combiner, the frequency mixer, the optical detector, and the like. Thus, the optical modulator integrated into the hybrid integrated photonic chip is a non-silicon-based optical modulator. The non-silicon-based optical modulator is, for example, an InP-based optical modulator. The InP-based optical modulator modulates the optical signal based on a quantum-confined Stark effect. By controlling the variation of the externally applied electric field, carrier changes are induced to change the refractive index, thereby modulating the optical signal.

It can be understood that when the optical chip 400 is a hybrid integrated photonic chip, the non-silicon-based optical modulator may also be a thin-film lithium niobate-based optical modulator or the like. The lithium niobate material has a strong electro-optic effect, with its refractive index varying linearly with an external driving voltage. This enables optical waves transmitted in mediums to have tunable information such as intensity and phase. Therefore, thin-film lithium niobate can be selected as the material for the optical modulator to achieve a higher modulation rate and the like. The thin-film lithium niobate material is relatively hard and difficult to etch, making it difficult to integrate a plurality of functional devices on its surface. In addition, the thin-film lithium niobate chip has a low optical loss.

Specifically, the above-mentioned hybrid integrated photonic chip may be a hybrid integrated III-V/Si photonic chip. In the hybrid integrated III-V/Si photonic chip, the growth material system for the optical modulator is a III-V semiconductor material, where the III-V material is a direct bandgap semiconductor material with a strong quantum-confined Stark effect. By controlling the variation of the externally applied electric field, carrier changes are induced to change the refractive index, thereby modulating the optical signal. The growth material system for the optical splitter, the optical combiner, the frequency mixer, the optical detector, and the like is a Si-based material. In some embodiments, the hybrid integrated III-V/Si photonic chip may be a hybrid integrated InP/Si photonic chip.

The following embodiments provide exemplary descriptions with the optical chip 400 as a hybrid integrated InP/Si photonic chip.

In the hybrid integrated InP/Si photonic chip, Si has extremely low luminous efficiency as an indirect bandgap semiconductor material. The light source of the above-mentioned hybrid integrated InP/Si photonic chip may be an external light source or an internally integrated light source. The III-V material is a direct bandgap semiconductor material with strong gain characteristics, and therefore has excellent light-emitting properties, such as an InP laser. Thus, the InP laser is integrated into the hybrid integrated InP/Si photonic chip.

In the present disclosure, an exemplary description is provided using the optical chip 400 as a hybrid integrated photonic chip and the non-silicon-based optical modulator integrated into the optical chip 400 as an InP-based optical modulator.

The optical chip 400 may include a Si-based platform 410. The optical splitter, the optical combiner, the frequency mixer, the optical detector, and the like may be formed on the surface of the Si-based platform 410. The Si-based platform 410 is grown from a Si material.

The optical chip 400 may include an InP modulation region 420. The InP modulation region 420 is grown from an InP material. An InP modulator is disposed inside the InP modulation region 420.

The InP modulation region 420 is located in the Si-based platform 410, such that the Si-based platform 410 wraps around the InP modulation region 420 from the front, back, left, right, and bottom directions.

The laser light generated by the light source 500 is coupled into the optical chip 400. The laser light is split into a first light beam and a second light beam by the optical splitter integrated into the optical chip 400. The first light beam serves as a light source for the optical emission signal and is transmitted to the InP modulation region 420 for modulating the optical signal. In some embodiments, the first light beam is split by a polarization beam splitter into two beams of light with different polarization directions, such as TE-polarized light and TM-polarized light. The InP modulation region 420 performs signal modulation on the TE-polarized light and the TM-polarized light to generate a first modulated optical signal and a second modulated optical signal respectively. The first modulated optical signal and the second modulated optical signal are combined by the optical combiner 404 to generate the optical emission signal. The optical emission signal is coupled out from the optical chip 400 to the outside. The second light beam serves as local oscillator light and is coupled to an optical demodulation part 470. The external optical signal is also coupled to the optical demodulation part 470. The second light beam and the external optical signal undergo coherent demodulation in the optical demodulation part 470 to obtain corresponding electrical signals.

In some embodiments, the InP modulators disposed in the InP modulation region 420 include a first InP modulator 421, a second InP modulator 422, a third InP modulator 423, and a fourth InP modulator 424, respectively.

The first InP modulator 421, the second InP modulator 422, the third InP modulator 423, and the fourth InP modulator 424 are arranged side by side in the InP modulation region 420. Based on the characteristics of InP, the InP modulators have high modulation efficiency and modulation rate.

The first light beam is split by the polarization beam splitter into two beams of light with different polarization directions, such as TE-polarized light and TM-polarized light. The first InP modulator 421 and the second InP modulator 422 perform I-modulation and Q-modulation on the TE-polarized light, respectively, thereby performing high-order IQ modulation on the TE-polarized light to generate the first modulated optical signal. The third InP modulator 423 and the fourth InP modulator 424 perform I-modulation and Q-modulation on the TM-polarized light, respectively, thereby performing high-order IQ modulation on the TM-polarized light to generate the second modulated optical signal. The first modulated optical signal and the second modulated optical signal are combined by the optical combiner 404 to generate the optical emission signal. Certainly, the first InP modulator 421 and the second InP modulator 422 may perform I-modulation and Q-modulation on the TM-polarized light, respectively; and the third InP modulator 423 and the fourth InP modulator 424 may perform I-modulation and Q-modulation on the TE-polarized light, respectively. There is no specific limitation.

In the present disclosure, the optical chip 400 is a hybrid integrated optical chip that achieves hybrid integration of the Si material and the InP material. It utilizes the InP material to provide high-speed modulation and the Si material to provide a highly integrated silicon photonic circuit, enabling the optical chip 400 to have the high-speed modulation characteristics of the InP material, meet the requirement for high-baud-rate modulation, and give full play to the characteristics of the Si material and the InP material.

In some embodiments, the hybrid integrated photonic chip undergoes temperature regulation via a thermoelectric cooler (TEC) to maintain its operating temperature within a certain range. However, temperature control using the TEC results in high power consumption. In the present disclosure, since the InP modulators are more sensitive to temperature than the Si-based material, temperature regulation is performed on the local region, namely the InP modulators of the optical chip, rather than the entire optical chip, thereby enabling the optical chip to operate within a certain temperature range while reducing power consumption.

In some embodiments, the hybrid integrated photonic chip is fabricated by bonding the InP modulation region 420 formed from the InP material with the Si-based platform 410 formed from the Si material, processing the InP modulators on the bonded InP modulation region 420, and forming the silicon photonic circuit on the bonded Si-based platform. However, a significant coefficient of thermal expansion mismatch tends to exist between the InP modulation region 420 and the Si-based platform 410 formed from the Si material. By way of example, the coefficient of thermal expansion of the InP material is greater than that of the Si material, which leads to problems such as a significant interfacial thermal stress during bonding. Such thermal stress may cause defects and dislocations during bonding, and even the significant thermal stress may result in bonding failure between the InP modulation region 420 and the Si-based platform 410. In the present disclosure, by regulating the temperature of the InP modulator, the thermal stress during bonding between the InP modulation region and the Si-based platform can be reduced, thereby improving the reliability and modulation rate of the InP modulator and meeting the requirements of high-rate optical modules.

In the present disclosure, heating parts are embedded inside the optical chip. Since the InP material is more sensitive to temperature than the Si material, temperature regulation is performed on the local region (especially the InP modulation region 420) of the optical chip via the heating parts to regulate the temperature of the entire region of the optical chip, thereby reducing power consumption.

In the present disclosure, the InP modulator in the InP modulation region 420 may be an InP-based Mach-Zehnder (MZ) modulator. Electro-absorption modulators (EAMs) and electro-absorption modulated lasers (EMLs) utilize the quantum-confined Stark effect of semiconductors to alter the absorption characteristics of the device by applying an external voltage, thereby increasing its absorption of modulated light and modulating the output light intensity. Unlike the intensity modulation principle of the EAM and the EML, the MZ modulator modulates the phase by changing the refractive index of the material, and then utilizes the principles of constructive and destructive interference of light to indirectly modulate the light intensity. The modulation principle determines the characteristics of the modulator. Compared with the EAM and the EML, the MZ modulator has a higher modulation rate, enables longer-distance transmission, and has a higher extinction ratio.

FIG. 7 is a schematic diagram of an internal structure of a hybrid integrated optical chip according to some embodiments of the present disclosure. As shown in FIG. 7, the optical chip 400 may include a heating region 403. The InP modulation region 420 wraps around the heating region 403.

Since the InP material is more sensitive to temperature than the Si material, the Si-based platform 410 is insensitive to temperature. Therefore, in the present disclosure, temperature regulation is performed on the local region, namely the InP modulation region 420 of the optical chip, rather than the entire optical chip, thereby enabling the entire optical chip to operate within a certain temperature range while reducing power consumption.

In the present disclosure, since the InP material is more sensitive to temperature than the Si material, temperature regulation is performed on the local region of the optical chip to regulate the temperature of the entire region of the optical chip, thereby reducing power consumption.

Temperature regulation is performed on the InP modulation region 420 rather than the entire optical chip via the heating region 403, thereby enabling the optical chip to operate within a certain temperature range.

In some embodiments, the heating region 403 is formed in the Si-based platform 410. The heating region 403 includes various heating parts.

In the present disclosure, the heating parts are embedded inside the Si-based platform 410, and the InP modulators are disposed inside the Si-based platform 410. The heat generated by the heating parts heats the Si-based platform 410, which in turn heats the InP modulators, thereby regulating the temperature of the InP modulation region 420 and further regulating the temperature of the entire optical chip.

Temperature regulation is performed on the local region, namely the InP modulators of the optical chip via the heating parts, thereby enabling the optical chip to operate within a certain temperature range in a low-power mode. In addition, by regulating the temperature of the InP modulator, the thermal stress during bonding between the InP modulation region and the Si-based platform can be reduced, thereby improving the reliability and modulation rate of the InP modulator.

One InP modulator may include two modulation waveguides, namely a first modulation waveguide and a second modulation waveguide. The first modulation waveguide and the second modulation waveguide are InP-based modulation waveguides.

The first modulation waveguide and the second modulation waveguide are two modulation arms of the InP modulator. By controlling the variation of the externally applied electric field, the phase difference between the first modulation waveguide and the second modulation waveguide can be altered. The output light intensity varies with the phase difference, that is, the output light intensity is modulated by a modulated electrical signal. The modulated electrical signal is modulated into the output light intensity of the modulated optical signal, thereby achieving modulation.

Correspondingly, the heating part includes a first heating part and a second heating part, where the first heating part regulates the temperature of the first modulation waveguide, and the second heating part regulates the temperature of the second modulation waveguide. The following naming of the structures of the plurality of InP modulators and the composition of the heating region 403 is merely for distinction.

The first InP modulator 421 may include a first modulation waveguide 4211 and a second modulation waveguide 4212. The second InP modulator 422 may include a third modulation waveguide 4221 and a fourth modulation waveguide 4222. The third InP modulator 423 may include a fifth modulation waveguide 4231 and a sixth modulation waveguide 4232. The fourth InP modulator 424 may include a seventh modulation waveguide 4241 and an eighth modulation waveguide 4242.

Correspondingly, the heating region 403 includes a first heating part 4031 and a second heating part 4032. The heating region 403 includes a third heating part 4033 and a fourth heating part 4034. The heating region 403 includes a fifth heating part 4035 and a sixth heating part 4036. The heating region 403 includes a seventh heating part 4037 and an eighth heating part 4038.

The above-mentioned heating parts form the heating region 403. The above-mentioned heating parts are all integrated into the optical chip 400, that is, the heating region 403 is integrated into the optical chip 400.

The first heating part 4031 is disposed adjacent to the first modulation waveguide 4211. The temperature of the first modulation waveguide 4211 is regulated by the first heating part 4031 to regulate the temperature of the local region of the optical chip, thereby maintaining the entire region of the optical chip within a certain temperature range. The second heating part 4032 is disposed adjacent to the second modulation waveguide 4212. The temperature of the second modulation waveguide 4212 is regulated by the second heating part 4032 to regulate the temperature of the local region of the optical chip, thereby maintaining the entire region of the optical chip within a certain temperature range.

The third heating part 4033 is disposed adjacent to the third modulation waveguide 4221. The temperature of the third modulation waveguide 4221 is regulated by the third heating part 4033 to regulate the temperature of the local region of the optical chip, thereby maintaining the entire region of the optical chip within a certain temperature range. The fourth heating part 4034 is disposed adjacent to the fourth modulation waveguide 4222. The temperature of the fourth modulation waveguide 4222 is regulated by the fourth heating part 4034 to regulate the temperature of the local region of the optical chip, thereby maintaining the entire region of the optical chip within a certain temperature range.

The fifth heating part 4035 is disposed adjacent to the fifth modulation waveguide 4231. The temperature of the fifth modulation waveguide 4231 is regulated by the fifth heating part 4035 to regulate the temperature of the local region of the optical chip, thereby maintaining the entire region of the optical chip within a certain temperature range. The sixth heating part 4036 is disposed adjacent to the sixth modulation waveguide 4232. The temperature of the sixth modulation waveguide 4232 is regulated by the sixth heating part 4036 to regulate the temperature of the local region of the optical chip, thereby maintaining the entire region of the optical chip within a certain temperature range.

The seventh heating part 4037 is disposed adjacent to the seventh modulation waveguide 4241. The temperature of the seventh modulation waveguide 4241 is regulated by the seventh heating part 4037 to regulate the temperature of the local region of the optical chip, thereby maintaining the entire region of the optical chip within a certain temperature range. The eighth heating part 4038 is disposed adjacent to the eighth modulation waveguide 4242. The temperature of the eighth modulation waveguide 4242 is regulated by the eighth heating part 4038 to regulate the temperature of the local region of the optical chip, thereby maintaining the entire region of the optical chip within a certain temperature range.

FIG. 8 is a structural diagram of a Si-based platform in a hybrid integrated optical chip according to some embodiments of the present disclosure. As shown in FIG. 8, the first heating part 4031 and the second heating part 4032 are disposed on the surface of a cladding layer 414, and the first modulation waveguide 4211 and the second modulation waveguide 4212 are embedded in the cladding layer 414. Thus, the heat generated by the first heating part 4031 and the second heating part 4032 heats the cladding layer 414, which in turn heats the first modulation waveguide 4211 and the second modulation waveguide 4212, thereby regulating the temperature of the first InP modulator 421 and further regulating the temperature of the entire optical chip.

Similarly, other heating parts perform temperature regulation and control on the InP modulators based on the same principle.

By way of example, the first modulation waveguide 4211 and the second modulation waveguide 4212 are respectively disposed between the first heating part 4031 and the second heating part 4032. The first heating part 4031 is disposed on one side of the first modulation waveguide 4211, and the second heating part 4032 is disposed on one side of the second modulation waveguide 4212.

By way of example, the third modulation waveguide 4221 and the fourth modulation waveguide 4222 are respectively disposed between the third heating part 4033 and the fourth heating part 4034. The third heating part 4033 is disposed on one side of the third modulation waveguide 4221, and the fourth heating part 4034 is disposed on one side of the fourth modulation waveguide 4222.

By way of example, the fifth modulation waveguide 4231 and the sixth modulation waveguide 4232 are respectively disposed between the fifth heating part 4035 and the sixth heating part 4036. The fifth heating part 4035 is disposed on one side of the fifth modulation waveguide 4231, and the sixth heating part 4036 is disposed on one side of the sixth modulation waveguide 4232.

By way of example, the seventh modulation waveguide 4241 and the eighth modulation waveguide 4242 are respectively disposed between the seventh heating part 4037 and the eighth heating part 4038. The seventh heating part 4037 is disposed on one side of the seventh modulation waveguide 4241, and the eighth heating part 4038 is disposed on one side of the eighth modulation waveguide 4242.

The second heating part 4032 is disposed adjacent to the third heating part 4033. The sixth heating part 4036 is disposed adjacent to the seventh heating part 4037.

In the present disclosure, the heating parts are embedded in the Si-based platform 410. Temperature regulation is performed on the local region, namely the InP modulation region 420 of the optical chip via the heating parts, thereby enabling the entire optical chip to operate within a certain temperature range in a low-power mode. In addition, by regulating the temperature of the InP modulator, the thermal stress during bonding between the InP modulation region and the Si-based platform can be reduced, thereby improving the reliability and modulation rate of the InP modulator and meeting the requirements of high-rate optical modules.

In the present disclosure, a temperature sensor 406 is embedded in the Si-based platform 410 to monitor the temperature of the InP modulation region 420 in real time. The temperature of the InP modulation region 420 is collected in real time via the temperature sensor 406, thereby enabling real-time temperature regulation of the InP modulation region 420 and achieving closed-loop control of temperature regulation. By way of example, the temperature sensor 406 is disposed between the fourth heating part 4034 and the fifth heating part 4035. Certainly, the temperature sensor 406 is typically disposed in an intermediate region of the plurality of heating parts to improve the detection accuracy of the temperature sensor 406.

In the present disclosure, since the InP material is more sensitive to temperature than the Si material, temperature regulation is performed on the local region of the optical chip to regulate the temperature of the entire region of the optical chip, thereby reducing power consumption.

As shown in FIG. 8, the Si-based platform 410 includes various layered structures. The Si-based platform 410 may include a substrate layer 411. By way of example, the substrate layer 411 is epitaxially grown from a Si material. The Si-based platform 410 may include an intermediate layer 412. By way of example, the intermediate layer 412 is epitaxially grown from a SiO₂ material. The Si-based platform 410 may include an optical waveguide layer 413. By way of example, the optical waveguide layer 413 is a silicon waveguide layer. Since the silicon waveguide has low-loss transmission characteristics, the silicon waveguide layer is used as the optical waveguide layer 413. The optical waveguide layer 413 is formed between the intermediate layer 412 and the cladding layer 414.

In some embodiments, the optical waveguide layer 413 includes a Si input waveguide. The Si input waveguide is used to transmit light to the InP modulator. The cross section of the Si input waveguide has an “inverted T”-shaped structure, that is, the dimension of the top of the Si input waveguide is smaller than that of the bottom of the Si input waveguide, which facilitates coupling of light input through the Si input waveguide into the InP modulator.

The Si-based platform 410 may include a cladding layer 414. By way of example, the cladding layer 414 is epitaxially grown from a SiO₂ material.

The substrate layer 411, the intermediate layer 412, the optical waveguide layer 413, and the cladding layer 414 are sequentially arranged from bottom to top.

FIG. 9 is a first schematic diagram of a connection between a Si-based platform and an InP modulator according to some embodiments of the present disclosure. FIG. 9 shows a cross-sectional structure corresponding to a first modulator 421, obtained by sectioning in a direction A indicated in FIG. 6. As shown in FIG. 9, the InP modulation region 420 is formed in the Si-based platform 410. Various InP modulators are arranged side by side in the InP modulation region 420.

The following provides an exemplary description using the first InP modulator 421 as an example.

The first InP modulator 421 is coupled to the optical waveguide layer 413. By way of example, the first InP modulator 421 is disposed above the optical waveguide layer 413. The optical waveguide layer 413 couples and transmits light that does not carry information to the first InP modulator 421.

The first InP modulator 421 may include a first modulation waveguide 4211 and a second modulation waveguide 4212.

The first modulation waveguide 4211 includes, from top to bottom, a p-InP layer 4201, an active quantum well layer 4202, and an n-InP layer 4203. The p-InP layer 4201 and the n-InP layer 4203 form a PN junction. The second modulation waveguide 4212 includes the same structure.

The first InP modulator 421 may include a first P-electrode metal layer 4213 and a second P-electrode metal layer 4214. The top of the first P-electrode metal layer 4213 and the top of the second P-electrode metal layer 4214 are disposed opposite to each other with a gap therebetween.

The first P-electrode metal layer 4213 is disposed on the surface of the cladding layer 414. The second P-electrode metal layer 4214 is disposed on the surface of the cladding layer 414. The first P-electrode metal layer 4213 is electrically connected to the first modulation waveguide 4211. By way of example, the first P-electrode metal layer 4213 is disposed above the first modulation waveguide 4211.

The second P-electrode metal layer 4214 is electrically connected to the second modulation waveguide 4212. By way of example, the second P-electrode metal layer 4214 is disposed above the second modulation waveguide 4212.

The first InP modulator 421 may include a first N-electrode metal layer 4215 and a second N-electrode metal layer 4216. By way of example, the first N-electrode metal layer 4215 and the second N-electrode metal layer 4216 may be respectively disposed on the surface of the n-InP layer 4203.

The first P-electrode metal layer 4213 and the first N-electrode metal layer 4215 are arranged in pairs and disposed opposite to each other to form a PN junction.

The second P-electrode metal layer 4214 and the second N-electrode metal layer 4216 are arranged in pairs and disposed opposite to each other to form a PN junction.

In the present disclosure, the InP modulator is an InP-based MZ modulator. The MZ modulator is a modulator based on an electro-optic effect. The electro-optic effect refers to the change in the refractive index of a material induced by an externally applied electric field.

Due to the extremely low electrical conductivity of the active quantum well layer 4202, most of the applied electric field is concentrated in the active quantum well layer 4202, and light is also transmitted to the active quantum well layer 4202, thereby enabling interaction between the transmitted optical signals.

The first P-electrode metal layer 4213 and the second P-electrode metal layer 4214 respectively provide P-type carriers, while the first N-electrode metal layer 4215 and the second N-electrode metal layer 4216 respectively provide N-type carriers. The P-type carriers are transmitted downward to the active quantum well layer 4202. The N-type carriers are transmitted upward to the active quantum well layer 4202. By way of example, the P-type carriers are holes, and the N-type carriers are electrons.

The electro-optic effect of the material of the active quantum well layer 4202 is utilized to induce carrier changes by controlling the variation of the externally applied electric field, thereby changing the refractive index of the active quantum well layer 4202. The amount of change in the refractive index of the active quantum well layer 4202 is directly proportional to the amount of phase change between the first modulation waveguide 4211 and the second modulation waveguide 4212. Thus, when the refractive index of the active quantum well layer 4202 changes, the phase of the transmitted light can be altered to achieve modulation.

The first P-electrode metal layer 4213 and the second P-electrode metal layer 4214 are respectively loaded with modulated electrical signals. By controlling the variation of the externally applied electric field, carrier changes are induced to change the refractive index of the active quantum well layer and cause a phase difference between the first modulation waveguide 4211 and the second modulation waveguide 4212. The output light intensity varies with the phase difference, that is, the output light intensity is modulated by a modulated electrical signal. The modulated electrical signal is modulated into the output light intensity of the modulated optical signal, thereby achieving modulation.

In some embodiments, the optical waveguide layer 413 includes a Si output waveguide. The modulated optical signal formed after modulation by the first modulation waveguide 4211 and the second modulation waveguide 4212 is coupled into the Si output waveguide for transmission via the Si output waveguide.

There is a gap between a Si input waveguide and a Si output waveguide, above which the first InP modulator is disposed. The Si input waveguide transmits light upward to the first modulation waveguide 4211 and the second modulation waveguide 4212. The modulated optical signal is transmitted downward to the Si output waveguide and output via the Si output waveguide.

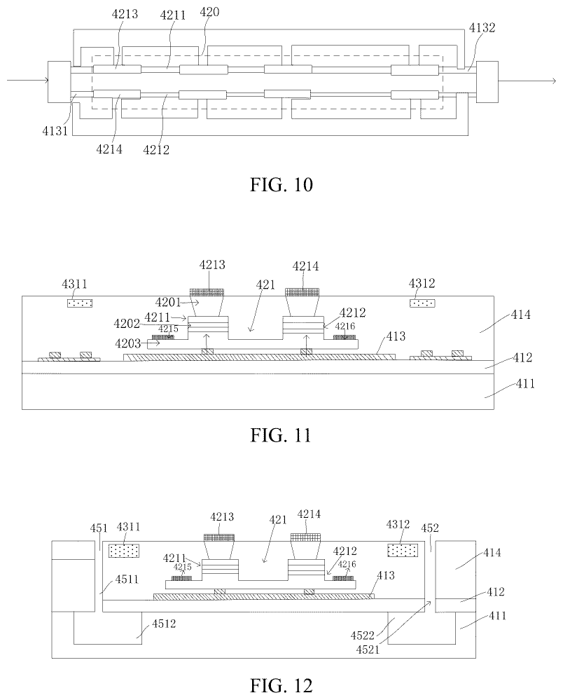

FIG. 10 is a schematic diagram of optical path transmission in a hybrid integrated optical chip according to some embodiments of the present disclosure. FIG. 10 is a schematic diagram of optical path transmission corresponding to one InP modulator. As shown in FIG. 10, the optical waveguide layer 413 includes a Si input waveguide 4131 and a Si output waveguide 4132, which are located at two opposite ends of the InP modulation region 420.

Light emitted by the light source is split by the optical splitter into two beams of light with different polarization directions. The two beams of light respectively enter the first modulation waveguide 4211 and the second modulation waveguide 4212 for InP modulation along the Si input waveguide 4131, and are respectively connected to the corresponding active quantum well layers. The modulated electrical signals to be loaded are transmitted to the first modulation waveguide 4211 and the second modulation waveguide 4212 via the first P-electrode metal layer 4213 and the second P-electrode metal layer 4214, and reach the corresponding active quantum well layers.

A phase difference is generated between the first modulation waveguide 4211 and the second modulation waveguide 4212. The output light intensity varies with the phase difference, that is, the output light intensity is modulated by a modulated electrical signal. The modulated electrical signal is modulated into the output light intensity of the modulated optical signal, thereby achieving modulation. The optical signal is generated by modulation and output to the outside along the Si output waveguide 4132.

The first P-electrode metal layer 4213 on the first modulation waveguide 4211 and the second P-electrode metal layer 4214 on the second modulation waveguide 4212 are paired electrodes. A plurality of first P-electrode metal layers 4213 are disposed on the first modulation waveguide 4211, and a plurality of second P-electrode metal layers 4214 are disposed on the second modulation waveguide 4212, such that multiple pairs of first P-electrode metal layers exist on one InP modulator. Light enters and exits the InP modulation region 420 respectively via the Si input waveguide 4131 and the Si output waveguide 4132.

When transmitted in the InP modulation region 420, light is transmitted and modulated via the InP-based waveguides, namely the first modulation waveguide 4211 and the second modulation waveguide 4212.

FIG. 11 is a second schematic diagram of a connection between a Si-based platform and an InP modulator according to some embodiments of the present disclosure. FIG. 11 shows a cross-sectional structure corresponding to a first modulator 421, obtained by sectioning in a direction A indicated in FIG. 6. As shown in FIG. 11, the Si-based platform 410 sequentially includes, from bottom to top: a substrate layer 411, an intermediate layer 412, an optical waveguide layer 413, and a cladding layer 414.

In the present disclosure, various heating parts are embedded in the Si-based platform 410, that is, the heating parts are disposed in an embedded manner. Temperature regulation is performed on the local region, namely the InP modulation region 420 of the optical chip via the heating parts, thereby enabling the entire optical chip to operate within a certain temperature range in a low-power mode. In addition, by regulating the temperature of the InP modulator, the thermal stress during bonding between the InP modulation region and the Si-based platform can be reduced, thereby improving the reliability and modulation rate of the InP modulator and meeting the requirements of high-rate optical modules.

Taking the first InP modulator 421 as an example, the first InP modulator 421 may include a first modulation waveguide 4211 and a second modulation waveguide 4212, which will be described by way of example below.

The first heating part 4031 is disposed on one side of the first modulation waveguide 4211, such that the temperature of the first modulation waveguide 4211 is regulated by the first heating part 4031 to regulate the temperature of the local region of the optical chip, thereby maintaining the entire region of the optical chip within a certain temperature range.

The second heating part 4032 is disposed on one side of the second modulation waveguide 4212, such that the temperature of the second modulation waveguide 4212 is regulated by the second heating part 4032 to regulate the temperature of the local region of the optical chip, thereby maintaining the entire region of the optical chip within a certain temperature range.

In some embodiments, the first heating part 4031, the second heating part 4032, and the like may be in the form of heating resistors. The heating resistors are used to heat the first modulation waveguide 4211 and the second modulation waveguide 4212, respectively.

In the present disclosure, the first heating part 4031 and the second heating part 4032 are embedded in the cladding layer 414.

In the present disclosure, a metal via hole is formed in the position of the cladding layer 414 where the first heating part 4031 and the second heating part 4032 are located, to achieve a power supply connection between the first heating part 4031 and the second heating part 4032. The metal via hole is connected to a power supply metal region of the optical chip, thereby heating the first heating part 4031 and the second heating part 4032.

FIG. 12 is a third schematic diagram of a connection between a Si-based platform and an InP modulator according to some embodiments of the present disclosure. FIG. 12 shows a cross-sectional structure corresponding to a first modulator 421, obtained by sectioning in a direction A indicated in FIG. 6. As shown in FIG. 12, the Si-based platform 410 sequentially includes, from bottom to top: a substrate layer 411, an intermediate layer 412, an optical waveguide layer 413, and a cladding layer 414.

The first heating part 4031 and the second heating part 4032 are disposed on the surface of the cladding layer 414. The cladding layer 414 is epitaxially grown from a SiO₂ material, and the substrate layer 411 is epitaxially grown from a Si material. The thermal conductivity of the Si material is greater than that of the SiO₂ material, that is, the thermal conductivity of the substrate layer 411 is greater than that of the cladding layer 414. Thus, the heat generated by the first heating part 4031 and the second heating part 4032 will be conducted downward to the substrate layer 411, thereby reducing the efficiency of temperature regulation.

A first thermal isolation part 451 is formed on one side of the first heating part 4031. The first thermal isolation part 451 penetrates downward from the cladding layer 414 to the substrate layer 411 to reduce the heat conducted downward from the first heating part 4031 to the substrate layer 411.

A second thermal isolation part 452 is formed on one side of the second heating part 4032. The second thermal isolation part 452 penetrates downward from the cladding layer 414 to the substrate layer 411 to reduce the heat conducted downward from the second heating part 4032 to the substrate layer 411.

In some embodiments, the first thermal isolation part 451 and the second thermal isolation part 452 may be of a groove-type structure. The first thermal isolation part 451 and the second thermal isolation part 452 are obtained by hollowing out downward. The first thermal isolation part 451 and the second thermal isolation part 452 extend downward to the substrate layer 411. A corresponding lower region of the first heating part 4031 is not hollowed out to ensure the supporting strength of the first heating part 4031. A corresponding lower region of the second heating part 4032 is not hollowed out to ensure the supporting strength of the second heating part 4032.

The medium in the first thermal isolation part 451 and the second thermal isolation part 452 may be air, with an extremely low thermal conductivity lower than that of the SiO₂ material and that of the InP material. Thus, the amount of heat generated by the first heating part 4031 and the second heating part 4032 that is conducted downward is very small, and the first thermal isolation part 451 and the second thermal isolation part 452 can block a path of downward heat conduction. Furthermore, the heat generated by the first heating part 4031 and the second heating part 4032 can be well maintained near the first InP modulator 421, thereby improving the efficiency of temperature regulation. Certainly, the arrangement of the first thermal isolation part 451 and the second thermal isolation part 452 can also reduce the amount of heat generated by the first heating part 4031 and the second heating part 4032 that is conducted to the surroundings, thereby minimizing heat diffusion into the surrounding Si-based platform 410.

In some embodiments, the first thermal isolation part 451 includes a first connection slot 4511 and a second connection slot 4512. The first connection slot 4511 extends downward to the substrate layer 411 and partially hollows out the substrate layer 411. The second connection slot 4512 extends horizontally to expand the hollowed-out range, thereby increasing the thermal isolation area.

The second thermal isolation part 452 includes a third connection slot 4521 and a fourth connection slot 4522. The third connection slot 4521 extends downward to the substrate layer 411 and partially hollows out the substrate layer 411. The fourth connection slot 4522 extends horizontally to expand the hollowed-out range, thereby increasing the thermal isolation area.

By way of example, the first connection slot 4511 is formed by etching downward, and then the etching is continued with an expanded range to form the second connection slot 4512. By way of example, the final shape formed by the first thermal isolation part 451 and the second thermal isolation part 452 may be irregular or regular.

In the present disclosure, by forming the first thermal isolation part 451 and the second thermal isolation part 452 in the Si-based platform 410 to block the downward conduction path of the heat generated by the first heating part 4031 and the second heating part 4032, the heat is confined near the first InP modulator 421, thereby improving the efficiency of temperature regulation.

For one InP modulator, the first thermal isolation part 451 and the second thermal isolation part 452 on both sides form a thermal isolation region of the InP modulator. The first heating part 4031 and the second heating part 4032 form a heating region of the InP modulator. The distance from the first connection slot 4511 to the first heating part 4031 meets the following conditions: the formed thermal isolation region wraps around the InP modulator, and the InP modulator is located between its thermal isolation region and heating region. This concentrates and confines heat generated in the heating region around the InP modulator to prevent its conduction to regions outside the thermal isolation region, thereby improving the efficiency of temperature regulation.

In the present disclosure, the first heating part 4031 and the second heating part 4032 form the heating region of the InP modulator, and the area occupied by the heating region is not limited. The area occupied by the heating region may be within the InP modulation region or outside the InP modulation region.

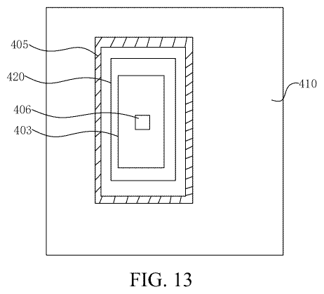

FIG. 13 is a schematic top view of a hybrid integrated optical chip according to some embodiments of the present disclosure. The perspective of FIG. 13 may be the same as that of FIG. 6. As shown in FIG. 13, the first heating parts and the second heating parts corresponding to the plurality of InP modulators, from the uppermost first heating part to the lowermost second heating part, form a heating region 403 of the hybrid integrated optical chip. The heating region 403 includes heating regions corresponding to the InP modulators. That is, the heating regions corresponding to the InP modulators form the heating region 403 of the hybrid integrated optical chip.

The first thermal isolation parts 451 and the second thermal isolation parts 452 corresponding to the plurality of InP modulators, from the uppermost first thermal isolation part 451 to the lowermost second thermal isolation part 452, form a thermal isolation region 405 of the hybrid integrated optical chip. The thermal isolation region 405 includes thermal isolation regions corresponding to the InP modulators. That is, the thermal isolation regions corresponding to the InP modulators form the thermal isolation region 405 of the hybrid integrated optical chip.

The thermal isolation region 405 wraps around the InP modulation region 420, the InP modulation region 420 wraps around the heating region 403, and the InP modulation region 420 is located between the heating region 403 and the thermal isolation region 405.

In the present disclosure, the InP modulation region 420, the heating region 403, and the thermal isolation region 405 are integrated into the optical chip 400. In the present disclosure, the InP modulation region 420 is heated by the heating region 403 to regulate the temperature of the local region of the optical chip, thereby regulating the temperature of the entire region of the optical chip and reducing power consumption.

In the present disclosure, since the InP modulators are more sensitive to temperature and the Si material is more insensitive to temperature, temperature regulation is performed on the local region, namely the InP modulation region 420 of the optical chip to regulate the temperature of the entire optical chip, thereby reducing power consumption and replacing the method for regulating the temperature of the optical chip by the TEC.

In the present disclosure, the thermal isolation region 405 blocks the conduction path of the heat generated by the heating region 403 to the substrate layer 411 to prevent its conduction to the substrate layer 411, thereby confining the heat around the InP modulation region 420 and improving the efficiency of temperature regulation.

In the present disclosure, from the perspective shown in FIG. 13, the thermal isolation region 405 is used to concentrate heat between the thermal isolation region 405 and the heating region 403 to prevent its conduction to a peripheral region of the thermal isolation region 405, thereby improving the efficiency of temperature regulation.

Certainly, in the present disclosure, the radiation area of the heating region 403 may extend to the periphery of the InP modulation region 420, that is, the area occupied by the heating region 403 is greater than that occupied by the InP modulation region 420. In this case, the heating region 403 is located between the InP modulation region 420 and the thermal isolation region 405.

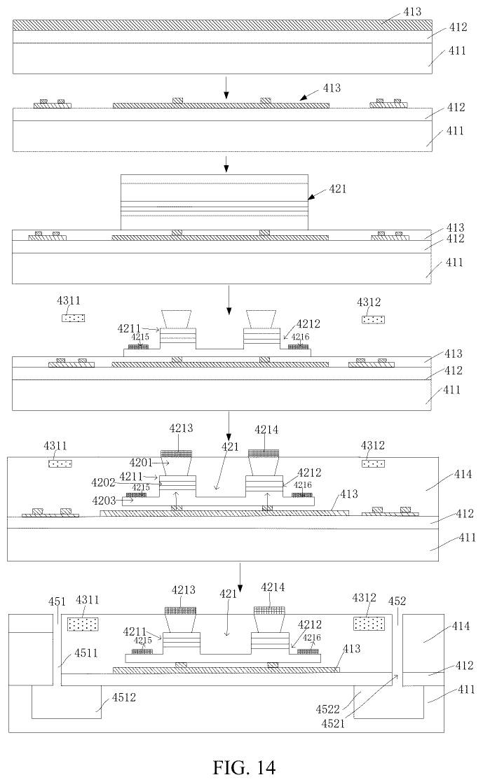

Based on the hybrid integrated optical chip provided in the embodiments of the present disclosure, the embodiments of the present disclosure further provide a method for fabricating the hybrid integrated optical chip. The method for fabricating the hybrid integrated optical chip provided in the embodiments of the present disclosure is used to facilitate fabrication of the hybrid integrated optical chip provided in the above-mentioned embodiments. FIG. 14 is a schematic diagram of a process for fabricating a hybrid integrated optical chip according to some embodiments of the present disclosure. As shown in FIG. 14, a method for fabricating a hybrid InP/Si photonic chip provided in the embodiments of the present disclosure includes the following steps.

In step S100, a silicon platform substrate is fabricated, where the silicon platform substrate includes a substrate layer and an intermediate layer, and the intermediate layer is located above the substrate layer.

The substrate layer 411 is epitaxially grown, and the intermediate layer 412 is grown on the substrate layer 411. The substrate layer 411 is epitaxially grown from a Si material, and the intermediate layer 412 is epitaxially grown from a SiO₂ material.

In step S200, etching is performed above the intermediate layer to form an optical waveguide layer.

The optical waveguide layer 413 is epitaxially grown on the intermediate layer 412, the optical waveguide layer 413 is masked to form a Si waveguide pattern, and etching is performed to form a Si input waveguide and a Si output waveguide.

There is a gap between the Si input waveguide and the Si output waveguide, above which the InP modulator is disposed. The Si input waveguide is used to input light and transmit it to the InP modulator; and the Si output waveguide is used to output light and transmit light output by the InP modulator.

In step S300, a first SiO₂ layer is formed around the optical waveguide layer after etching, a region etched out of the optical waveguide layer is filled with the first SiO₂ layer, and an InP bare die is disposed above the first SiO₂ layer, where the InP bare die includes, from bottom to top, an n-InP layer, an active quantum well layer, and a p-InP layer.

The first SiO₂ layer is epitaxially grown, such that the first SiO₂ layer wraps around a side edge of the optical waveguide layer 413, and the top of the optical waveguide layer 413 is exposed.

The InP bare die is disposed above the first SiO₂ layer, where the InP bare die includes, from bottom to top, an n-InP layer, a quantum well layer, and a p-InP layer.

The InP bare die is disposed on the first SiO₂ layer and covers the gap between the Si input waveguide and the Si output waveguide, and the end of the Si input waveguide and the end of the Si output waveguide are located below the end of the InP bare die.

The InP bare die is flip-chip bonded onto the first SiO₂ layer, such that the n-InP layer contacts the top surface of the first SiO₂ layer.

In step S400, the InP bare die is etched to form a first modulation waveguide and a second modulation waveguide, and a first N-electrode metal layer, a second N-electrode metal layer, a first heating part, and a second heating part are grown.

The shapes of the first modulation waveguide and the second modulation waveguide are formed by etching. In addition, the first N-electrode metal layer 4215, the second N-electrode metal layer 4216, the first heating part 4031, and the second heating part 4032 are grown. The first N-electrode metal layer 4215 and the second N-electrode metal layer 4216 are respectively disposed on both sides of the n-InP layer.

In step S500, a second SiO₂ layer is formed by filling, and the first SiO₂ layer and the second SiO₂ layer form a cladding layer; and a first P-electrode metal layer and a second P-electrode metal layer are fabricated on the surface of the cladding layer.

The second SiO₂ layer is epitaxially grown, such that the second SiO₂ layer is formed on side edges of the first modulation waveguide and the second modulation waveguide and filled in a surrounding region. The first SiO₂ layer and the second SiO₂ layer form the cladding layer.

The first P-electrode metal layer and the second P-electrode metal layer are fabricated on the surface of the cladding layer.

In step S600, downward etching is performed on one side of a corresponding heating part to form a corresponding thermal isolation part.

In some embodiments, the first thermal isolation part 451 includes a first connection slot 4511 and a second connection slot 4512. The first connection slot 4511 extends downward to the substrate layer 411 and partially hollows out the substrate layer 411. The second connection slot 4512 extends horizontally to expand the hollowed-out range, thereby increasing the thermal isolation area.

The second thermal isolation part 452 includes a third connection slot 4521 and a fourth connection slot 4522. The third connection slot 4521 extends downward to the substrate layer 411 and partially hollows out the substrate layer 411. The fourth connection slot 4522 extends horizontally to expand the hollowed-out range, thereby increasing the thermal isolation area.

By way of example, the first connection slot 4511 is formed by etching downward, and then the etching is continued with an expanded range to form the second connection slot 4512. By way of example, the final shape formed by the first thermal isolation part 451 and the second thermal isolation part 452 may be irregular or regular.

In the present disclosure, since the InP modulators are more sensitive to temperature than the Si-based material, temperature regulation is performed on the local region, namely the InP modulation region of the optical chip, rather than the entire optical chip, thereby enabling the optical chip to operate within a certain temperature range while reducing power consumption. By way of example, the surface of the cladding layer is respectively embedded with a first heating part and a second heating part. The first modulation waveguide in the InP modulator is disposed adjacent to the first heating part, such that the temperature of the first modulation waveguide is regulated via the first heating part; and the second modulation waveguide is disposed adjacent to the second heating part, such that the temperature of the second modulation waveguide is regulated via the second heating part.

In the present disclosure, the heating parts are embedded in the Si-based platform. Temperature regulation is performed on the local region, namely the InP modulation region of the optical chip via the heating parts, thereby enabling the optical chip to operate within a certain temperature range in a low-power mode. In addition, by regulating the temperature of the InP modulator, the thermal stress during bonding between the InP modulation region and the Si-based platform can be reduced, thereby improving the reliability and modulation rate of the InP modulator and meeting the requirements of high-rate optical modules.

In the present disclosure, the heating parts are integrated into the optical chip in an embedded manner. Since the InP material is more sensitive to temperature than the Si material, temperature regulation is performed on the local region of the optical chip via the heating parts to regulate the temperature of the entire region of the optical chip, thereby reducing power consumption. Furthermore, the thermal isolation parts confine the heat within the InP modulation region, thereby improving the efficiency of temperature regulation.

As shown in FIG. 5, in some embodiments, the light source 500 may be an electro-absorption modulated laser (EML). The EML requires an independent packaging space, and one EML corresponds to one optical channel, so the EML is not suitable for multi-channel transmission. Moreover, the EML cannot reduce the optical fiber dispersion effect, so it is not suitable for long-distance transmission.

In the present disclosure, the lasers corresponding to the channels are integrated into the hybrid integrated optical chip to enhance integration. Furthermore, since each channel corresponds to one laser, the local power density and the thermal stress can be reduced, thereby improving the reliability of the hybrid integrated optical chip and making it suitable for multi-channel transmission.

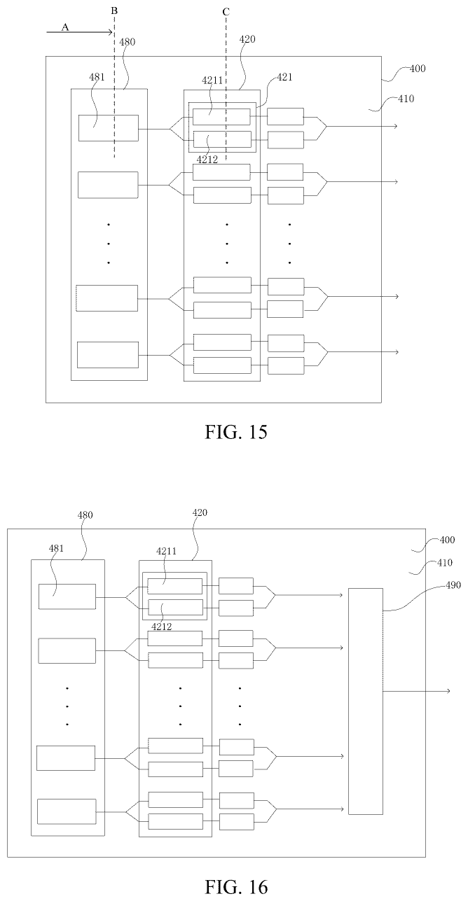

FIG. 15 is a first structural diagram of a hybrid integrated optical chip according to some embodiments of the present disclosure. As shown in FIG. 15, the optical chip 400 is a hybrid integrated optical chip.

In addition to including the Si-based platform 410 in the above-mentioned embodiments, the optical chip 400 may further include the following InP light-emitting region 480 and InP modulation region 420. The structure and formation method of the Si-based platform 410 can be understood with reference to the above-mentioned embodiments, and will not be repeated herein.

The optical chip 400 may include an InP light-emitting region 480. The InP light-emitting region 480 is grown from an InP material. Various lasers 481 are disposed in the InP light-emitting region 480. The laser 481 may be a III-V laser, such as an InP laser. The III-V material is a direct bandgap material with a strong linear electro-optic Pockels effect, making it easy to achieve optical gain functionality.

The optical chip 400 may include an InP modulation region 420. The InP modulation region 420 is grown from an InP material. A plurality of InP modulators 421 are disposed in the InP modulation region 420. The InP-based optical modulator modulates the optical signal based on a quantum-confined Stark effect. By controlling the variation of the externally applied electric field, carrier changes are induced to change the refractive index, thereby modulating the optical signal. The InP modulators have high modulation rate and efficiency.

The InP modulation region 420 is disposed on a light output path of the InP light-emitting region 480 to receive light emitted by the InP light-emitting region 480 and perform signal modulation thereon.

A coupled waveguide is disposed between the InP light-emitting region 480 and the InP modulation region 420. The coupled waveguide may be a Si waveguide or an InP waveguide. Considering optical transmission loss, the Si waveguide with low optical loss may be selected as the coupled waveguide. Considering the growth process, the coupled waveguide may be fabricated using the same InP material as the InP light-emitting region 480 and the InP modulation region 420, in which case the coupled waveguide is the InP waveguide.

In the present disclosure, the InP light-emitting region 480 and the InP modulation region 420 are merged into an InP region. Thus, the optical chip 400 is a hybrid integrated InP/Si photonic chip. In the present disclosure, the optical chip 400 is a hybrid integrated optical chip that achieves hybrid integration of the Si material and the InP material. It utilizes the InP material to provide high-speed modulation and the Si material to provide a highly integrated silicon photonic circuit, enabling the optical chip 400 to have the high-speed modulation characteristics of the InP material, meet the requirement for high-baud-rate modulation, and give full play to the characteristics of the Si material and the InP material.

In the present disclosure, the hybrid integrated optical chip integrates both the InP light-emitting region 480 and the InP modulation region 420, thereby having both light emission and signal modulation functions and completing light emission and signal modulation in the same chip.

The InP light-emitting region 480 and the InP modulation region 420 are located in the Si-based platform 410, such that the Si-based platform 410 wraps around the InP light-emitting region 480 and the InP modulation region 420 from the front, back, left, right, and bottom directions.

The InP modulation region 420 in the present disclosure can be understood with reference to the above-mentioned embodiments, and will not be repeated herein.

The InP modulator in the present disclosure is a linear electro-optic modulator, such as an MZ modulator. Thus, the hybrid integrated optical chip in the present disclosure has a linear electro-optic modulation effect. Based on the linear electro-optic modulation effect, the hybrid integrated optical chip in the present disclosure has high modulation efficiency and high bit rate; moreover, under the same modulation rate, the hybrid integrated optical chip in the present disclosure can achieve higher-order pulse amplitude modulation (PAM) at a lower modulation bandwidth; additionally, in the hybrid integrated optical chip in the present disclosure, the chirp parameter of the InP modulator is optimized by adjusting the operating parameters of the InP modulator, thereby reducing the impact of the optical fiber dispersion effect, making the hybrid integrated optical chip in the present disclosure more suitable for long-distance transmission; and furthermore, the hybrid integrated optical chip in the present disclosure can support linear drive applications. The hybrid integrated optical chip provided in the present disclosure is more suitable for multi-channel and long-distance transmission, and can achieve high-bit-rate and higher-order PAM.

In some embodiments, on one channel, one laser corresponds to one InP modulator. For an 8-channel optical module, eight lasers are integrated into the InP light-emitting region 480, and eight InP lasers are integrated into the InP modulation region 420. For a 16-channel optical module, sixteen lasers are integrated into the InP light-emitting region 480, and sixteen InP lasers are integrated into the InP modulation region 420. There is no specific limitation herein.

In the present disclosure, the lasers corresponding to the channels are integrated into the hybrid integrated optical chip to enhance integration. Furthermore, since each channel corresponds to one laser, the local power density and the thermal stress can be reduced, thereby improving the reliability of the hybrid integrated optical chip and making it suitable for multi-channel transmission.

FIG. 16 is a second structural diagram of a hybrid integrated optical chip according to some embodiments of the present disclosure. As shown in FIG. 16, an optical multiplexing assembly 490 is integrated into the optical chip 400. The optical multiplexing assembly 490 combines various paths of optical signals into a beam of light and outputs it.

In some embodiments, the InP light-emitting region 480 and the InP modulation region 420 are merged into an InP region. Light is transmitted in the InP region via the InP waveguide. Light is transmitted outside the InP region via the optical waveguide layer 413.

Referring to FIG. 8, the Si-based platform 410 may include a cladding layer 414. By way of example, the cladding layer 414 is epitaxially grown from a SiO₂ material. The substrate layer 411, the intermediate layer 412, the optical waveguide layer 413, and the cladding layer 414 are sequentially arranged from bottom to top.

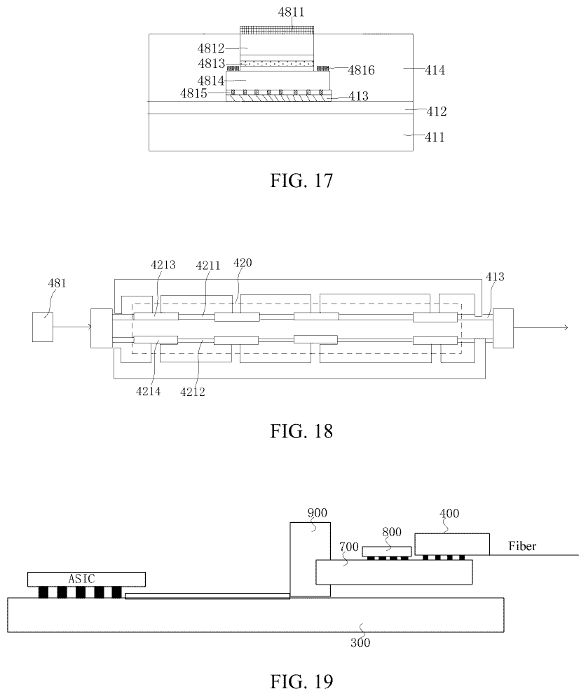

FIG. 17 is a partial cross-sectional view of a hybrid integrated optical chip according to some embodiments of the present disclosure. FIG. 17 is a structural diagram formed by sectioning in a direction A indicated in FIG. 15 to a position B. As shown in FIG. 17, the laser 481 is disposed in the Si-based platform 410.

The laser 481 may include a first electrode metal layer 4811. When the second electrode metal layer 4816 and the first electrode metal layer 4811 form a PN junction, the concentration difference of carriers leads to diffusion motion. The result of carrier diffusion is that the first electrode metal layer 4811 contains holes and negative ions.

The laser 481 may include a p-InP layer 4812.

The laser 481 may include an active quantum well layer 4813. The active quantum well layer 4813 may adopt a multiple-quantum-well structure, thereby enhancing the carrier collection capability of the active quantum well layer 4813 and the radiative recombination capability. As the number of quantum wells increases, the amount of active material increases, and the optical gain gradually increases, thereby increasing the output optical power.

The laser 481 may include an n-InPlayer 4814. Both ends of the n-InP layer 4814 extend beyond the active quantum well layer 4814, such that second electrode metal layers 4816 are respectively disposed on the surfaces of the both ends of the n-InP layer 4814.

The laser 481 may include a grating layer 4815.

In some embodiments, the grating layer 4815 is formed by etching along the surface of the optical waveguide layer 413.

The laser 481 may include second electrode metal layers 4816. The second electrode metal layers 4816 are disposed on the surfaces of the both ends of the n-InP layer 4814 that extend outward oppositely. When the second electrode metal layer 4816 and the first electrode metal layer 4811 form a PN junction, the concentration difference of carriers leads to diffusion motion. The result of carrier diffusion is that the second electrode metal layer 4816 contains electrons and positive ions.

In some embodiments, when the second electrode metal layer 4816 and the first electrode metal layer 4811 form a PN junction, the concentration difference of carriers leads to diffusion motion. The result of carrier diffusion is that the first electrode metal layer 4811 contains holes and negative ions, and the second electrode metal layer 4816 contains electrons and positive ions. Based on the charge principle, holes are driven downward into the active quantum well layer 4813, and electrons are driven upward into the active quantum well layer 4813. Therefore, the first electrode metal layer 4811 is used to inject holes into the active quantum well layer 4813, where the holes are the above-mentioned P-type carriers; and the second electrode metal layer 4816 is used to inject electrons into the active quantum well layer 4813, where the electrons are the above-mentioned N-type carriers. In the active quantum well layer 4813, stimulated radiation induces the recombination of discrete electron-hole pairs to generate photons, thereby effectively converting electrically injected carriers into photons and producing gain light. The photons generated by recombination in the active quantum well layer 4813 are reflected by a resonant cavity or a distributed feedback grating to form positive feedback, thereby generating lasing light.

In some embodiments, by changing the current injected into the grating layer 4815, the effective refractive index of the grating layer 4815 can be changed, thereby altering the resonant lasing wavelength of the laser 481 to achieve specific wavelength selection.

In the present disclosure, the p-InP layer corresponding to the first modulation waveguide, the p-InP layer corresponding to the second modulation waveguide, and the p-InP layer corresponding to the laser are located in the same layer. The n-InP layer corresponding to the first modulation waveguide, the n-InP layer corresponding to the second modulation waveguide, and the n-InP layer corresponding to the laser are located in the same layer. The active quantum well layer corresponding to the first modulation waveguide, the active quantum well layer corresponding to the second modulation waveguide, and the active quantum well layer corresponding to the laser are located in the same layer.

In the present disclosure, an exemplary description is provided using one optical channel as an example. A beam splitter is formed in an optical path between the laser 481 and the InP modulator 421. Light emitted by the laser 481 is split by the beam splitter into two beams of light, which respectively enter the first modulation waveguide 4211 and the second modulation waveguide 4212. By controlling different phase differences between the first modulation waveguide 4211 and the second modulation waveguide 4212, the output light intensity of the laser is modulated by a modulated electrical signal. The modulated electrical signal is modulated into the output light intensity of the modulated optical signal, thereby achieving modulation.

The InP modulator in the present disclosure is a linear electro-optic modulator, such as an MZ modulator. Thus, the hybrid integrated optical chip in the present disclosure has a strong linear electro-optic modulation effect.

Based on the strong linear electro-optic modulation effect, the hybrid integrated optical chip in the present disclosure has high modulation efficiency and bit rate. In addition, under the same modulation rate, the hybrid integrated optical chip in the present disclosure can achieve higher-order PAM at a lower modulation bandwidth. For example, at the same modulation rate of 448 Gbps, the modulation bandwidth corresponding to PAM6 modulation is 87 GHz, while that corresponding to PAM4 modulation is 112 GHz.

Based on the strong linear electro-optic modulation effect, in the hybrid integrated optical chip in the present disclosure, the chirp parameter of the InP modulator is optimized by adjusting the operating parameters of the InP MZ modulator, thereby reducing the impact of the optical fiber dispersion effect, and making the hybrid integrated optical chip in the present disclosure more suitable for long-distance transmission. For example, the chirp parameter of the InP MZ modulator is optimized by adjusting the parameters such as a splitting ratio and an operating point of the InP MZ modulator, thereby reducing the impact of the optical fiber dispersion effect, and making the hybrid integrated optical chip in the present disclosure more suitable for long-distance transmission.

Based on the strong linear electro-optic modulation effect, the hybrid integrated optical chip in the present disclosure can support linear drive applications. The hybrid integrated optical chip provided in the present disclosure is more suitable for multi-channel and long-distance transmission, and can achieve high-bit-rate and higher-order PAM.

FIG. 18 is a schematic diagram of optical path transmission in a hybrid integrated optical chip according to some embodiments of the present disclosure. As shown in FIG. 18, the InP modulation region 420 is disposed on a light output path of the InP light-emitting region 480 to receive light emitted by the InP light-emitting region 480 and perform signal modulation thereon.

A beam splitter is formed in an optical path between the laser 481 and the InP modulator 421. Light emitted by the laser 481 is split by the beam splitter into two beams of light, which respectively enter the first modulation waveguide 4211 and the second modulation waveguide 4212. By controlling different phase differences between the first modulation waveguide 4211 and the second modulation waveguide 4212, the output light intensity is modulated by a modulated electrical signal. The modulated electrical signal is modulated into the output light intensity of the modulated optical signal, thereby achieving modulation. The optical signal generated by modulation is transmitted via the optical waveguide layer 413.

A coupled waveguide is disposed between the laser 481 and the InP modulator 421. The coupled waveguide may be a Si waveguide or an InP waveguide. Considering optical transmission loss, the Si waveguide with low optical loss may be selected as the coupled waveguide. Considering the growth process, the coupled waveguide may be fabricated using the same InP material as the InP light-emitting region 480 and the InP modulation region 420, in which case the coupled waveguide is the InP waveguide.

The first P-electrode metal layer 4213 on the first modulation waveguide 4211 and the second P-electrode metal layer 4214 on the second modulation waveguide 4212 are paired electrodes. A plurality of first P-electrode metal layers 4213 are disposed on the first modulation waveguide 4211, and a plurality of first P-electrode metal layers 4213 are disposed on the second modulation waveguide 4212, such that multiple pairs of first P-electrode metal layers exist on one InP modulator.

One InP modulator includes two modulation waveguides, namely a first modulation waveguide 4211 and a second modulation waveguide 4212. The first modulation waveguide 4211 and the second modulation waveguide 4212 are two modulation arms of the InP modulator 421.

The first modulation waveguide 4211 and the second modulation waveguide 4212 are InP-based modulation waveguides. To improve the optical coupling efficiency, a spot size converter can be disposed between the InP-based modulation waveguide and the Si waveguide to enhance the optical coupling efficiency between the two. A high coupling loss may occur between the InP-based modulation waveguide and the Si waveguide due to a significant mode field mismatch. The spot size converter is used to match the spot size and mode field between the two, thereby improving the optical coupling efficiency.

FIG. 19 is a schematic diagram of an external electrical connection of a hybrid integrated optical chip according to some embodiments of the present disclosure. Based on the hybrid integrated optical chip provided in the embodiments of the present disclosure, the present disclosure further provides a hybrid integrated optical chip assembly. As shown in FIG. 19, the hybrid integrated optical chip assembly includes a substrate 700, a driver 800, and an optical chip 400, with the driver 800 and the optical chip 400 disposed above the substrate 700. The optical chip 400 is a hybrid integrated optical chip.

By way of example, the driver 800 and the hybrid integrated optical chip are respectively connected to the substrate 700 via solder balls.

One end of the above-mentioned hybrid integrated optical chip assembly is embedded into an electrical connection part 900. One end of the electrical connection part 900 is electrically connected to the driver 800 and the optical chip 400, and the other end thereof is electrically connected to an ASIC device via a high-frequency transmission line.

The InP modulator in the present disclosure is a linear electro-optic modulator, such that the hybrid integrated optical chip in the present disclosure has a linear electro-optic modulation effect. Based on the linear electro-optic modulation effect, the hybrid integrated optical chip in the present disclosure can support linear drive applications.

Since the hybrid integrated optical chip in the present disclosure can support linear drive applications, the high-frequency signal transmission quality can be ensured, thereby allowing long high-frequency transmission lines to transmit electrical signals to the optical chip 400.

Based on the hybrid integrated optical chip provided in the embodiments of the present disclosure, the process for fabricating the hybrid integrated optical chip in the embodiments of the present disclosure may include the following steps.

In step S100, a silicon platform substrate is fabricated, where the silicon platform substrate includes a substrate layer and an intermediate layer, and the intermediate layer is located above the substrate layer.

The substrate layer 411 is epitaxially grown, and the intermediate layer 412 is grown on the substrate layer 411. The substrate layer 411 is epitaxially grown from a Si material, and the intermediate layer 412 is epitaxially grown from a SiO₂ material.

In step S200, etching is performed above the intermediate layer to form a Si waveguide layer, and the surface of the Si waveguide layer is etched to form a grating layer.

The Si waveguide layer is epitaxially grown on the intermediate layer 412 to form an optical waveguide layer 413. Moreover, the surface of the optical waveguide layer 413 is etched to form the grating layer 4815.

In step S300, a first SiO₂ layer is formed around the Si waveguide layer and the grating layer after etching, a region etched out of the Si waveguide layer is filled with the first SiO₂ layer, and an InP bare die is grown above the first SiO₂ layer.

The region around the Si waveguide layer and the grating layer after etching is filled with SiO₂.

In step S400, the InP bare die is etched layer by layer to obtain respective n-InP layers, respective active quantum well layers, and respective p-InP layers of a laser, a first modulation waveguide, and a second modulation waveguide.

In the present disclosure, the p-InP layer corresponding to the first modulation waveguide, the p-InP layer corresponding to the second modulation waveguide, and the p-InP layer corresponding to the laser are located in the same layer. The n-InP layer corresponding to the first modulation waveguide, the n-InP layer corresponding to the second modulation waveguide, and the n-InP layer corresponding to the laser are located in the same layer. The active quantum well layer corresponding to the first modulation waveguide, the active quantum well layer corresponding to the second modulation waveguide, and the active quantum well layer corresponding to the laser are located in the same layer.

In step S500, second electrode metal layers of the laser are fabricated on the surfaces of both ends of the n-InP layer of the laser; and a first N-electrode metal layer and a second N-electrode metal layer are fabricated on the surfaces of both ends of the n-InP layer of the InP modulator.

The both ends of the n-InP layer 4814 of the laser extend beyond the active quantum well layer 4813, such that the second electrode metal layers 4816 are respectively disposed on the surfaces of the both ends of the n-InP layer 4814.

The both ends of the n-InP layer 4203 of the InP modulator extend beyond the active quantum well layer 4202, such that the first N-electrode metal layer 4215 and the second N-electrode metal layer 4216 are respectively disposed on the surfaces of the both ends of the n-InP layer 4203 that extend outward.

In step S600, a current blank region is filled to form a second SiO₂ layer, and the first SiO₂ layer and the second SiO₂ layer form a cladding layer.

SiO₂ is filled from the p-InP layer corresponding to the first modulation waveguide downward to the n-InP layer corresponding to the first modulation waveguide in a height direction, and along the blank region of the region formed by the substrate layer 411 in a width direction, where the filled SiO₂ layer is the second SiO₂ layer. The first SiO₂ layer and the second SiO₂ layer form the cladding layer 414.

In step S700, a first electrode metal layer of the laser, a first P-electrode metal layer corresponding to the first modulation waveguide, and a second P-electrode metal layer corresponding to the second modulation waveguide are fabricated on the surface of the cladding layer.

In the present disclosure, the hybrid integrated optical chip includes a Si-based platform, an InP light-emitting region, and an InP modulation region. The InP light-emitting region and the InP modulation region are disposed on the Si-based platform. The InP modulation region is disposed on a light output path of the InP light-emitting region to receive light emitted by the InP light-emitting region and perform signal modulation thereon. Various lasers are arranged side by side on the surface of the InP light-emitting region. The laser includes an active quantum well layer and a grating layer. The active quantum well layer is used to output light and transmit the output light toward the grating layer. The grating layer is disposed on the surface of the Si waveguide layer and used to perform wavelength selection on the light output by the active quantum well layer. Various InP modulators are arranged side by side on the surface of the InP modulation region. The InP modulator is a linear electro-optic modulator. The InP modulators are correspondingly connected to the lasers. The InP modulator is disposed on the surface of the Si waveguide layer. The InP modulator includes a first modulation waveguide and a second modulation waveguide. The first modulation waveguide and the second modulation waveguide are optically coupled to the laser to receive the light output by the laser. The InP modulator is configured to perform signal modulation on the light output by the laser to generate an optical signal. The hybrid integrated optical chip in the present disclosure is a hybrid integrated InP/Si photonic chip. The InP modulator has a high modulation rate, and the surface of the Si-based platform can be etched to form various functional devices. Therefore, the hybrid integrated optical chip in the present disclosure has both a high modulation rate and surface etchability.

In the present disclosure, the lasers corresponding to the channels are integrated into the hybrid integrated optical chip to enhance integration. Furthermore, since each channel corresponds to one laser, the local power density and the thermal stress can be reduced, thereby improving the reliability of the hybrid integrated optical chip and making it suitable for multi-channel transmission.

The InP modulator in the present disclosure is a linear electro-optic modulator, such that the hybrid integrated optical chip in the present disclosure has a linear electro-optic modulation effect. Based on the linear electro-optic modulation effect, the hybrid integrated optical chip in the present disclosure has high modulation efficiency and bit rate.

Under the same modulation rate, the hybrid integrated optical chip in the present disclosure can achieve higher-order PAM modulation at a lower modulation bandwidth.

In the hybrid integrated optical chip in the present disclosure, the chirp parameter of the InP modulator is optimized by adjusting the operating parameters of the InP modulator, thereby reducing the impact of the optical fiber dispersion effect, and making the hybrid integrated optical chip in the present disclosure more suitable for long-distance transmission.

The hybrid integrated optical chip in the present disclosure can support linear drive applications. The hybrid integrated optical chip provided in the present disclosure is more suitable for multi-channel and long-distance transmission, and can achieve high-bit-rate and higher-order PAM.

In the embodiments of the present disclosure, based on the above-mentioned exemplary optical modulator structure (which, from bottom to top, includes the silicon waveguide layer, the N-type InPlayer, the quantum well layer, and the P-type InP layer), in order to improve the optical coupling efficiency between the optical modulator and the demultiplexer and multiplexer (also referred to as a beam splitter and a beam combiner) located on both sides thereof, the structures at both ends of the optical modulator are improved, that is, tapered structures are formed at both ends of the optical modulator respectively to reduce mode discontinuity during optical coupling between the silicon waveguide and the InP waveguide, thereby achieving low-loss optical coupling between the silicon waveguide and the InP waveguide. The specific structure of the optical modulator can be understood with reference to the following embodiments.

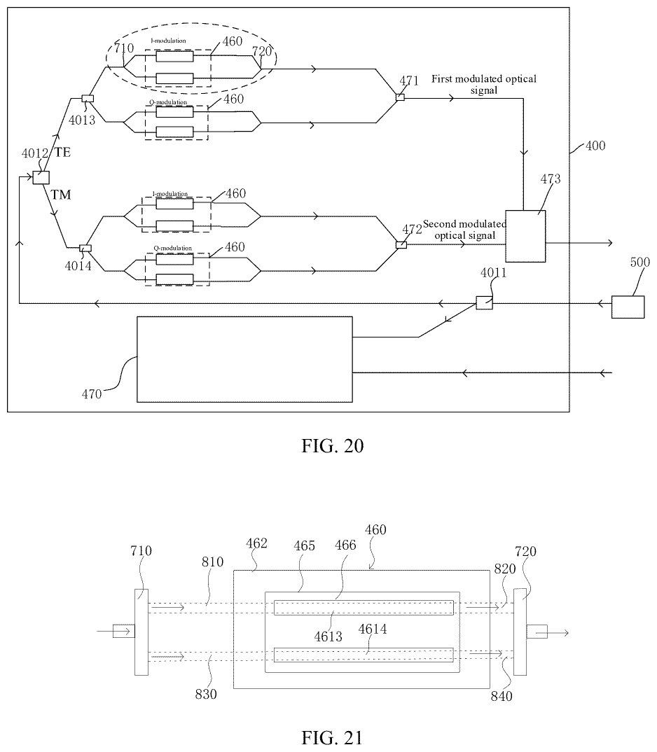

FIG. 20 is a schematic diagram of an internal structure of an optical chip according to some embodiments of the present disclosure. As shown in FIG. 20, the external light source 500 provides light to the optical chip 400.

The laser light generated by the external light source 500 is coupled into the optical chip 400. The laser light is split into a first light beam and a second light beam by the optical splitter 4011 integrated into the optical chip 400.

The first light beam serves as local oscillator light and is coupled into an optical demodulator disposed in the optical chip 400, while the external optical signal is coupled into the optical demodulator. The second light beam and the external optical signal undergo coherent demodulation in the optical demodulator to obtain corresponding electrical signals.

The second light beam serves as a light source for the optical emission signal and is transmitted to the polarization beam splitter 4012. The second light beam is split by the polarization beam splitter 4012 into two beams of light with different polarization directions: TE-polarized light and TM-polarized light.

The TE-polarized light is split by the optical splitter 4013 into two beams of light, which are respectively coupled into two optical modulators 460 located close to the upper side in FIG. 20. In these two optical modulators 460, the upper optical modulator 460 performs I-modulation on the received light to generate an I-modulated signal; and the lower optical modulator 460 performs Q-modulation on the received light to generate a Q-modulated signal. The I-modulated signal and the Q-modulated signal of this beam of light are combined by the multiplexer 471 to generate a first modulated optical signal. Certainly, the upper optical modulator 460 may perform Q-modulation on the received light, and the lower optical modulator 460 may perform I-modulation on the received light. There is no limitation herein.

The TM-polarized light is split by the optical splitter 4014 into two beams of light, which are respectively coupled into two optical modulators 460 located close to the lower side in FIG. 20. In these two optical modulators 460, the upper optical modulator 460 performs I-modulation on the received light to generate an I-modulated signal; and the lower optical modulator 460 performs Q-modulation on the received light to generate a Q-modulated signal. The I-modulated signal and the Q-modulated signal of this beam of light are combined by the multiplexer 472 to generate a second modulated optical signal.

The first modulated optical signal and the second modulated optical signal are combined by the multiplexer 473 to generate an optical emission signal, thereby completing modulation of the optical signal.

The following embodiments provide an exemplary description using one of the optical modulators 460 as circled by the ellipse in FIG. 20 as an example.

FIG. 21 is a first top view of an optical modulator according to some embodiments of the present disclosure. As shown in FIG. 21, in some embodiments, one end of the optical modulator 460 is connected to a demultiplexer 710, and the other end thereof is connected to a multiplexer 720.

In some embodiments, the demultiplexer 710 is disposed on one side of the optical modulator 460 to respectively output two paths of light to be modulated to the optical modulator 460.

In some embodiments, the multiplexer 720 is disposed on the other side of the optical modulator 460 to combine the two paths of modulated optical signals generated by the optical modulator 460.

In some embodiments, the optical modulator 460 can be understood with reference to the above-mentioned example, and an InP-based Mach-Zehnder (MZ) modulator can be selected. Incident light of the MZ modulator is split into two paths by the demultiplexer 710, and phase modulation is performed on one or both paths to generate a phase difference between the two paths of light, thereby achieving modulation of the light intensity. The two paths of modulated optical signals are combined by the multiplexer 720 and output. In some embodiments, since the silicon waveguide has low transmission loss, it is used as the optical waveguide in the hybrid integrated InP/Si photonic chip.

For one optical modulator 460, the silicon waveguide includes a silicon waveguide between the output of the demultiplexer 710 and the input of the optical modulator 460, a silicon waveguide of the optical modulator 460 itself, and a silicon waveguide between the output of the optical modulator 460 and the input of the multiplexer 720. The three waveguides are sequentially connected to form an entire silicon waveguide.

Incident light of the MZ modulator is split into two paths by the demultiplexer 710, so the demultiplexer 710 has two outputs. The optical modulator 460 correspondingly has two inputs and two outputs. The inputs and outputs of the optical modulator 460 are respectively located on the silicon waveguide of the optical modulator 460 itself.

In some embodiments, the silicon waveguide between the first output of the demultiplexer 710 and the first input of the optical modulator 460 is referred to as a silicon waveguide 810. The silicon waveguide after the first output of the optical modulator 460 is referred to as a silicon waveguide 820. The silicon waveguide 810 and the silicon waveguide 820 correspond to one path of optical signal output by the demultiplexer 710.

The silicon waveguide between the second output of the demultiplexer 710 and the second input of the optical modulator 460 is referred to as a silicon waveguide 830. The silicon waveguide after the second output of the optical modulator 460 is referred to as a silicon waveguide 840. The silicon waveguide 830 and the silicon waveguide 840 correspond to the other path of optical signal output by the demultiplexer 710.

For the optical modulator 460, the silicon waveguide 810, the silicon waveguide 820, the silicon waveguide 830, and the silicon waveguide 840 are external silicon waveguides.

In some embodiments, the silicon waveguide between the first input and the first output of the optical modulator 460 is a first silicon ridge waveguide 4613. This silicon waveguide adopts a ridge waveguide with high modulation rate and efficiency. The first silicon ridge waveguide 4613 corresponds to one path of optical signal output by the demultiplexer 710.

The silicon waveguide between the second input and the second output of the optical modulator 460 is a second silicon ridge waveguide 4614. This silicon waveguide also adopts a ridge waveguide with high modulation rate and efficiency. The second silicon ridge waveguide 4614 corresponds to the other path of optical signal output by the demultiplexer 710.

For the optical modulator 460, the first silicon ridge waveguide 4613 and the second silicon ridge waveguide 4614 are silicon waveguides of the optical modulator 460 itself.

In some embodiments, the silicon waveguide 810, the first silicon ridge waveguide 4613, and the silicon waveguide 820 are sequentially connected, that is, the input of the first silicon ridge waveguide 4613 is connected to the silicon waveguide 810 to receive the light to be modulated; and the output thereof is connected to the silicon waveguide 820 to output the modulated optical signal generated by modulation.

The silicon waveguide 830, the second silicon ridge waveguide 4614, and the silicon waveguide 840 are sequentially connected, that is, the input of the second silicon ridge waveguide 4614 is connected to the silicon waveguide 830 to receive the light to be modulated; and the output thereof is connected to the silicon waveguide 840 to output the modulated optical signal generated by modulation.

In some embodiments, since the first silicon ridge waveguide 4613 and the second silicon ridge waveguide 4614 adopt a ridge waveguide structure, the silicon waveguide 810, the silicon waveguide 820, the silicon waveguide 830, and the silicon waveguide 840 also adopt a ridge waveguide structure to simplify the growth process.

In some embodiments, the optical modulator 460 includes an N-type InP layer 462, a quantum well layer 465, and a P-type InP layer 466 to achieve modulation. The N-type InP layer 462, the quantum well layer 465, and the P-type InP layer 466 are stacked longitudinally in sequence.

The quantum well layer 465 is a target layer for the light to be modulated to reach, thereby achieving modulation in the quantum well layer 465. By controlling the variation of the externally applied electric field, carrier changes are induced to change the refractive index of the active quantum well layer 465, thereby achieving signal modulation.

The quantum well layer 465 is located between the N-type InP layer 462 and the P-type InP layer 466. The optical field is confined within the quantum well layer 465 by the vertically arranged N-type InP layer 462 and P-type InP layer 466 to avoid optical field divergence.

It can be understood that the optical field within the first silicon ridge waveguide 4613 will diffuse upward to the InP region, that is, the optical spot will expand into the InP region, so the light to be modulated that is transmitted in the first silicon ridge waveguide 4613 will be coupled upward to the InP region.

Similarly, the optical field within the InP region will diffuse downward into the first silicon ridge waveguide 4613, that is, the optical spot will expand into the region of the first silicon ridge waveguide 4613, so the modulated optical signal generated by modulation will be coupled downward into the first silicon ridge waveguide 4613.

In some embodiments, incident light of the MZ modulator is split into two paths by the demultiplexer 710.

One path of light to be modulated is coupled along the silicon waveguide 810 to the input of the first silicon ridge waveguide 4613, and the light to be modulated that is transmitted in the first silicon ridge waveguide 4613 is coupled upward to the quantum well layer 465 for modulation. The modulated optical signal is coupled downward to the output of the first silicon ridge waveguide 4613, and then sequentially transmitted along the first silicon ridge waveguide 4613 and the silicon waveguide 820 into the multiplexer 720.

The other path of light to be modulated is coupled along the silicon waveguide 830 to the input of the second silicon ridge waveguide 4614, and the light to be modulated that is transmitted in the second silicon ridge waveguide 4614 is coupled upward to the quantum well layer 465 for modulation. The modulated optical signal is coupled downward to the second silicon ridge waveguide 4614, and then sequentially transmitted along the second silicon ridge waveguide 4614 and the silicon waveguide 840 into the multiplexer 720.

Two paths of modulated optical signals are respectively connected to the multiplexer 720, combined into one path of optical signal, and output.

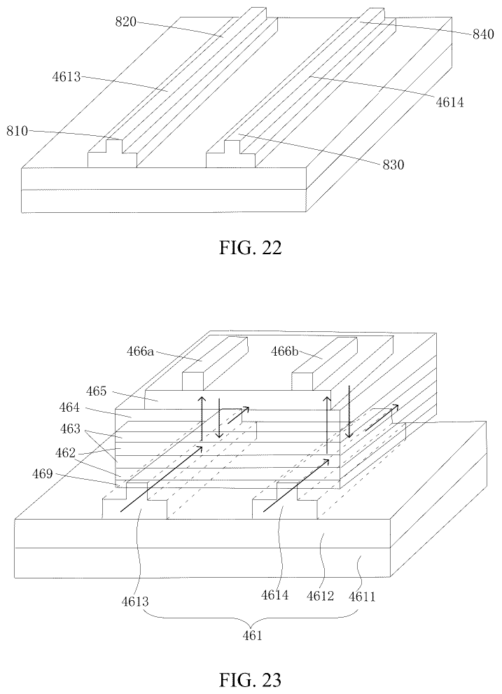

FIG. 22 is a structural diagram of a silicon waveguide according to some embodiments of the present disclosure. As shown in FIG. 22, in some embodiments, the silicon waveguide adopts a ridge structure to reduce transmission loss.

When adopting a ridge structure, the silicon waveguide includes a silicon slab with a large cross-sectional area and a silicon ridge with a small cross-sectional area. The silicon ridge is located on the surface of the silicon slab.

A complete silicon waveguide is divided into sections along an optical path transmission direction. The silicon waveguide 810 and the silicon waveguide 820 are respectively connected to the first input and the first output of the optical modulator 460; and the silicon waveguide 830 and the silicon waveguide 840 are respectively connected to the second input and the second output of the optical modulator 460.

The InP modulation region of the optical modulator 460 is disposed above the first silicon ridge waveguide 4613 and the second silicon ridge waveguide 4614. Therefore, the two paths of light transmitted in the first silicon ridge waveguide 4613 and the second silicon ridge waveguide 4614 are respectively coupled upward into the InP modulation region, and after modulation is completed, they are downwardly coupled back into the first silicon ridge waveguide 4613 and the second silicon ridge waveguide 4614 for output.

A silicon waveguide 810 is disposed between the first output of the demultiplexer 710 and the first input of the optical modulator 460 to couple one path of split light into the optical modulator 460. A first silicon ridge waveguide 4613 is disposed between the first input and the first output of the optical modulator 460. A silicon waveguide 820 is disposed behind the first output of the optical modulator 460 to output the optical signal generated by modulation in the optical modulator 460.

A silicon waveguide 830 is disposed between the second output of the demultiplexer 710 and the second input of the optical modulator 460 to couple the other path of split light into the optical modulator 460. A second silicon ridge waveguide 4614 is disposed between the second input and the second output of the optical modulator 460. A silicon waveguide 840 is disposed behind the second output of the optical modulator 460 to output the optical signal generated by modulation in the optical modulator 460.

One path of light output by the demultiplexer 710 is transmitted along the silicon waveguide 810 to the input of the first silicon ridge waveguide 4613, and then this path of light is coupled upward to the optical modulation region of the optical modulator 460 for signal modulation. The modulated optical signal is downwardly coupled back to the output of the first silicon ridge waveguide 4613, and continues to be transmitted along the silicon waveguide 820 to be connected to the multiplexer 720.

The other path of light output by the demultiplexer 710 is transmitted along the silicon waveguide 830 to the input of the second silicon ridge waveguide 4614, and then this path of light is coupled upward to the optical modulation region of the optical modulator 460 for signal modulation. The modulated optical signal is downwardly coupled back to the output of the second silicon ridge waveguide 4614, and continues to be transmitted along the silicon waveguide 840 to be connected to the multiplexer 720.

Two paths of modulated optical signals are respectively connected to the multiplexer 720, combined into one path of optical signal, and output.

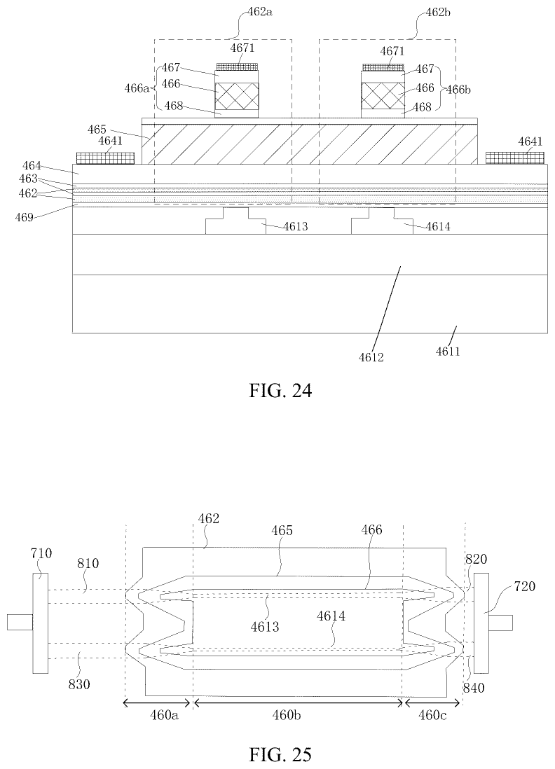

FIG. 23 is a perspective view of an optical modulator according to some embodiments of the present disclosure. FIG. 24 is a cross-sectional view of an optical modulator according to some embodiments of the present disclosure. As shown in FIG. 23 and FIG. 24, in some embodiments, taking the optical chip 400 as a hybrid integrated InP/Si photonic chip as an example, the hybrid integrated InP/Si photonic chip is internally provided with an optical modulator 460.

In some embodiments, the optical modulator 460 is a hybrid integrated InP/Si optical modulator.

The optical modulator 460 may include a silicon waveguide layer 461 located at the bottom, where the silicon waveguide layer 461 is the silicon waveguide of the optical modulator 460 itself, thereby fully utilizing the advantage of low transmission loss of the silicon waveguide.

The optical modulator 460 may include an InP modulation region located above the silicon waveguide layer 461, thereby fully utilizing the advantage of high modulation rate of the InP semiconductor material.

In some embodiments, the silicon waveguide layer 461 is implemented using silicon-on-insulator (SOI).

In some embodiments, the SOI waveguide includes: a bottom silicon layer 4611, a buried oxide layer 4612 located on an upper surface of the bottom silicon layer 4611, and a first silicon ridge waveguide 4613 and a second silicon ridge waveguide 4614 respectively located on both sides of an upper surface of the buried oxide layer 4612. Two paths of light to be modulated are transmitted respectively via the first silicon ridge waveguide 4613 and the second silicon ridge waveguide 4614, thereby avoiding mutual coupling between the two paths of light to be modulated. By way of example, the bottom silicon layer 4611 is a substrate layer.

By way of example, the buried oxide layer 4612 is a SiO₂ layer. Due to the large refractive index difference between silicon and SiO₂, the SOI waveguide has a strong optical field confinement capability, resulting in low optical transmission loss for the SOI waveguide.

By way of example, the first silicon ridge waveguide 4613 and the second silicon ridge waveguide 4614 are respective transmission layers for the two paths of light. Based on the low transmission loss of the ridge waveguide, a ridge waveguide structure is adopted in the present disclosure. It can be understood that, in some embodiments, a non-ridge waveguide structure may also be adopted.

In some embodiments, incident light of the MZ modulator is split into two paths by the demultiplexer 710 at the input.

The first output of the demultiplexer 710 is connected to the input of the first silicon ridge waveguide 4613 via the silicon waveguide 810 to receive one path of light output by the demultiplexer 710 and couple it into the first silicon ridge waveguide 4613.

The second output of the demultiplexer 710 is connected to the input of the second silicon ridge waveguide 4614 via the silicon waveguide 830 to receive the other path of light output by the demultiplexer 710 and couple it into the second silicon ridge waveguide 4614.

The two paths of light to be modulated that are coupled and transmitted to the first silicon ridge waveguide 4613 and the second silicon ridge waveguide 4614 are respectively coupled upward to the InP modulation region. After modulation is completed in the InP modulation region, they are downwardly coupled back to the outputs of the first silicon ridge waveguide 4613 and the second silicon ridge waveguide 4614, and then the two paths of modulated optical signals generated by modulation are respectively connected to the multiplexer 720 along the silicon waveguide 820 and the silicon waveguide 840, combined into one path of optical signal, and output.

In some embodiments, the InP modulation region, from bottom to top, includes: an N-type InP layer 462, located on an upper surface of the silicon waveguide layer 461; a stress confinement layer 463; an N—InP ohmic contact layer 464; a quantum well layer 465; a P-type InP layer 466; and a P—InP ohmic contact layer 467. In some embodiments, the N-type InP layer 462 is an N-type doped semiconductor, such as one doped with a pentavalent element.

The P-type InP layer 466 is a P-type doped semiconductor, such as one doped with a trivalent element.

The N-type InP layer 462 and the P-type InP layer 466 form a PN junction by doping with different impurity elements.

When no forward bias voltage is applied to the PN junction, the above-mentioned carrier motion is in an equilibrium state. When a forward bias voltage is applied to the PN junction, the equilibrium state of carrier motion is disrupted, thereby forming a conduction current. The formed conduction current is applied to the quantum well layer 465.

In some embodiments, an intrinsic i-InP layer 468 is formed below the P-type InP layer 466. The intrinsic i-InP layer 468 is undoped.

A depletion region exists at an interface between a P region and an N region in the PN junction, where the depletion region of the PN junction is narrow, and the carriers contain a diffusion component, which severely affects the modulation rate. By forming the intrinsic i-InP layer 468 in the middle of the PN junction, the width of the depletion region is increased, such that the carriers drift to the PN junction under the action of a strong electric field, thereby avoiding the impact of the diffusion component in the carriers on the optical modulator 460, and increasing the modulation rate.

In some embodiments, the growth material of the silicon waveguide layer 461 is silicon, and the InP modulation region is an InP region. Due to the significant difference in lattice constants between the silicon material and the InP semiconductor material, there is a large lattice mismatch between the two, which leads to a stress during epitaxial growth of the InP material on the silicon. The stress confinement layer 463 can confine the stress between the silicon material and the InP semiconductor material therein to prevent the stress from being transmitted upward to the quantum well layer 465, thereby protecting the quantum well layer 465.

In some embodiments, the quantum well layer 465 is an active region and a target layer for light to be modulated to reach, thereby achieving modulation in the quantum well layer 465. The quantum well material has a high refractive index, such that the optical signal can be well confined in the quantum well layer 465 longitudinally.

By controlling the variation of the externally applied electric field, carrier changes are induced to change the refractive index of the active quantum well layer 465. Since the change in the refractive index of the quantum well layer 465 is directly proportional to the phase change between the two modulation arms of the optical modulator 460, the phase difference between the two modulation arms can be adjusted by adjusting the refractive index of the quantum well layer 465.

The output light intensity varies with the phase difference between the two modulation arms, that is, the output light intensity is modulated by a modulated electrical signal. The modulated electrical signal is modulated into the output light intensity of the modulated optical signal, thereby achieving modulation.

The two paths of light to be modulated that are transmitted to the first silicon ridge waveguide 4613 and the second silicon ridge waveguide 4614 are respectively coupled upward into the quantum well layer 465. After modulation is completed in the quantum well layer 465, they are downwardly coupled back to the outputs of the first silicon ridge waveguide 4613 and the second silicon ridge waveguide 4614, and then the two paths of modulated optical signals generated by modulation are respectively connected to the multiplexer 720 along the silicon waveguide 820 and the silicon waveguide 840, combined into one path of optical signal, and output.

In some embodiments, in the InP modulation region, a corresponding region above the first silicon ridge waveguide 4613 is the first modulation arm 462a of the optical modulator 460, and a corresponding region above the second silicon ridge waveguide 4614 is the second modulation arm 462b of the optical modulator 460.

The quantum well layer 465 includes: a first modulation sub-region corresponding to the first modulation arm 462a, and a second modulation sub-region corresponding to the second modulation arm 462b. The first modulation sub-region modulates the light to be modulated that is output by the first silicon ridge waveguide 4613, and the second modulation sub-region modulates the light to be modulated that is output by the second silicon ridge waveguide 4614.

In some embodiments, the quantum well layer 465 is located between the N-type InP layer 462 and the P-type InP layer 466, where the N-type InP layer 462 and the P-type InP layer 466 confine the optical field vertically to confine the optical field within a vertical region of the quantum well layer 465. The optical field is confined upward by the P-type InP layer and downward by the N-type InP layer 462, thereby preventing divergence of the optical field and improving the optical coupling efficiency.

To enhance the optical confinement effect of the P-type InP layer 466, two paths of optical fields to be modulated are respectively confined in the first modulation sub-region and the second modulation sub-region of the quantum well layer 465. The intrinsic i-InP layer 468, the P-type InP layer 466, and the P—InP ohmic contact layer 467 are etched respectively to obtain a first P-type InP region 466a corresponding vertically to the first modulation sub-region and a second P-type InP region 466b corresponding vertically to the second modulation sub-region.

The first P-type InP region 466a and the second P-type InP region 466b protrude relative to the quantum well layer 465, thereby forming a ridge structure. For ease of description, the first P-type InP region 466a includes, from bottom to top: an intrinsic i-InP layer 468, a P-type InP layer 466, and a P—InP ohmic contact layer 467; and the second P-type InP region 466b includes, from bottom to top: an intrinsic i-InP layer 468, a P-type InP layer 466, and a P—InP ohmic contact layer 467.

In some embodiments, the surface of the P—InP ohmic contact layer 467 in the first P-type InP region 466a is provided with a P-type electrode 4671, and the surface of the P—InP ohmic contact layer 467 in the second P-type InP region 466b is provided with a P-type electrode 4671.

When the width of the N—InP ohmic contact layer 464 is greater than that of the quantum well layer 465, both ends of the N—InP ohmic contact layer 464 have blank spaces relative to the ends of the quantum well layer 465, such that N-type electrodes 4641 can be respectively formed at the both ends of the N—InP ohmic contact layer 464.

In some embodiments, the optical modulator 460 may include an intermediate bonding layer 469. The intermediate bonding layer 469 is located between the silicon waveguide layer 461 and the InP modulation region.

The growth material of the silicon waveguide layer 461 is silicon, and the InP modulation region is an InP region. Due to the significant difference in lattice constants between the silicon material and the InP semiconductor material, there is a large lattice mismatch between the two, which leads to a stress during epitaxial growth of the InP material on the silicon, thereby resulting in poor hybrid integration quality. Thus, an intermediate bonding layer 469 is formed between the silicon waveguide layer 461 and the InP modulation region.

The intermediate bonding layer 469 is located between the silicon material and the InP semiconductor material, where the bonding force between the intermediate bonding layer 469 and the silicon material and the bonding force between the intermediate bonding layer 469 and the InP semiconductor material, such as van der Waals force or chemical bonds, are used to bond the silicon material and the InP semiconductor material together, thereby achieving hybrid integration of the silicon material and the InP semiconductor material.

By way of example, the intermediate bonding layer 469 is a SiO₂ layer. SiO₂ has good hydrophilicity and can form stable covalent bonds at a lower temperature, thereby achieving high bonding strength and a good bonding interface.

In the present disclosure, the growth material of the silicon waveguide layer 461 in the optical modulator 460 is silicon, and the InP modulation region is an InP region, so the optical modulator 460 is a hybrid integrated InP/Si optical modulator.

The silicon waveguide and the InP waveguide are waveguides made of different materials and have different optical field modes, such that there is a significant mode discontinuity during optical coupling between the silicon waveguide and the InP waveguide, resulting in mode field mismatch and substantial coupling loss.

By way of example, when the light to be modulated is coupled upward from the first silicon ridge waveguide 4613 and the second silicon ridge waveguide 4614 to the quantum well layer 465, a certain loss is generated; and when the modulated optical signal is coupled downward from the quantum well layer 465 back to the first silicon ridge waveguide 4613 and the second silicon ridge waveguide 4614, a certain loss is further generated, thereby reducing the optical coupling efficiency.

FIG. 25 is a second top view of an optical modulator 460 according to some embodiments of the present disclosure. As shown in FIG. 25, in some embodiments, the optical modulator 460 sequentially includes, from bottom to top: a silicon waveguide layer 461, an N-type InP layer 462, a quantum well layer 465, and a P-type InP layer 466.

In some embodiments, to enhance the optical confinement effect of the P-type InP layer 466, two paths of optical fields to be modulated are respectively confined in the first modulation sub-region and the second modulation sub-region of the quantum well layer 465. The P-type InP layer 466 can be divided into two independent structures respectively corresponding to the two paths of light to be modulated, namely the first P-type InP region 466a and the second P-type InP region 466b as shown in FIG. 10.

In the present disclosure, the waveguide layers at one end of the optical modulator 460 facing the demultiplexer 710 and the other end of the optical modulator facing the multiplexer 720 are respectively provided with tapered structures, and the silicon waveguide and the InP-region waveguide at the same end have opposite tapering trends, thereby reducing mode discontinuity during optical coupling between the silicon waveguide and the InP waveguide, and achieving low-loss optical coupling between the silicon waveguide and the InP waveguide.

In a coupling region at one end of the optical modulator 460, namely one end facing the demultiplexer 710, the widths of the first silicon ridge waveguide 4613 and the second silicon ridge waveguide 4614 gradually narrow, and the widths of the waveguide layers in the InP region gradually widen, thereby squeezing optical field energy in the silicon ridge waveguide into the InP-region waveguide, and allowing more optical field energy to be modulated to be coupled upward to the InP region for modulation. When the refractive index of the silicon ridge waveguide is the same as that of the InP-region waveguide at a certain moment, the maximum optical coupling efficiency is achieved.

In a coupling region at the other end of the optical modulator 460, namely the end facing the multiplexer 720, the widths of the first silicon ridge waveguide 4613 and the second silicon ridge waveguide 4614 gradually widen, and the widths of the waveguide layers in the InP region gradually narrow, thereby squeezing optical field energy in the InP-region waveguide into the silicon ridge waveguide, and allowing more modulated optical field energy to be coupled downward into the silicon ridge waveguide for output. When the refractive index of the silicon ridge waveguide is the same as that of the InP-region waveguide at a certain moment, the maximum optical coupling efficiency is achieved.

In an intermediate coupling region of the optical modulator 460, no tapered structures are designed for the waveguides, thereby maintaining the optical field energy in this coupling region for modulation.

For ease of description, one end of the optical modulator 460 facing the demultiplexer 710 is referred to as a first end, and the other end of the optical modulator 460 facing the multiplexer 720 is referred to as a second end. The coupling region corresponding to the first end is referred to as a first tapered coupling region 460a, and the coupling region corresponding to the second end is referred to as a second tapered coupling region 460c.

In some embodiments, a waveguide tapered structure is formed at the first end of the optical modulator 460, such that the dimensions of the waveguide layers in the first tapered coupling region can be gradually changed to reduce the optical field confinement capability of the silicon ridge waveguide in the first tapered coupling region 460a and enhance that of the InP waveguide, and more optical fields to be modulated in the silicon ridge waveguide in the first tapered coupling region 460a can be squeezed into the InP modulation region for modulation.

In some embodiments, a waveguide tapered structure is formed at the second end of the optical modulator 460, such that the dimensions of the waveguide layers in the second tapered coupling region can be gradually changed to reduce the optical field confinement capability of the InP waveguide in the second tapered coupling region 460c and enhance that of the silicon ridge waveguide, and the modulated optical field within the InP modulation region in the second tapered coupling region 460c can be squeezed into the silicon ridge waveguide to output the modulated optical signal.

The waveguide layers at both ends of the optical modulator 460 are respectively provided with tapered structures, and the silicon waveguide and the InP-region waveguide in the coupling region at the same end have opposite tapering trends, such that the optical loss of coupling upward from the first silicon ridge waveguide 4613 and the second silicon ridge waveguide 4614 to the quantum well layer 465, and the optical loss of coupling downward from the quantum well layer 465 into the first silicon ridge waveguide 4613 and the second silicon ridge waveguide 4614 can be reduced, thereby achieving low-loss coupling.

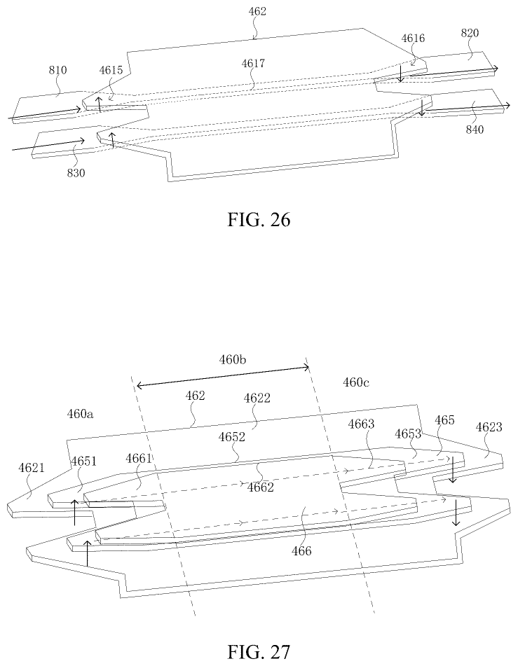

FIG. 26 is a first layered structure diagram of an optical modulator according to some embodiments of the present disclosure. FIG. 27 is a second layered structure diagram of an optical modulator according to some embodiments of the present disclosure. As shown in FIG. 26 and FIG. 27, the first silicon ridge waveguide 4613 and the second silicon ridge waveguide 4614 in the same layer, the N-type InP layer 462, the quantum well layer 465, and the P-type InP layer 466 are sequentially stacked.

In some embodiments, the N-type InP layer 462 has a large waveguide width to provide better support.

In some embodiments, incident light of the MZ modulator is split into two paths by the demultiplexer 710, so the demultiplexer 710 has two outputs. The optical modulator 460 correspondingly has two inputs and two outputs.

In some embodiments, the silicon waveguide layer 461 is provided with a silicon contraction region 4615 at one end facing the demultiplexer 710 to receive the two paths of light to be modulated, and a silicon expansion region 4616 at the other end facing the multiplexer 720 to couple the two paths of modulated optical signals.

In some embodiments, the N-type InP layer 462 is provided with a first InP expansion region 4621 at one end facing the demultiplexer 710 to couple the two paths of light to be modulated, and a first InP contraction region 4623 at the other end facing the multiplexer 720 to couple the two paths of modulated optical signals.

In some embodiments, the quantum well layer 465 is provided with a second InP expansion region 4651 at one end facing the demultiplexer 710 to couple the two paths of light to be modulated, and a second InP contraction region 4653 at the other end facing the multiplexer 720 to couple the two paths of modulated optical signals.

In some embodiments, the P-type InP layer 466 is provided with a third InP expansion region 4661 at one end facing the demultiplexer 710 to couple the two paths of light to be modulated, and a third InP contraction region 4663 at the other end facing the multiplexer 720 to couple the two paths of modulated optical signals.

The silicon contraction region 4615, the first InP expansion region 4621, the second InP expansion region 4651, and the third InP expansion region 4661 that correspond to one path of light to be modulated are stacked longitudinally in sequence to couple the light to be modulated in the silicon contraction region 4615 upward to the quantum well layer 465 for signal modulation.

The silicon expansion region 4616, the first InP contraction region 4623, the second InP contraction region 4653, and the third InP contraction region 4663 that correspond to one path of modulated optical signal are stacked longitudinally in sequence to couple the modulated optical signal generated by the quantum well layer via modulation downward to the silicon expansion region for output.

In some embodiments, the first silicon ridge waveguide 4613 and the second silicon ridge waveguide 4614 have the same structure. As described above, the silicon ridge waveguide includes a silicon slab with a large cross-sectional area and a silicon ridge with a small cross-sectional area. The silicon slab and the silicon ridge have the same tapered structure. The following provides an exemplary description of the tapered structure of the first silicon ridge waveguide 4613 and the second silicon ridge waveguide 4614 using the silicon slab as an example.

In some embodiments, the first silicon ridge waveguide 4613 is provided with a silicon contraction region 4615 at the input and a silicon expansion region 4616 at the output to enhance the coupling efficiency between the silicon waveguide and the InP waveguide. The first silicon ridge waveguide is provided with a silicon flat region 4617 in the middle.

The N-type InP layer 462 includes two symmetric sub-regions to couple two paths of optical signals respectively. The two symmetric sub-regions have the same structure. The N-type InP layer 462 has two ends corresponding to the two paths of light and is provided with a first InP expansion region 4621 at one end facing the demultiplexer 710, a first InP contraction region 4623 at the other end facing the multiplexer 720, and a first InP flat region 4622 in the middle.

The quantum well layer 465 is used to modulate the two paths of optical signals respectively. The quantum well layer 465 includes a first modulation sub-region and a second modulation sub-region that are arranged symmetrically to modulate the two paths of optical signals respectively. The first modulation sub-region and the second modulation sub-region have the same structure. The quantum well layer 465 has two ends corresponding to the two paths of light and is provided with a second InP expansion region 4651 at one end facing the demultiplexer 710, a second InP contraction region 4653 at the other end facing the multiplexer 720, and a second InP flat region 4652 in the middle. The second InP expansion region 4651 is a coupling structure at one end of the quantum well layer 465; the second InP contraction region 4653 is a coupling structure at the other end of the quantum well layer 465; and the second InP flat region 4652 is an effective modulation structure of the quantum well layer 465, where the light to be modulated is modulated in the second InP flat region 4652.

The P-type InP layer 466 has two ends corresponding to the two paths of light and is provided with a third InP expansion region 4661 at one end facing the demultiplexer 710, a third InP contraction region 4663 at the other end facing the multiplexer 720, and a third InP flat region 4662 in the middle.

The above-mentioned “contraction” means that the waveguide width gradually narrows in the direction from the demultiplexer 710 to the multiplexer 720. “Expansion” means that the waveguide width gradually widens in the direction from the demultiplexer 710 to the multiplexer 720. The meanings of the above-mentioned contraction regions and expansion regions all fall within the scope of this explanation.

In the coupling region of the optical modulator 460 facing the demultiplexer 710, the silicon contraction region 4615, the first InP expansion region 4621, the second InP expansion region 4651, and the third InP expansion region 4661 are stacked longitudinally in sequence.

In the coupling region at the output of the optical modulator 460, the silicon expansion region 4616, the first InP contraction region 4623, the second InP contraction region 4653, and the third InP contraction region 4663 are stacked longitudinally in sequence.

In the intermediate region of the optical modulator 460, the silicon flat region 4617, the first InP flat region 4622, the second InP flat region 4652, and the third InP flat region 4662 are stacked longitudinally in sequence.

The purpose of forming the above-mentioned contraction regions and expansion regions is to reduce mode discontinuity in the coupling region, while the purpose of forming the flat regions is to maintain the current optical field mode.

In some embodiments, the first tapered coupling region 460a of the optical modulator 460 includes, from bottom to top in sequence: a silicon contraction region 4615, a first InP expansion region 4621, a second InP expansion region 4651, and a third InP expansion region 4661. In the first tapered coupling region 460a, the width of the silicon waveguide gradually narrows, such that the effective refractive index of the silicon waveguide at the input gradually decreases, the optical wave confinement gradually weakens, and the optical field area gradually increases.

The first InP expansion region 4621, the second InP expansion region 4651, and the third InP expansion region 4661 are the structures of the waveguide layers in the InP region. In the first tapered coupling region 460a, the widths of the waveguide layers in the InP region gradually widen, such that the effective refractive indices of the waveguide layers in the InP region gradually increase, and the optical wave confinement is gradually enhanced. Consequently, in the first tapered coupling region 460a, the optical field is squeezed from the silicon waveguide into the InP region for signal modulation.

In the present disclosure, in the first tapered coupling region 460a of the optical modulator 460, the waveguides are provided with tapered structures, thereby reducing mode discontinuity between the silicon waveguide and the InP waveguide for the light to be modulated, and achieving low-loss coupling in this coupling region.

In some embodiments, the second tapered coupling region 460c of the optical modulator 460 includes, from bottom to top in sequence: a silicon expansion region 4616, a first InP contraction region 4623, a second InP contraction region 4653, and a third InP contraction region 4663.

In the second tapered coupling region 460c, the width of the silicon waveguide gradually widens, such that the effective refractive index of the silicon waveguide at the output gradually increases, and the optical wave confinement is gradually enhanced.

The first InP contraction region 4623, the second InP contraction region 4653, and the third InP contraction region 4663 are the structures of the waveguide layers in the InP region. In the second tapered coupling region 460c, the widths of the waveguide layers in the InP region gradually narrow, such that the effective refractive indices of the waveguide layers in the InP region gradually decrease, and the optical wave confinement gradually weakens. Consequently, in the second tapered coupling region 460c, the optical field is squeezed from the InP region into the silicon waveguide to transmit the modulated optical signal generated by modulation.

In the present disclosure, in the second tapered coupling region 460c of the optical modulator 460, the waveguides are provided with tapered structures, thereby reducing mode discontinuity between the silicon waveguide and the InP waveguide for the modulated optical signal, and achieving low-loss coupling in this coupling region.

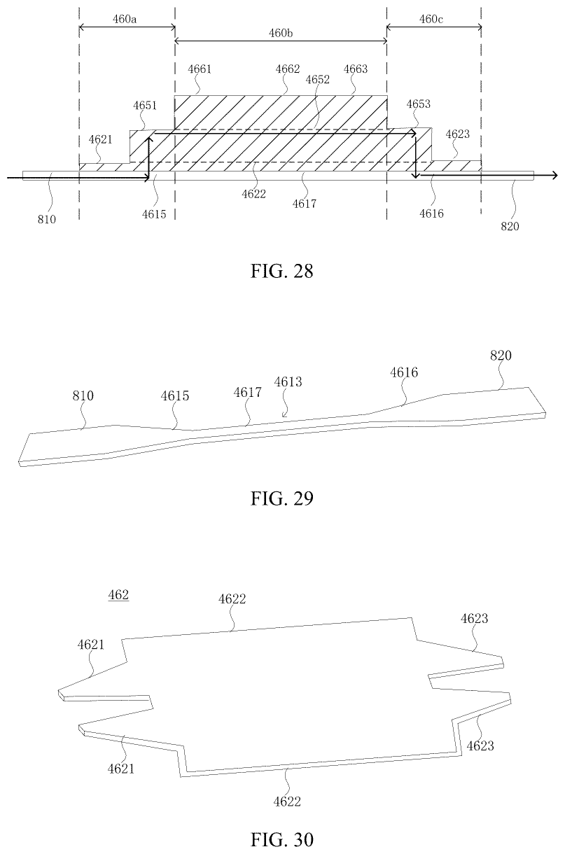

FIG. 28 is a schematic diagram of an optical path of an optical modulator according to some embodiments of the present disclosure. As shown in FIG. 28, the following provides an exemplary illustration of the optical path using one path of optical signal output by the demultiplexer 710 as an example.

The silicon flat region 4617, the first InP flat region 4622, the second InP flat region 4652, and the third InP flat region 4662, which are stacked longitudinally, form the optical modulation region 460b of the optical modulator 460. The second InP flat region 4652 is a structure that performs signal modulation substantially.

The silicon contraction region 4615, the first InP expansion region 4621, the second InP expansion region 4651, and the third InP expansion region 4661, which are stacked longitudinally, form the first tapered coupling region 460a.

The silicon expansion region 4616, the first InP contraction region 4623, the second InP contraction region 4653, and the third InP contraction region 4663, which are stacked longitudinally, form the second tapered coupling region 460c.

By forming the first tapered coupling region 460a at one end facing the demultiplexer 710, more optical field energy to be modulated is transferred from the silicon waveguide to the InP region for modulation.

By forming the second tapered coupling region 460c at the other end facing the multiplexer 720, more modulated optical field energy is released from the InP region into the silicon waveguide.

The optical modulation region 460b of the optical modulator 460 is in a flat state without tapering to ensure that the energy is maintained in this region.

The first tapered coupling region 460a is used to couple the light to be modulated upward to the optical modulation region 460b.

The second tapered coupling region 460c is used to couple the modulated optical signal downward from the optical modulation region 460b for output.

In the first tapered coupling region 460a, by gradually narrowing the width of the silicon waveguide and gradually widening the width of the InP waveguide, the light to be modulated is coupled upward from the silicon waveguide to the second InP flat region 4652 for signal modulation, thereby generating a modulated optical signal.

In the second tapered coupling region 460c, by gradually narrowing the width of the InP waveguide and gradually widening the width of the silicon waveguide, the modulated optical signal is coupled downward from the second InP flat region 4652 to the silicon waveguide for output of the modulated optical signal.

In some embodiments, one path of optical signal output by the demultiplexer 710 enters the silicon contraction region 4615 along the silicon waveguide 810, is sequentially coupled upward to the first InP expansion region 4621 and the second InP expansion region 4651, and is then transversely coupled to the second InP flat region 4652 in the same layer as the second InP expansion region 4651, where signal modulation is performed in the second InP flat region 4652.

The modulated optical signal is transversely coupled from the second InP flat region 4652 to the second InP contraction region 4653 in the same layer. The modulated optical signal is sequentially coupled downward from the second InP contraction region 4653 to the first InP contraction region 4623 and the silicon expansion region 4616, and then enters the silicon waveguide 820 in the same layer as the silicon expansion region 4616, such that the modulated optical signal is output along the silicon waveguide 820.

It can be understood that, in some embodiments, the first tapered coupling region 460a of the optical modulator 460 may also be in the form of a coupler independent of the optical modulator 460, that is, a coupler is disposed at one end of the optical modulator 460 facing the demultiplexer 710.

Similarly, the second tapered coupling region 460c of the optical modulator 460 may also be in the form of a coupler independent of the optical modulator 460, that is, the other coupler is disposed at the other end of the optical modulator 460 facing the multiplexer 720.

These two separate couplers have the same structure as the optical modulator 460, except that these two couplers are passive devices and do not require P-type and N-type electrodes.

FIG. 29 is a schematic diagram of tapering of a silicon waveguide according to some embodiments of the present disclosure. As shown in FIG. 29, in some embodiments, the silicon waveguide 810, the first silicon ridge waveguide 4613, and the silicon waveguide 820 correspond to one of the paths of light output by the demultiplexer 710.

In some embodiments, the first silicon ridge waveguide 4613 is provided with a silicon contraction region 4615 at the input, a silicon expansion region 4616 at the output, and a silicon flat region 4617 in the middle. The waveguide width at the position of the silicon flat region 4617 is the narrowest.

The silicon contraction region 4615 is used to squeeze the optical field to be modulated upward into the quantum well layer 465 by gradually narrowing the waveguide width, and the silicon expansion region 4616 is used to “attract” the modulated optical field within the quantum well layer 465 downward by gradually widening the waveguide width, thereby enhancing the optical coupling efficiency between the silicon waveguide and the InP waveguide.

FIG. 30 is a structural diagram of an N-type InP layer according to some embodiments of the present disclosure. As shown in FIG. 30, in some embodiments, both ends of the N-type InP layer 462 are respectively provided with tapered structures.

The N-type InP layer 462 includes two symmetric sub-regions with the same structure to transmit two paths of optical signals respectively.

The N-type InP layer 462 has two ends corresponding to the two paths of light and is provided with a first InP expansion region 4621 at one end facing the demultiplexer 710, a first InP contraction region 4623 at the other end facing the multiplexer 720, and a first InP flat region 4622 in the middle.

The first InP expansion region 4621 is used to attract the optical field to be modulated upward into the quantum well layer 465 by gradually widening the waveguide width, and the first InP contraction region 4623 is used to squeeze the modulated optical field within the quantum well layer 465 downward into the silicon waveguide for output by gradually narrowing the waveguide width, thereby enhancing the optical coupling efficiency between the silicon waveguide and the InP waveguide.

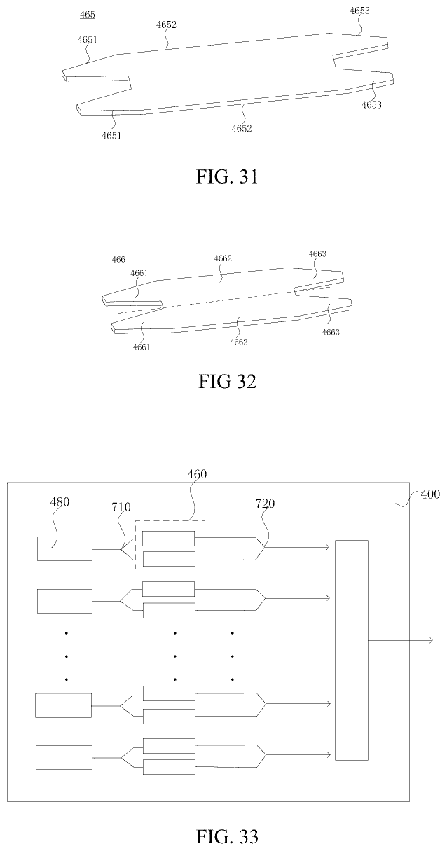

FIG. 31 is a structural diagram of a quantum well layer according to some embodiments of the present disclosure. As shown in FIG. 31, in some embodiments, the input and the output of the quantum well layer 465 are respectively provided with tapered structures.

The quantum well layer 465 includes a first modulation sub-region and a second modulation sub-region that are arranged symmetrically to modulate the two paths of optical signals respectively. The first modulation sub-region and the second modulation sub-region have the same structure.

The quantum well layer 465 has two ends corresponding to the two paths of light and is provided with a second InP expansion region 4651 at one end facing the demultiplexer 710, a second InP contraction region 4653 at the other end facing the multiplexer 720, and a second InP flat region 4652 in the middle.

The second InP expansion region 4651 is a coupling structure at one end of the quantum well layer 465; the second InP contraction region 4653 is a coupling structure at the other end of the quantum well layer 465; and the second InP flat region 4652 is an effective modulation structure of the quantum well layer 465 the light to be modulated is modulated in the second InP flat region 4652.

The second InP expansion region 4651 is used to attract the optical field to be modulated upward into the quantum well layer 465 by gradually widening the waveguide width, and the second InP contraction region 4653 is used to squeeze the modulated optical field within the quantum well layer 465 downward into the silicon waveguide for output by gradually narrowing the waveguide width, thereby enhancing the optical coupling efficiency between the silicon waveguide and the InP waveguide.

FIG. 32 is a structural diagram of a P-type InP layer according to some embodiments of the present disclosure. As shown in FIG. 32, in some embodiments, the P-type InP layer 466 has two ends corresponding to the two paths of light and is provided with a third InP expansion region 4661 at one end facing the demultiplexer 710, a third InP contraction region 4663 at the other end facing the multiplexer 720, and a third InP flat region 4662 in the middle.

The third InP expansion region 4661 is used to attract the optical field to be modulated upward into the quantum well layer 465 by gradually widening the waveguide width, and the third InP contraction region 4663 is used to squeeze the modulated optical field within the quantum well layer 465 downward into the silicon waveguide for output by gradually narrowing the waveguide width, thereby enhancing the optical coupling efficiency between the silicon waveguide and the InP waveguide.

In the present disclosure, as described above, the light source of the hybrid integrated InP/Si photonic chip may also adopt an internally integrated light source. The III-V material is a direct bandgap semiconductor material with strong gain characteristics, and therefore has excellent light-emitting properties, such as an InP laser. Thus, the InP laser is integrated into the hybrid integrated InP/Si photonic chip.

FIG. 33 is a schematic structural diagram of an optical chip with internally integrated modulators according to some embodiments of the present disclosure. As shown in FIG. 33, a laser 481 is integrated into the optical chip 400. By way of example, the laser 481 is an InP laser.

The laser 481 is integrated into the optical chip 400, and laser light output by the laser 481 is transmitted to the optical modulator 460 for signal modulation. The above-mentioned first tapered coupling region 460a and second tapered coupling region 460c can be formed at both ends of the optical modulator 460 respectively.

The light output by the laser 481 is transmitted to the demultiplexer 710, the two paths of light output by the demultiplexer 710 are respectively coupled into the optical modulator 460 for signal modulation, and the two paths of optical signals generated by modulation are coupled into the multiplexer 720. The multiplexer 720 combines the two paths of modulated optical signals into one path of modulated optical signal and outputs it.

The optical chip 400 integrates both the laser 481 and the optical modulator 460 therein, thereby having both light emission and signal modulation functions and completing light emission and signal modulation in the same chip.

In the present disclosure, the lasers corresponding to the channels are integrated into the hybrid integrated optical chip to enhance integration. Furthermore, since each channel corresponds to one laser, the local power density and the thermal stress can be reduced, thereby improving the reliability of the hybrid integrated optical chip and making it suitable for multi-channel transmission.

FIG. 34 is a schematic cross-sectional view of a laser according to some embodiments of the present disclosure. FIG. 35 is a schematic partial view of a laser according to some embodiments of the present disclosure. As shown in FIGS. 34 and 35, in some embodiments, the layer structures of the laser 481 and the growth materials of the layer structures of the laser 481 are the same.

In some embodiments, the laser 481 is a hybrid integrated InP/Si laser.

In some embodiments, the laser 481 may include a waveguide layer located at the bottom. By way of example, the waveguide layer is a silicon waveguide layer 4801, and the silicon waveguide layer 4801 is the silicon waveguide of the laser 481 itself, thereby fully utilizing the advantage of low transmission loss of the silicon waveguide.

In some embodiments, the laser 481 may include an InP light-emitting region located above the silicon waveguide layer 4801, thereby fully utilizing the gain characteristics of the InP semiconductor material.

In some embodiments, the silicon waveguide layer 4801 is implemented using silicon-on-insulator (SOI).

In some embodiments, the SOI waveguide includes: a bottom silicon layer 481a, a buried oxide layer 481b located on an upper surface of the bottom silicon layer 481a, and a silicon ridge waveguide 481c located on an upper surface of the buried oxide layer 481b.

By way of example, the bottom silicon layer 481a is a substrate layer.

By way of example, the buried oxide layer 481b is a SiO₂ layer. Due to the large refractive index difference between silicon and SiO₂, the SOI waveguide has a strong optical field confinement capability, resulting in low optical transmission loss for the SOI waveguide.

Based on the low transmission loss of the ridge waveguide, a ridge waveguide structure is adopted in the present disclosure. It can be understood that, in some embodiments, a non-ridge waveguide structure may also be adopted.

The laser 481 provided in the present disclosure can be understood with reference to the hierarchical structure of the laser in the above-mentioned embodiments. Certainly, for a more specific understanding of the layer structures of the laser 481, in some embodiments, the InP light-emitting region includes, from bottom to top: an N-type InP layer 482, located on the upper surface of the silicon waveguide layer 4801; a stress confinement layer 483; an N—InP ohmic contact layer 484; a quantum well layer 485; a P-type InP layer 486; and a P—InP ohmic contact layer 4862.

In some embodiments, the N-type InP layer 482 is an N-type doped semiconductor, such as one doped with a pentavalent element.

The P-type InP layer 486 is a P-type doped semiconductor, such as one doped with a trivalent element.

The N-type InP layer 482 and the P-type InP layer 486 form a PN junction by doping with different impurity elements.

In some embodiments, when a PN junction is formed, the concentration difference of carriers leads to diffusion motion. The result of carrier diffusion is that the P-type InP layer 486 contains holes and negative ions, and the N-type InP layer 482 contains electrons and positive ions. Based on the charge principle, holes are driven downward into the quantum well layer 485, and electrons are driven upward into the quantum well layer 485.

In the quantum well layer 485, stimulated radiation induces the recombination of discrete electron-hole pairs to generate photons, thereby effectively converting electrically injected carriers into photons and producing gain light. The photons generated by recombination in the quantum well layer 485 are reflected by a resonant cavity or a distributed feedback grating to form positive feedback, thereby generating lasing light.

In some embodiments, a grating layer 488 is further formed on the surface of the silicon ridge waveguide 481c to enable the laser 481 to emit light with a specific wavelength. By way of example, the grating layer 488 is a Bragg grating.

In some embodiments, by changing the current injected into the grating layer 488, the effective refractive index of the grating layer 488 can be changed, thereby altering the resonant lasing wavelength of the laser 481 to achieve specific wavelength selection.

In some embodiments, an undoped intrinsic i-InP layer 4861 is formed below the P-type InP layer 486.

A depletion region exists at an interface between a P region and an N region in the PN junction, where the depletion region of the PN junction is narrow, and the carriers contain a diffusion component, which severely affects the modulation rate. By forming the intrinsic i-InP layer 4861 in the middle of the PN junction, the width of the depletion region is increased, such that the carriers drift to the PN junction under the action of a strong electric field, thereby avoiding the impact of the diffusion component in the carriers on the laser 481, and increasing the modulation rate.

In some embodiments, the growth material of the silicon waveguide layer 4801 is silicon, and the InP light-emitting region is an InP region. Due to the significant difference in lattice constants between the silicon material and the InP semiconductor material, there is a large lattice mismatch between the two, which leads to a stress during epitaxial growth of the InP material on the silicon. The stress confinement layer 483 can confine the stress between the silicon material and the InP semiconductor material therein to prevent the stress from being transmitted upward to the quantum well layer 485, thereby protecting the quantum well layer 485.

In some embodiments, the quantum well layer 485 is an active region and a target layer for carriers to reach, thereby enabling recombination in the quantum well layer 485 to generate photons. The quantum well material has a high refractive index, such that the optical signal can be well confined in the quantum well layer 485 longitudinally.

In some embodiments, the surface of the P—InP ohmic contact layer 4862 is provided with a P-type electrode 487a.

When the width of the N—InP ohmic contact layer 484 is greater than that of the quantum well layer 485, both ends of the N—InP ohmic contact layer 484 have blank spaces relative to the ends of the quantum well layer 485, such that N-type electrodes 487b can be respectively formed at the both ends of the N—InP ohmic contact layer 484.

In some embodiments, the laser 481 may include an intermediate bonding layer 489. The intermediate bonding layer 489 is located between the silicon waveguide layer 4801 and the InP light-emitting region.

The growth material of the silicon waveguide layer 4801 is silicon, and the InP modulation region is an InP region. Due to the significant difference in lattice constants between the silicon material and the InP semiconductor material, there is a large lattice mismatch between the two, which leads to a stress during epitaxial growth of the InP material on the silicon, thereby resulting in poor hybrid integration quality. Thus, an intermediate bonding layer 489 is formed between the silicon waveguide layer 4801 and the InP light-emitting region.

The intermediate bonding layer 489 is located between the silicon material and the InP semiconductor material, where the bonding force between the intermediate bonding layer 489 and the silicon material and the bonding force between the intermediate bonding layer 489 and the InP semiconductor material, such as van der Waals force or chemical bonds, are used to bond the silicon material and the InP semiconductor material together, thereby achieving hybrid integration of the silicon material and the InP semiconductor material.

By way of example, the intermediate bonding layer 489 is a SiO₂ layer. SiO₂ has good hydrophilicity and can form stable covalent bonds at a lower temperature, thereby achieving high bonding strength and a good bonding interface.

In some embodiments, the optical confinement factor of the silicon waveguide layer 4801 is greater than that of the quantum well layer 485, so the optical field within the quantum well layer 485 is large and can then be coupled downward into the silicon waveguide layer 4801.

In some embodiments, the optical field generated by the quantum well layer 485 is large and can be coupled downward into the silicon waveguide layer 4801. By way of example, when the propagation constant of the quantum well layer 485 is the same as that of the silicon waveguide layer 4801, the coupling efficiency between the quantum well layer 485 and the silicon waveguide layer 4801 is high.

In some embodiments, the silicon waveguide layer 4801 and the quantum well layer 485 can be designed as waveguides with opposite tapering trends. When their effective refractive indices are the same after tapering, that is, when their transmission constants are the same, the coupling efficiency between the two is maximized.

In some embodiments, the laser 481 emits light downward from the quantum well layer 485, which is then horizontally output through the silicon waveguide layer 4801.

In some embodiments, the laser light output by the silicon waveguide layer 4801 is laser light that does not carry signals, and the silicon waveguide layer 4801 is coupled to the demultiplexer 710, thereby transmitting the laser light output by the laser 481 to the demultiplexer 710. The demultiplexer 710 splits the laser light into two paths of light, which are respectively transmitted to the optical modulator 460 for signal modulation.

In some embodiments, based on the above-mentioned laser, the above-mentioned laser 481 can be integrated into the hybrid integrated photonic chip, so the hybrid integrated photonic chip includes the laser 481, the demultiplexer 710, the optical modulator 460, and the multiplexer 720.

In some embodiments, the demultiplexer 710 is disposed on the light output path of the laser 481 to receive the light output by the waveguide layer of the laser 481 and split the light into two paths of light to be modulated. The optical modulator 460 is disposed on the light output path of the demultiplexer 710 to receive and modulate the two paths of light to be modulated. The multiplexer 720 is disposed on one side of the optical modulator 460 and configured to combine the two paths of modulated optical signals generated by the optical modulator 460 via modulation.

In some embodiments, the optical modulator 460 is the above-mentioned modulator 460 provided with the first tapered coupling region 460a and the second tapered coupling region 460c at both ends, so its structure will not be described.

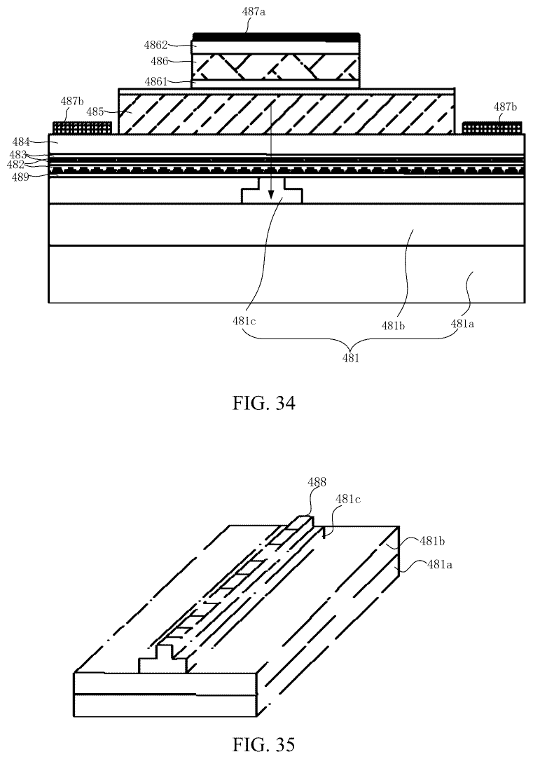

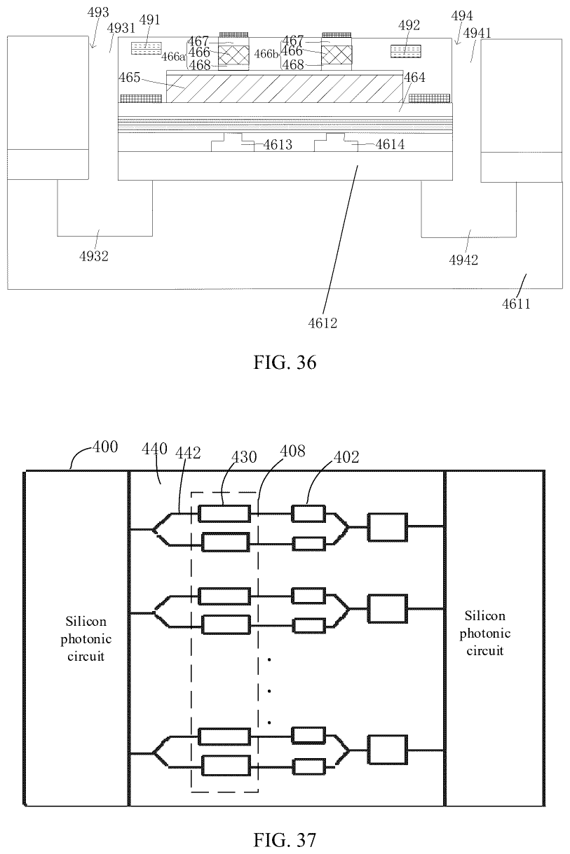

FIG. 36 is a schematic structural diagram of an optical modulator with internally integrated heaters according to some embodiments of the present disclosure. As shown in FIG. 36, a first heating part 491 and a second heating part 492 are respectively formed on both sides of the optical modulator 460. The above-mentioned first tapered coupling region 460a and second tapered coupling region 460c can be formed at both ends of the optical modulator 460 respectively.

In some embodiments, a first heating part 491 and a second heating part 492 are respectively formed on both sides of the P-type InP layer 466.

In some embodiments, a first heating part 491 is formed on one side of the first P-type InP region 466a, and a second heating part 492 is formed on one side of the second P-type InP region 466b. It should be noted that the arrangement of the first heating part and the second heating part here has the same effect and method as that of the heating parts in the InP modulation region in the above-mentioned embodiments.

In some embodiments, the hybrid integrated photonic chip undergoes temperature regulation via a TEC to maintain its operating temperature within a certain range. However, temperature control using the TEC results in high power consumption. In the present disclosure, since the InP semiconductor material is more sensitive to temperature than the Si-based material, temperature regulation is performed on the local region, namely the first P-type InP region 466a and the second P-type InP region 466b of the optical chip, rather than the entire optical chip, thereby enabling the optical chip to operate within a certain temperature range while reducing power consumption.

In the present disclosure, since the InP semiconductor material is more sensitive to temperature than the Si material, temperature regulation is performed on the local region of the optical chip, rather than the entire optical chip, thereby enabling the optical chip to operate within a certain temperature range. The purpose of regulating temperature of the entire region of the optical chip is achieved, thereby reducing power consumption.

The heat generated by the first heating part 491 heats the first P-type InP region 466a, and the heat generated by the second heating part 492 heats the second P-type InP region 466b, thereby heating the InP modulation regions respectively. By regulating the temperature of the InP modulation region, the temperature of the entire optical chip is regulated.

Temperature regulation is performed on the local region, namely the InP modulation region of the optical chip via the first heating part 491 and the second heating part 492, thereby enabling the optical chip to operate within a certain temperature range in a low-power mode. In addition, by regulating the temperature of the InP modulation region, the thermal stress during bonding between the InP modulation region and the Si-based substrate can be reduced, thereby improving the reliability and modulation rate of the optical modulator 460.

The first heating part 491 is disposed adjacent to the first P-type InP region 466a. The temperature of the first P-type InP region 466a is regulated by the first heating part 491 to regulate the temperature of the local region of the optical chip, thereby maintaining the entire region of the optical chip within a certain temperature range.

The second heating part 492 is disposed adjacent to the first P-type InP region 466a. The temperature of the first P-type InP region 466a is regulated by the second heating part 492 to regulate the temperature of the local region of the optical chip, thereby maintaining the entire region of the optical chip within a certain temperature range.

In some embodiments, a temperature sensor is embedded in the Si-based platform to monitor the temperature of the InP modulation region in real time. The temperature of the InP modulation region is collected in real time via the temperature sensor, thereby enabling real-time temperature regulation of the InP modulation region and achieving closed-loop control of temperature regulation.

In some embodiments, the first heating part 491 and the second heating part 492 may be in the form of heating resistors. The heating resistors are used to heat the first P-type InP region 466a and the second InP region 466b, respectively.

In some embodiments, a metal via hole is formed in the layer where the first heating part 491 and the second heating part 492 are located, to achieve a power supply connection between the first heating part 491 and the second heating part 492. The metal via hole is connected to a power supply metal region of the optical chip, thereby heating the first heating part 491 and the second heating part 492.

In some embodiments, the region where the first heating part 491 and the second heating part 492 are located is epitaxially grown from a SiO₂ material, and the bottom silicon layer 4611 is epitaxially grown from a Si material. The thermal conductivity of the Si material is greater than that of the SiO₂ material, that is, the thermal conductivity of the bottom silicon layer 4611 is greater than that of the region where the heating parts are located. Thus, the heat generated by the first heating part 491 and the second heating part 492 will be conducted downward to the bottom silicon layer 4611, thereby reducing the efficiency of temperature regulation.

In some embodiments, a first thermal isolation part 493 is formed on one side of the first heating part 491. The first thermal isolation part 493 penetrates downward to the bottom silicon layer 4611 to reduce the heat conducted downward from the first heating part 491 to the bottom silicon layer 4611.

A second thermal isolation part 494 is formed on one side of the second heating part 492. The second thermal isolation part 494 penetrates downward from the cladding layer 414 to the bottom silicon layer 4611 to reduce the heat conducted downward from the second heating part 492 to the bottom silicon layer 4611.

In some embodiments, the first thermal isolation part 493 and the second thermal isolation part 494 may be in the form of groove-type structures. The first thermal isolation part 493 and the second thermal isolation part 494 are obtained by hollowing out downward. The first thermal isolation part 493 and the second thermal isolation part 494 extend downward to the bottom silicon layer 4611. A corresponding lower region of the first heating part 491 is not hollowed out to ensure the supporting strength of the first heating part 491. A corresponding lower region of the second heating part 492 is not hollowed out to ensure the supporting strength of the second heating part 492.

The medium in the first thermal isolation part 493 and the second thermal isolation part 494 is air, with an extremely low thermal conductivity lower than that of the SiO₂ material and that of the InP material. Thus, the amount of heat generated by the first heating part 491 and the second heating part 492 that is conducted downward is very small, and the first thermal isolation part 493 and the second thermal isolation part 494 can block a path of downward heat conduction. Thus, the heat generated by the first heating part 491 and the second heating part 492 can be well concentrated near the first P-type InP region 466a and the second P-type InP region 466b, thereby improving the efficiency of temperature regulation.

In some embodiments, the first thermal isolation part 493 includes a first connection slot 4931 and a second connection slot 4932. The first connection slot 4931 extends downward to the bottom silicon layer 4611 and partially hollows out the bottom silicon layer 4611. The second connection slot 4932 extends horizontally to expand the hollowed-out range, thereby increasing the thermal isolation area.

The second thermal isolation part 494 includes a third connection slot 4941 and a fourth connection slot 4942. The third connection slot 4941 extends downward to the bottom silicon layer 4611 and partially hollows out the bottom silicon layer 4611. The fourth connection slot 4942 extends horizontally to expand the hollowed-out range, thereby increasing the thermal isolation area.

By way of example, the first connection slot 4931 is formed by etching downward, and then the etching is continued with an expanded range to form the second connection slot 4932. By way of example, the final shape formed by the first thermal isolation part 493 and the second thermal isolation part 494 may be irregular or regular.

In the present disclosure, by forming the first thermal isolation part 493 and the second thermal isolation part 494 in the Si-based platform to block the downward conduction path of the heat generated by the first heating part 491 and the second heating part 492, the heat is confined near the first P-type InP region 466a and the second P-type InP region 466b to prevent downward conduction of the heat, thereby improving the efficiency of temperature regulation.

In some embodiments, the optical chip 400 is a silicon photonic chip. However, the basic characteristics of the silicon material result in defects such as low modulation efficiency, large capacitance, limited bandwidth, and high optical loss in the implementation of the optical modulator. Since silicon photonic phase modulators operate based on carriers, the transmission rate per channel in current long-distance 400G optical modules can only reach 50-60 Gbaud. In next-generation optical modules supporting 1.6-3.2T PAM short-distance transmission and 800G-3.2T coherent long-distance transmission, the transmission rate per channel is required to exceed 100 Gbaud, which in turn requires the modulation rate of silicon photonic phase modulators to exceed 100 Gbaud. However, when the modulation rate of silicon photonic phase modulators approaches 100 Gbaud, the driver has high output voltage swing and high power, making it unsuitable for optical modules.

In some embodiments, the optical chip 400 is a hybrid InP/Si photonic chip.

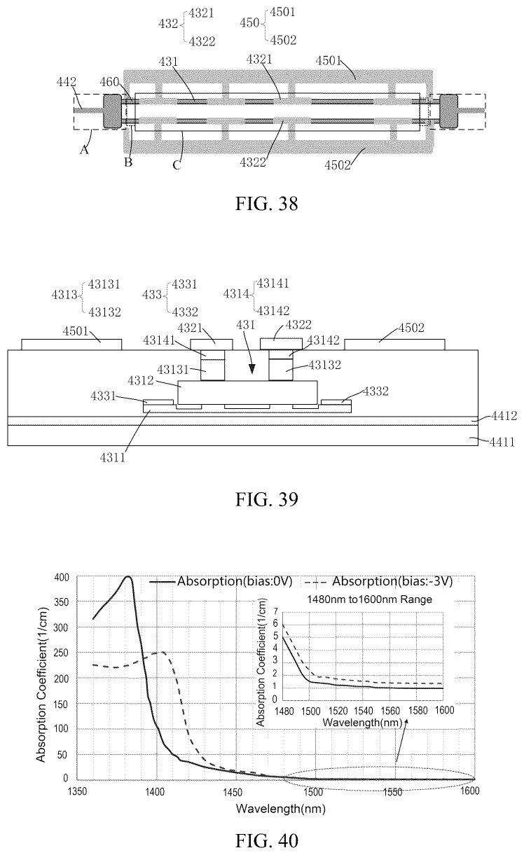

FIG. 37 is a schematic layout diagram of a hybrid InP/Si photonic chip according to some embodiments. FIG. 38 is a schematic partial view of a hybrid InP/Si photonic chip according to some embodiments. As shown in FIG. 37 and FIG. 38, the hybrid InP/Si photonic chip includes a plurality of channels. Each channel includes an InP phase modulator 430 and a thermal phase adjuster 402. The InP phase modulator 430 is made of an InP material, and the thermal phase adjuster 402 is made of a silicon material. The InP phase modulator 430 and the thermal phase adjuster 402 are connected to each other by a silicon waveguide to form a high-traveling-wave MZM. The hybrid InP/Si photonic chip provided in the present disclosure achieves hybrid integration of the Si-based material and the InP material, where the InP material provides high-speed modulation, and the Si material provides a highly integrated silicon photonic circuit, enabling the optical chip 400 to have the high-speed modulation characteristics of the InP material and meet the requirement for high-baud-rate modulation.

In some embodiments, the indium phosphide (InP) modulator is an InP-based MZ modulator. The MZ modulator is a modulator based on an electro-optic effect. The electro-optic effect refers to the change in the refractive index of a material induced by an externally applied electric field (i.e., an external power supply).

In some embodiments, the InP-based material is bonded to the Si-based material, and then the InP phase modulator, the silicon photonic circuit, and the like are fabricated on the bonded materials. There is a significant coefficient of thermal expansion (CTE) mismatch between an InP-based material platform and a silicon-based photonic material platform, resulting in a thermal stress. The InP-based material is a brittle material, so any mechanical and thermal stress will cause reliability problems caused by temperature and aging.

In some embodiments, the hybrid InP/Si photonic chip may include an InP region 408. By way of example, as shown in FIG. 38, the region C is the InP region 408. The waveguide in the region C may include an InP modulation waveguide.

In some embodiments, the hybrid InP/Si photonic chip may include a Si platform 440. The InP region 408 can be located in the Si platform 440, such that the Si platform 440 wraps around the InP region 408 from the front, back, left, right, and bottom directions of the InP region 408. Specifically, this can be understood with reference to the above-mentioned embodiments.

In some embodiments, the Si platform 440 may include a region A. A waveguide can be disposed on the region A. The waveguide on the region A may be a silicon waveguide 422.

In some embodiments, the Si platform 440 may include a region B. An optical coupler 407 can be disposed on the region B.

A radio frequency pad can be disposed on one side of the InP region 408. The radio frequency pad can be located on the Si platform 440. The radio frequency pad can be electrically connected to the driver to input a radio frequency signal. The radio frequency signal is a modulated signal.

An InP phase modulator 430 is disposed in the InP region 408. The InP phase modulator 430 may include an indium phosphide (InP) modulation waveguide 431. The InP modulation waveguide 431 can be located in the InP region 408.

A radio frequency traveling waveguide 450 can be disposed at the top of the hybrid InP/Si photonic chip. One end of the radio frequency traveling waveguide 450 can be connected to the radio frequency pad. The radio frequency traveling waveguide 450 can extend above the InP modulation waveguide 431 and span across the InP region 408 to the other side of the InP region 408, thereby coupling the radio frequency signal to the InP modulation waveguide 431.

The InP phase modulator 430 may include a radio frequency electrode 432. The radio frequency electrode 432 can be located in the InP region 408. The radio frequency electrode 432 can be disposed above the InP modulation waveguide 431. By way of example, multiple pairs of radio frequency electrodes 432 are disposed above the InP modulation waveguide 431, and each pair of radio frequency electrodes 432 is connected to the radio frequency traveling waveguide 450.

In the InP phase modulator 430, one InP-MQW optical waveguide can achieve high-speed modulation with excellent quantum confinement effects, and enable high bandwidth of an InP-based traveling-waveguide MZM, thereby meeting the high-rate requirement of the optical module.

The InP region 408 is a restricted region in the hybrid circuit layout of the hybrid InP/Si photonic chip, and no pads or other devices requiring bonding are disposed in the InP region 408 to avoid any stress caused by bonding, mechanical factors, and thermal effects, thereby eliminating the problems caused by temperature and aging.

In some embodiments, the radio frequency traveling waveguide 450 may include a first radio frequency traveling waveguide 4501. The first radio frequency traveling waveguide 4501 can extend from one side of the InP region 408 to the other side of the InP region 408. The middle of the first radio frequency traveling waveguide 4501 can be located above the edge of one side of the InP modulation waveguide 431.

In some embodiments, the radio frequency traveling waveguide 450 may include a second radio frequency traveling waveguide 4502. The second radio frequency traveling waveguide 4502 can extend from one side of the InP region 408 to the other side of the InP region 408. The middle of the second radio frequency traveling waveguide 4502 can be located above the edge of the other side of the InP modulation waveguide 431.

In some embodiments, each pair of radio frequency electrodes 432 may include a first radio frequency electrode 4321. The first radio frequency electrode 4321 can be located above the InP modulation waveguide 431. The first radio frequency electrode 4321 can be electrically connected to the first radio frequency traveling waveguide 4501.

In some embodiments, each pair of radio frequency electrodes 432 may include a second radio frequency electrode 4322. The second radio frequency electrode 4322 can be located above the InP modulation waveguide 431. The second radio frequency electrode 4322 can be electrically connected to the second radio frequency traveling waveguide 4502.

The first radio frequency electrode 4321 and the second radio frequency electrode 4322 have a gap therebetween and are located between the first radio frequency traveling waveguide 4501 and the second radio frequency traveling waveguide 4502. By way of example, the first radio frequency electrode 4321 and the second radio frequency electrode 4322 are both in a uniform thin strip shape. Certainly, the embodiments of the present application are not limited thereto.

FIG. 39 is a first cross-sectional view of a hybrid InP/Si photonic chip according to some embodiments. FIG. 39 shows a cross-sectional structure of a hybrid InP/Si photonic chip in an InP region, with the cross section taken through the InP region. As shown in FIG. 39, in some embodiments, the InP region may include a modulation waveguide. The modulation waveguide may include an InP modulation waveguide 431. A silicon modulation waveguide can be disposed below the InP modulation waveguide. The silicon modulation waveguide can couple light to the InP waveguide 431. The width of the silicon modulation waveguide is much smaller than that of the InP modulation waveguide 431.

As shown in FIG. 39, the InP modulation waveguide 431 may include a first modulation waveguide layer 4311. The first modulation waveguide layer 4311 can be mainly made of an N-type doped InP material, such that the first modulation waveguide layer 4311 is an n-InP modulation waveguide layer. A silicon modulation waveguide can be disposed below the first modulation waveguide layer 4311, but the width of the silicon modulation waveguide is much smaller than that of the first modulation waveguide layer 4311.

One end of an upper portion of the first modulation waveguide layer 4311 can be provided with an N electrode 433. The N electrode 433 can be in contact connection with an upper surface of the first modulation waveguide layer 4311. The N electrode 433 can be connected to a positive electrode of the external power supply, thereby supplying power to the N electrode 433.

The N electrode 433 may include a first N electrode 4331. The first N electrode 4331 can be located at a left end of the upper portion of the first modulation waveguide layer 4311. The N electrode 433 may include a second N electrode 4332. The second N electrode 4332 can be located at a right end of the upper portion of the first modulation waveguide layer 4311.

As shown in FIG. 39, the InP modulation waveguide 431 may include a second modulation waveguide layer 4312. The second modulation waveguide layer 4312 can be located above the first modulation waveguide layer 4311. A lower surface of the second modulation waveguide layer 4312 can be in contact connection with the upper surface of the first modulation waveguide layer 4311, such that light can be coupled between the second modulation waveguide layer 4312 and the first modulation waveguide layer 4311. The second modulation waveguide layer 4312 can be mainly made of a multilayer quantum well material such as InGaAsP or InAlGaAs, such that the second modulation waveguide layer 4312 is a quantum well modulation waveguide layer.

In some embodiments, the second modulation waveguide layer 4312 may include a fifth sub-modulation waveguide layer. The fifth sub-modulation waveguide layer can be located above the first modulation waveguide layer 4311. A lower surface of the fifth sub-modulation waveguide layer can be in contact connection with the upper surface of the first modulation waveguide layer 4311, such that light can be coupled between the fifth sub-modulation waveguide layer and the first modulation waveguide layer 4311.

In some embodiments, the second modulation waveguide layer 4312 may include a sixth sub-modulation waveguide layer. The sixth sub-modulation waveguide layer can be located above the first modulation waveguide layer 4311. A lower surface of the sixth sub-modulation waveguide layer can be in contact connection with the upper surface of the first modulation waveguide layer 4311, such that light can be coupled between the sixth sub-modulation waveguide layer and the first modulation waveguide layer 4311.

There may be a gap between the fifth sub-modulation waveguide layer and the sixth sub-modulation waveguide layer.

The second modulation waveguide layer 4312 may include a plurality of quantum wells. The number of quantum wells in the second modulation waveguide layer 4312 may be greater than a fifth preset value. By way of example, the fifth preset value may be 40, and the number of quantum wells in the second modulation waveguide layer 4312 is at least 40.

The greater the number of quantum wells is, the higher the refractive index of the quantum well modulation layer is. Δφ=2πΔnL/λ, where Δφ is a phase difference between two branches, Δn is the refractive index of the quantum well modulation layer, L is the length of the optical waveguide, namely the length of the InP modulation waveguide, and λ is the wavelength of light.

Since Δφ=2πΔnL/λ, when the phase difference Δφ remains unchanged, the higher the refractive index Δn of the quantum well modulation waveguide layer is, the shorter the length L of the InP modulation waveguide is. The shorter the length L of the InP modulation waveguide is, the higher the modulation bandwidth is. Therefore, the inclusion of the plurality of quantum wells in the second modulation waveguide layer 4312 can increase the refractive index of the quantum well modulation waveguide layer, thereby reducing the length of the InP modulation waveguide and increasing the modulation bandwidth.

Due to the low conductivity of the second modulation waveguide layer 4312, most of the electrical signal is concentrated in the second modulation waveguide layer 4312.

As shown in FIG. 39, the InP modulation waveguide 431 may include a third modulation waveguide layer 4313. The third modulation waveguide layer 4313 can be located above the second modulation waveguide layer 4312. A lower surface of the third modulation waveguide layer 4313 can be in contact connection with an upper surface of the second modulation waveguide layer 4312, such that the electrical signal is transmitted via the third modulation waveguide layer 4313 to the second modulation waveguide layer 4312. The third modulation waveguide layer 4313 may be mainly made of a P-type doped InP material, such that the third modulation waveguide layer 4313 is a p-InP modulation waveguide layer.

In some embodiments, the third modulation waveguide layer 4313 may include a first sub-modulation waveguide layer 43131. The first sub-modulation waveguide layer 43131 can be located above the first sub-modulation waveguide layer. A lower surface of the first sub-modulation waveguide layer 43131 can be in contact connection with a lower surface of the first sub-modulation waveguide layer, such that the electrical signal is transmitted via the first sub-modulation waveguide layer 43131 to the first sub-modulation waveguide layer, namely the second modulation waveguide layer 4312.

In some embodiments, the third modulation waveguide layer 4313 may include a second sub-modulation waveguide layer 43132. The second sub-modulation waveguide layer 43132 can be located above the second sub-modulation waveguide layer. A lower surface of the second sub-modulation waveguide layer 43132 can be in contact connection with an upper surface of the second sub-modulation waveguide layer, such that the electrical signal is transmitted via the second sub-modulation waveguide layer 43132 to the second sub-modulation waveguide layer, namely the second modulation waveguide layer 4312.

There may be a gap between the second sub-modulation waveguide layer 43132 and the first sub-modulation waveguide layer 43131, such that the electrical signal is transmitted to the second modulation waveguide layer 4312 through the first sub-modulation waveguide layer 43131 and the second sub-modulation waveguide layer 43132.

The first modulation waveguide layer 4311, the second modulation waveguide layer 4312, and the third modulation waveguide layer 4313 form a PIN junction. The PIN junction includes a depletion region (an i-region).

The depletion region may include a second modulation waveguide layer 4312 (i.e., a quantum well modulation waveguide layer), but is not limited to the second modulation waveguide layer 4312. The depletion region includes not only the second modulation waveguide layer 4312 but also part of the first modulation waveguide layer 4311 and part of the third modulation waveguide layer 4313.

As shown in FIG. 39, the InP modulation waveguide 431 may include a fourth modulation waveguide layer 4314. The fourth modulation waveguide layer 4314 can be located above the third modulation waveguide layer 4313. A lower surface of the fourth modulation waveguide layer 4314 can be in contact connection with an upper surface of the third modulation waveguide layer 4313. The fourth modulation waveguide layer 4314 can be made of a P-type InGaAs material with a high doping concentration to achieve good contact with the radio frequency electrode 432.

In some embodiments, the fourth modulation waveguide layer 4314 may include a third sub-modulation waveguide layer 43141. The third sub-modulation waveguide layer 43141 can be located above the first sub-modulation waveguide layer 43131. A lower surface of the third sub-modulation waveguide layer 43141 can be in contact connection with an upper surface of the first sub-modulation waveguide layer 43131, such that the signal is transmitted via the third sub-modulation waveguide layer 43141 to the first sub-modulation waveguide layer 43131.

In some embodiments, the fourth modulation waveguide layer 4314 may include a fourth sub-modulation waveguide layer 43142. The fourth sub-modulation waveguide layer 43142 can be located above the second sub-modulation waveguide layer 43132. A lower surface of the fourth sub-modulation waveguide layer 43142 can be in contact connection with an upper surface of the second sub-modulation waveguide layer 43132, such that the signal is transmitted via the fourth sub-modulation waveguide layer 43142 to the second sub-modulation waveguide layer 43132.

There may be a gap between the third sub-modulation waveguide layer 43141 and the fourth sub-modulation waveguide layer 43142, such that the signal is transmitted to the third modulation waveguide layer 4313 via the third sub-modulation waveguide layer 43141 and the fourth sub-modulation waveguide layer 43142.

As shown in FIG. 39, a radio frequency electrode 432 can be disposed above the fourth modulation waveguide layer 4314. A lower surface of the radio frequency electrode 432 can be in contact connection with an upper surface of the third modulation waveguide layer 4313, such that the electrical signal can be transmitted via the radio frequency electrode 432 to the fourth modulation waveguide layer 4314.

Since the radio frequency electrode 432 is also a P electrode. The P electrode can be connected not only to the radio frequency pad, but also to a negative electrode of the external power supply. Therefore, the electrical signal transmitted via the radio frequency electrode 432 to the fourth modulation waveguide layer 4314 includes not only a modulated signal but also a reverse bias voltage.

In some embodiments, the first radio frequency electrode 4321 (i.e., the first P electrode) can be located above the third sub-modulation waveguide layer 43141. The first radio frequency electrode 4321 can be in contact connection with an upper surface of the third sub-modulation waveguide layer 43141, such that the radio frequency signal of the first radio frequency electrode 4321 is transmitted to the first sub-modulation waveguide layer 43131 via the third sub-modulation waveguide layer 43141.

In some embodiments, the second radio frequency electrode 4322 (i.e., the second P electrode) can be located above the fourth sub-modulation waveguide layer 43142. The second radio frequency electrode 4322 can be in contact connection with an upper surface of the fourth sub-modulation waveguide layer 43142, such that the radio frequency signal of the second radio frequency electrode 4322 is transmitted to the second sub-modulation waveguide layer 43132 via the fourth sub-modulation waveguide layer 43142.

The first P electrode and the second P electrode are respectively loaded with modulated signals. By controlling the variation of the externally applied electric field (i.e., the reverse bias voltage provided to the P electrode by the external power supply), carrier changes of the PIN junction are induced to change the refractive index of the quantum well modulation layer and cause a phase difference between the first modulation waveguide and the second modulation waveguide. The output light intensity varies with the phase difference, that is, the output light intensity is modulated by a modulated electrical signal. The modulated electrical signal is modulated into the output light intensity of the modulated optical signal, thereby achieving modulation. The first modulation waveguide is half of the InP modulation waveguide 431 where the first sub-modulation waveguide layer 43131 is located, and the second modulation waveguide is the other half of the InP modulation waveguide 431 where the second sub-modulation waveguide layer 43132 is located.

FIG. 40 shows relationship curves between quantum well absorption coefficient and wavelength according to some embodiments. In FIG. 40, the horizontal axis represents the wavelength, the vertical axis represents the absorption coefficient, the solid line represents the absorption coefficient curve at a reverse bias voltage of 0 V, and the dashed line represents the absorption coefficient curve at a reverse bias voltage of −3 V. As shown in FIG. 40, with an increase in the reverse bias voltage, the absorption coefficient of the quantum well undergoes a redshift, i.e., the absorption coefficient of the quantum well increases. As the quantum well absorption increases, the quantum well absorption loss of the PIN junction increases.

As shown in FIG. 40, the exciton absorption peak of the quantum well is at 1382 nm, and its absorption coefficient at 1550 nm is 1/cm. When the voltage increases to −3 V, its exciton absorption peak shifts to 1403 nm, and its absorption coefficient at 550 nm is 1.4/cm.

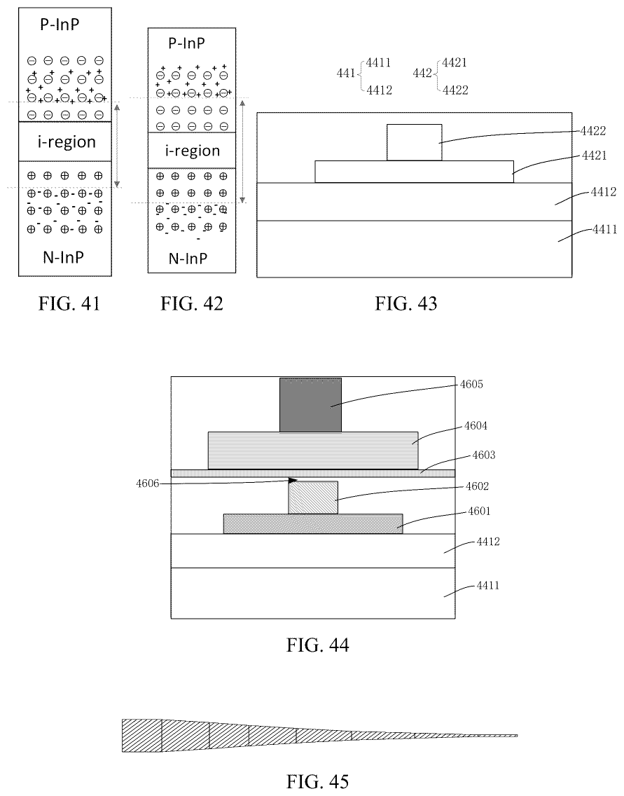

FIG. 41 shows a width of a depletion region of a PIN junction at a reverse bias voltage of 0 V according to some embodiments. FIG. 42 shows a width of a depletion region of a PIN junction at a reverse bias voltage of −3V according to some embodiments. As shown in FIG. 41 and FIG. 42, with an increase in the reverse bias voltage, the width of the depletion region increases, resulting in a decrease in carrier absorption loss of the PIN junction.

If the number of quantum wells in the second modulation waveguide layer is small, the variation of the reverse bias voltage of the external power supply has a small impact on the quantum well absorption coefficient, and there is no need to consider compensating for the increase in quantum well absorption loss. However, when the number of quantum wells increases, the variation of the reverse bias voltage of the external power supply will affect the change in the quantum well absorption coefficient, resulting in an increase in the quantum well absorption loss of the PIN junction. Excessive quantum well absorption loss will induce residual amplitude modulation that will be added to the phase modulation of the InP modulation waveguide, thereby affecting the accuracy of the phase modulation of the InP modulation waveguide. To solve this problem, in some embodiments, the decrease in carrier absorption loss is adjusted by optimizing the P-type doping concentration of the third modulation waveguide layer 4313 and the N-type doping concentration of the first modulation waveguide layer 4311 to compensate for the increase in quantum well absorption loss, thereby avoiding residual amplitude modulation and improving the accuracy of phase modulation.

Due to the same doping concentration, the absorption loss caused by P-type doping in the third modulation waveguide layer 4313 is greater than that caused by N-type doping in the first modulation waveguide layer 4311 (by approximately 10 times). Therefore, in some embodiments, the decrease in carrier absorption loss is adjusted by optimizing the P-type doping concentration of the third modulation waveguide layer 4313 to compensate for the increase in quantum well absorption loss.

If the P-type doping concentration of the third modulation waveguide layer 4313 is too low, the reverse bias voltage causes the width of the depletion region to excessively increase, such that more of the reverse bias voltage drops outside the quantum well modulation waveguide layer, thereby reducing the modulation efficiency of the InP modulation waveguide 431. If the P-type doping concentration of the third modulation waveguide layer 4313 is too high, the width of the depletion region is reduced, such that the higher the carrier absorption loss is, the higher the optical loss is. Therefore, in some embodiments, the P-type doping concentration of the third modulation waveguide layer 4313 may be within a first preset range. The first preset range may be 2-6e¹⁷ cm⁻³. By way of example, the first preset range may be 2-4e¹⁷ cm⁻³. The first preset range may be 4-6e¹⁷ cm⁻³.

In some embodiments, the range of P-type doping concentration for the first sub-modulation waveguide layer 43131 may be 2-6e¹⁷ cm⁻³.

In some embodiments, the range of P-type doping concentration for the second sub-modulation waveguide layer 43132 may be 2-6e¹⁷ cm⁻³.

If the N-type doping concentration of the first modulation waveguide layer 4311 is too low, the reverse bias voltage causes the width of the depletion region to excessively increase, such that more of the reverse bias voltage drops outside the quantum well modulation waveguide layer, thereby reducing the modulation efficiency of the InP modulation waveguide 431. If the N-type doping concentration of the first modulation waveguide layer 431 is too high, the width of the depletion region is reduced, such that the higher the carrier absorption loss is, the higher the optical loss is. Therefore, in some embodiments, the N-type doping concentration of the first modulation waveguide layer 431 may be within a second preset range. The second preset range may be 1-5e¹⁸ cm⁻³. By way of example, the second preset range may be 1-3e¹⁸ cm⁻³. The second preset range may be 3-5e¹⁸ cm⁻³.

FIG. 43 is a second cross-sectional view of a hybrid InP/Si photonic chip according to some embodiments. FIG. 43 shows a cross-sectional structure of a hybrid InP/Si photonic chip outside an InP region, with the cross section not taken through the InP region. As shown in FIG. 43, in some embodiments, the Si platform 440 may include a silicon substrate 441. The silicon substrate 441 may include a substrate layer 4411. A BOX layer 4412 can be disposed above the substrate layer 4411.

As shown in FIG. 43, a plurality of silicon waveguides can be disposed on the silicon substrate 441. The silicon waveguide can be located above the BOX layer 4412. The silicon waveguide may include an input/output waveguide 442.

The input/output waveguide 442 may include a first input/output waveguide layer 4421. The first input/output waveguide layer 4421 can be located above the BOX layer 4412.

The input/output waveguide 442 may include a second input/output waveguide layer 4422. The second input/output waveguide layer 4422 can be located above the first input/output waveguide layer 4421. The width of the second input/output waveguide layer 4422 may be less than the length of the first input/output waveguide layer 4421.

The input/output waveguide 442 includes a first input/output waveguide and a second input/output waveguide, where the first input/output waveguide and the second input/output waveguide are respectively located on both sides of the InP region. The light emitted by the light source that does not carry data is transmitted to the InP region via the first input/output waveguide. The light that does not carry data is modulated in the InP region to become data-carrying light, and the data-carrying light is transmitted out of the optical chip via the second input/output waveguide.

The first input/output waveguide is a silicon waveguide, and the first input/output waveguide and the silicon modulation waveguide are located in the same layer of the optical chip. Light can be completely transmitted from the first input/output waveguide to the silicon modulation waveguide. However, since the width of the silicon modulation waveguide is much smaller than the width of the InP modulation waveguide 431, there is a significant difference in refractive index between the InP modulation waveguide 431 and the silicon modulation waveguide, resulting in a large difference in effective refractive index between the silicon modulation waveguide and the InP modulation waveguide 431. The effective refractive indices of the silicon modulation waveguide and the InP modulation waveguide 431 differ significantly, that is, the propagation constants of the silicon modulation waveguide and the InP modulation waveguide 431 differ significantly, such that it is difficult for light to couple between the silicon modulation waveguide and the InP modulation waveguide 431, resulting in low coupling efficiency.

To solve this problem, in some embodiments, an optical coupler is disposed between the input/output waveguide and the modulation waveguide, where the optical coupler includes a silicon coupled waveguide layer and an InP coupled waveguide layer. The InP coupled waveguide layer is located above the silicon coupled waveguide layer, and both the silicon coupled waveguide layer and the InP coupled waveguide layer include tapered regions. There is an overlap region between the tapered region of the InP coupled waveguide layer and the tapered region of the silicon coupled waveguide layer. From the input/output waveguide to the modulation waveguide, the width of the tapered region of the silicon coupled waveguide layer gradually decreases, and the width of the tapered region of the InP coupled waveguide layer gradually increases. That is, the direction in which the width of the tapered region of the silicon coupled waveguide layer decreases is the same as that in which the width of the tapered region of the InP coupled waveguide layer increases.

The width and effective refractive index of the tapered region of the silicon coupled waveguide layer gradually decrease. The width and effective refractive index of the tapered region of the InP coupled waveguide layer gradually increase.

There is an overlap region between the tapered region of the indium phosphide coupled waveguide layer and the tapered region of the silicon coupled waveguide layer. The effective refractive index of the tapered region of the silicon coupled waveguide layer gradually decreases, and the effective refractive index of the tapered region of the indium phosphide coupled waveguide layer gradually increases, such that when their effective refractive indices are close, light is almost completely coupled from the silicon coupled waveguide layer to the InP coupled waveguide layer, or light is almost completely coupled from the InP coupled waveguide layer to the silicon coupled waveguide layer, thereby improving the optical coupling efficiency between the silicon coupled waveguide layer and the indium phosphide coupled waveguide layer.

However, since the effective refractive index of one gradually increases and that of the other gradually decreases, after light is coupled from the coupled waveguide layer with a gradually decreasing effective refractive index to the coupled waveguide layer with a gradually increasing effective refractive index, it will not be coupled back from the coupled waveguide layer with a gradually increasing effective refractive index to the coupled waveguide layer with a gradually decreasing effective refractive index. By way of example, the effective refractive index of the silicon coupled waveguide layer gradually decreases, and the effective refractive index of the indium phosphide coupled waveguide layer gradually increases, such that after light is coupled from the silicon coupled waveguide layer to the indium phosphide coupled waveguide layer, it will not be coupled back from the indium phosphide coupled waveguide layer to the silicon coupled waveguide layer.

For the optical coupler between the first input/output waveguide and the InP region, from the first input/output waveguide to the modulation waveguide, the effective refractive index of the tapered region of the silicon coupled waveguide layer gradually decreases, and the effective refractive index of the tapered region of the InP coupled waveguide layer gradually increases, such that when their effective refractive indices are close, light is almost completely coupled from the silicon coupled waveguide layer to the InP coupled waveguide layer, thereby improving the optical coupling efficiency between the silicon coupled waveguide layer and the indium phosphide coupled waveguide layer.

For the optical coupler between the InP region and the second input/output waveguide, from the modulation waveguide to the second input/output waveguide, the effective refractive index of the tapered region of the silicon coupled waveguide layer gradually increases, and the effective refractive index of the tapered region of the InP coupled waveguide layer gradually decreases, such that when their effective refractive indices are close, light is almost completely coupled from the InP coupled waveguide layer to the silicon coupled waveguide layer, thereby improving the optical coupling efficiency between the silicon coupled waveguide layer and the indium phosphide coupled waveguide layer.

Specifically, the optical coupler is described using the optical coupler between the first input/output waveguide and the InP region as an example.

FIG. 44 is a third cross-sectional view of a hybrid InP/Si photonic chip according to some embodiments. FIG. 44 shows a cross-sectional structure of a hybrid InP/Si photonic chip, with the cross section taken through an optical coupler. FIG. 44 shows a hybrid InP/Si photonic chip with the cross section taken through an optical coupler. As shown in FIG. 44, the optical coupler 407 can be disposed on the silicon substrate 441. The optical coupler 407 can be grown on a second BOX layer 4412 of the silicon substrate 441.

As shown in FIG. 44, in some embodiments, the optical coupler 407 may include a silicon coupled waveguide layer. One end of the silicon coupled waveguide layer can be connected to one end of the input/output waveguide 442. The other end of the silicon coupled waveguide layer can be connected to one end of the silicon modulation waveguide.

In some embodiments, the silicon coupled waveguide layer includes a first silicon coupled waveguide layer 4601. One end of the first silicon coupled waveguide layer 4601 can be connected to one end of the first input/output waveguide layer 4421. The other end of the first silicon coupled waveguide layer 4601 can be connected to a part of the silicon modulation waveguide.

In some embodiments, the silicon coupled waveguide layer includes a second silicon coupled waveguide layer 4602. One end of the second silicon coupled waveguide layer 4602 can be connected to one end of the second input/output waveguide layer 4422. The other end of the second silicon coupled waveguide layer 4602 can be connected to the other part of the silicon modulation waveguide. The second silicon coupled waveguide layer 4602 can be located above the first silicon coupled waveguide layer 4601. A lower surface of the second silicon coupled waveguide layer 4602 can be in contact connection with an upper surface of the first silicon coupled waveguide layer 4601. The width of the second silicon coupled waveguide layer 4602 is less than that of the first silicon coupled waveguide layer 4601.

In some embodiments, the width of the first silicon coupled waveguide layer 4601 may be greater than that of the second silicon coupled waveguide layer 4602.

In some embodiments, the height of the first silicon coupled waveguide layer 4601 may be less than that of the second silicon coupled waveguide layer 4602.

As shown in FIG. 44, in some embodiments, the optical coupler 407 may include an InP coupled waveguide layer. One end of the InP coupled waveguide layer can be suspended above the input/output waveguide, and the other end of the InP coupled waveguide layer can be connected to the InP modulation waveguide 431. The InP coupled waveguide layer can be located above the silicon coupled waveguide layer. The silicon coupled waveguide layer can couple light to the InP coupled waveguide layer.

In some embodiments, the InP coupled waveguide layer may include an n-InP coupled waveguide layer 4603. The n-InP coupled waveguide layer 4603 can be located above the second silicon coupled waveguide layer 4602. The n-InP coupled waveguide layer 4603 can be mainly made of an N-type doped InP material.

In some embodiments, the InP coupled waveguide layer may include a quantum well coupled waveguide layer 4604. The quantum well coupled waveguide layer 4604 can be located above the n-InP coupled waveguide layer 4603. A lower surface of the quantum well coupled waveguide layer 4604 can be in contact connection with an upper surface of the n-InP coupled waveguide layer 4603. The quantum well coupled waveguide layer 4604 can be mainly made of an InGaAsP or InAlGaAs multiple-quantum-well material.

In some embodiments, the width of the n-InP coupled waveguide layer 4603 may be greater than that of the quantum well coupled waveguide layer 4604.

In some embodiments, the height of the n-InP coupled waveguide layer 4603 may be less than that of the quantum well coupled waveguide layer 4604.

In some embodiments, the InP coupled waveguide layer may include a p-InP coupled waveguide layer 4605. The p-InP coupled waveguide layer 4605 can be located above the quantum well coupled waveguide layer 4604. A lower surface of the p-InP coupled waveguide layer 4605 can be in contact connection with an upper surface of the quantum well coupled waveguide layer 4604. The p-InP coupled waveguide layer 4605 can be mainly made of a P-type doped InP material.

In some embodiments, the width of the quantum well coupled waveguide layer 4604 may be greater than that of the p-InP coupled waveguide layer 4605.

In some embodiments, the height of the quantum well coupled waveguide layer 4604 may be less than that of the p-InP coupled waveguide layer 4605.

Due to the difference in lattice constants between the silicon coupled waveguide layer and the InP coupled waveguide layer, there is a large stress between the silicon coupled waveguide layer and the InP coupled waveguide layer. To release the stress between the silicon coupled waveguide layer and the InP coupled waveguide layer, there is a gap between the silicon coupled waveguide layer and the InP coupled waveguide layer, that is, a buffer layer 4606 is formed between the silicon coupled waveguide layer and the InP coupled waveguide layer. The buffer layer 4606 may be a SiO₂ filling layer. The buffer layer 4606 is used to release the stress between the silicon coupled waveguide layer and the InP coupled waveguide layer, thereby achieving a buffering effect.

In some embodiments, the height of the buffer layer 4606 is 10-100 nm. By way of example, the height of the buffer layer 4606 is 10-30 nm, 30-70 nm, or 70-100 nm.

The silicon coupled waveguide layer and the InP coupled waveguide layer are embedded in silicon dioxide (SiO₂), such that the silicon coupled waveguide layer and the InP coupled waveguide layer are surrounded by SiO₂.

FIG. 45 is a top view of a first silicon coupled waveguide layer according to some embodiments. As shown in FIG. 45 and Table 1, in some embodiments, the first silicon coupled waveguide layer 4601 may include a first tapered region. From the input/output waveguide to the modulation waveguide (i.e., from left to right), the width of the first tapered region may gradually decrease. The width of the first tapered region may gradually decrease, and the effective refractive index of the first tapered region may gradually increase.

As shown in FIG. 45 and Table 1, the first tapered region may include a first silicon slab taper (Si slab taper). The length of the first silicon slab taper is 12 μm. The width of the first silicon slab taper may change from 5.5 μm to 4.5 μm.

The first tapered region may include a second silicon slab taper. The length of the second silicon slab taper may be 10 μm. The width of the second silicon slab taper may change from 4.5 μm to 3.5 μm.

The first tapered region may include a third silicon slab taper. The length of the third silicon slab taper may be 12 μm. The width of the third silicon slab taper may change from 3.5 μm to 2.5 μm.

The first tapered region may include a fourth silicon slab taper. The length of the fourth silicon slab taper may be 14 μm. The width of the fourth silicon slab taper may change from 2.5 μm to 1.5 μm.

The first tapered region may include a fifth silicon slab taper. The length of the fifth silicon slab taper may be 16 μm. The width of the fifth silicon slab taper may change from 1.5 μm to 0.9 μm.

The first tapered region may include a sixth silicon slab taper. The length of the sixth silicon slab taper may be 16 μm. The width of the sixth silicon slab taper may change from 0.9 μm to 0.6 μm.

TABLE 1
is a parameter table for the silicon slab tapers.

| Si slab | | | | | | |
|---|---|---|---|---|---|---|
| tapers | Taper 1 | Taper 2 | Taper 3 | Taper 4 | Taper 5 | Taper 6 |
| Taper | 5.5 to 4.5 | 4.5 to 3.5 | 3.5 to 2.5 | 2.5 to 1.5 | 1.5 to 0.9 | 0.9 to 0.6 |
| width | | | | | | |
| (um) | | | | | | |
| Taper | 12 | 10 | 12 | 14 | 16 | 16 |
| length | | | | | | |
| (um) | | | | | | |

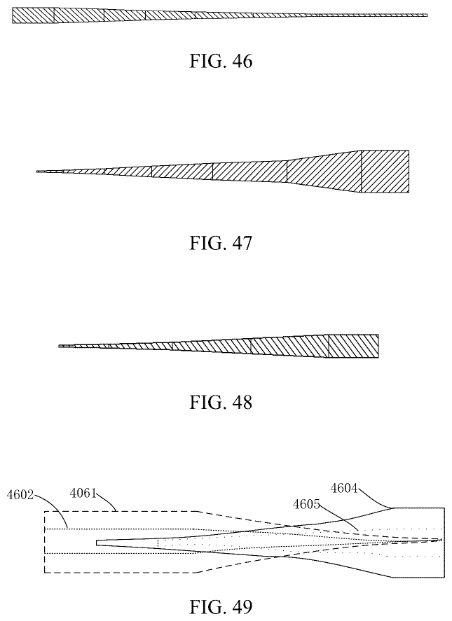

FIG. 46 is a top view of a second silicon coupled waveguide layer according to some embodiments. As shown in FIG. 46 and Table 2, the second silicon coupled waveguide layer 4602 may include a second tapered region. From the input/output waveguide to the modulation waveguide (i.e., from left to right), the width of the second tapered region gradually decreases. The width of the second tapered region gradually decreases, and the effective refractive index of the second tapered region gradually increases.

As shown in FIG. 46 and Table 2, the second tapered region may include a first silicon ridge taper (Si ridge taper). The length of the first silicon ridge taper is 12 μm. The width of the first silicon ridge taper may change from 2.0 μm to 1.6 μm.

The second tapered region may include a second silicon ridge taper. The length of the second silicon ridge taper may be 10 μm. The width of the second silicon ridge taper may change from 1.6 μm to 1.2 μm.

The second tapered region may include a third silicon ridge taper. The length of the third silicon ridge taper may be 12 μm. The width of the third silicon ridge taper may change from 1.2 μm to 0.9 μm.

The second tapered region may include a fourth silicon ridge taper. The length of the fourth silicon ridge taper may be 14 μm. The width of the fourth silicon ridge taper may change from 0.9 μm to 0.6 μm.

The second tapered region may include a fifth silicon ridge taper. The length of the fifth silicon ridge taper may be 16 μm. The width of the fifth silicon ridge taper may change from 0.6 μm to 0.3 μm.

TABLE 2
is a parameter table for the silicon ridge tapers.

| Si ridge tapers | Taper 1 | Taper 2 | Taper 3 | Taper 4 | Taper 5 |
|---|---|---|---|---|---|
| Taper width (um) | 2.0 to | 1.6 to | 1.2 to | 0.9 to | 0.6 to |
| | 1.6 | 1.2 | 0.9 | 0.6 | 0.3 |
| Taper length (um) | 12 | 10 | 12 | 14 | 16 |

FIG. 47 is a top view of a quantum well coupled waveguide layer according to some embodiments. As shown in FIG. 47 and Table 3, the quantum well coupled waveguide layer 4604 may include a third tapered region. From the input/output waveguide to the modulation waveguide (i.e., from left to right), the width of the third tapered region gradually increases. The width of the third tapered region gradually increases, and the effective refractive index of the third tapered region gradually increases.

As shown in FIG. 47 and Table 3, the third tapered region may include a first multiple-quantum-wells mesa taper (MQWs Mesa taper). The length of the first multiple-quantum-wells mesa taper is 10 μm. The width of the first multiple-quantum-wells mesa taper may change from 0.2 μm to 0.4 μm.

The third tapered region may include a second multiple-quantum-wells mesa taper. The length of the second multiple-quantum-wells mesa taper may be 15 μm. The width of the second multiple-quantum-wells mesa taper may change from 0.4 μm to 0.8 μm.

The third tapered region may include a third multiple-quantum-wells mesa taper. The length of the third multiple-quantum-wells mesa taper may be 17.5 μm. The width of the third multiple-quantum-wells mesa taper may change from 0.8 μm to 1.6 μm.

The third tapered region may include a fourth multiple-quantum-wells mesa taper. The length of the fourth multiple-quantum-wells mesa taper may be 22.5 μm. The width of the fourth multiple-quantum-wells mesa taper may change from 1.6 μm to 2.4 μm.

The third tapered region may include a fifth multiple-quantum-wells mesa taper. The length of the fifth multiple-quantum-wells mesa taper may be 27.5 μm. The width of the fifth multiple-quantum-wells mesa taper may change from 2.4 μm to 3.2 μm.

The third tapered region may include a sixth multiple-quantum-wells mesa taper. The length of the sixth multiple-quantum-wells mesa taper may be 27.5 μm. The width of the sixth multiple-quantum-wells mesa taper may change from 3.2 μm to 6.2 μm.

TABLE 3
is a parameter table for the multiple-quantum-wells mesa tapers.

| MQWs Mesa | | | | | | |
|---|---|---|---|---|---|---|
| Taper | Taper 1 | Taper 2 | Taper 3 | Taper 4 | Taper 5 | Taper 6 |
| Taper width | 0.2 to 0.4 | 0.4 to 0.8 | 0.8 to 1.6 | 1.6 to 2.4 | 2.4 to 3.2 | 3.2 to 6.2 |
| (um) | | | | | | |
| Taper length | 10 | 15 | 17.5 | 22.5 | 27.5 | 27.5 |
| (um) | | | | | | |

FIG. 48 is a top view of a p-InP coupled waveguide layer according to some embodiments. As shown in FIG. 48 and Table 4, the p-InP coupled waveguide layer 4605 may include a fourth tapered region. From the input/output waveguide to the modulation waveguide (i.e., from left to right), the width of the fourth tapered region gradually increases. The width of the fourth tapered region gradually increases, and the effective refractive index of the fourth tapered region gradually increases.

As shown in FIG. 44 and Table 4, the fourth tapered region may include a first indium phosphide ridge taper (InP ridge taper). The width of the first indium phosphide ridge taper may change from 0.2 μm to 0.4 μm.

The third tapered region may include a second indium phosphide ridge taper. The width of the second indium phosphide ridge taper may change from 0.4 μm to 0.8 μm.

The third tapered region may include a third indium phosphide ridge taper. The width of the third indium phosphide ridge taper may change from 0.8 μm to 1.6 μm.

The third tapered region may include a fourth indium phosphide ridge taper. The width of the fourth indium phosphide ridge taper may change from 1.6 μm to 2.4 μm.

TABLE 4
is a parameter table for the indium phosphide ridge tapers.

| InP ridge tapers | Taper 1 | Taper 2 | Taper 3 | Taper 4 |
|---|---|---|---|---|
| Taper width (um) | 0.2 to | 0.4 to | 0.8 to | 1.6 to |
| | 0.4 | 0.8 | 1.6 | 2.4 |
| Taper length (um) | | | | |

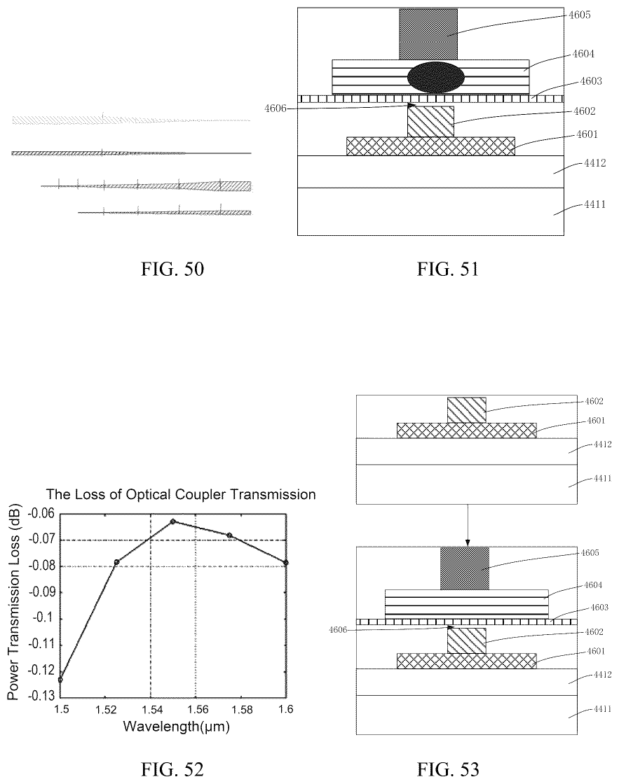

FIG. 49 is an overlap diagram of a first silicon coupled waveguide layer, a second silicon coupled waveguide layer, a quantum well coupled waveguide layer, and a p-InP coupled waveguide layer according to some embodiments. FIG. 50 is a combination diagram of a first silicon coupled waveguide layer, a second silicon coupled waveguide layer, a quantum well coupled waveguide layer, and a p-InP coupled waveguide layer according to some embodiments. As shown in FIG. 49 and FIG. 50, from left to right, the width of the tapered region of the silicon coupled waveguide layer gradually decreases, the width of the tapered region of the InP coupled waveguide layer gradually increases, and there is an overlap region between the tapered region of the silicon coupled waveguide layer and the tapered region of the InP coupled waveguide layer.

The width of the tapered region of the silicon coupled waveguide layer gradually decreases, resulting in a gradual decrease in the effective refractive index of the tapered region of the silicon coupled waveguide layer. The width of the tapered region of the InP coupled waveguide layer gradually increases, resulting in an increase in the effective refractive index of the tapered region of the InP coupled waveguide layer. The effective refractive index of the tapered region of the silicon coupled waveguide layer gradually decreases, and the effective refractive index of the tapered region of the InP coupled waveguide layer gradually increases, such that when their effective refractive indices are close, light can be coupled between the silicon coupled waveguide layer and the InP coupled waveguide layer. However, due to the increase in the effective refractive index of the InP coupled waveguide layer, after light is coupled from the silicon coupled waveguide layer to the InP coupled waveguide layer, it will not be coupled back from the InP coupled waveguide layer to the silicon coupled waveguide layer.

As shown in FIG. 49 and FIG. 50, in some embodiments, a starting point of the quantum well coupled waveguide layer and a starting point of the p-InP coupled waveguide layer may both be located above a first end of the silicon coupled waveguide layer.

As shown in FIG. 49 and FIG. 50, in some embodiments, an end point of the quantum well coupled waveguide layer and an end point of the p-InP coupled waveguide layer may both be located above a second end of the silicon coupled waveguide layer.

The starting point of the quantum well coupled waveguide layer and the starting point of the p-InP coupled waveguide layer may both be located above the first end of the silicon coupled waveguide layer, and the end point of the quantum well coupled waveguide layer and the end point of the p-InP coupled waveguide layer may both be located above the second end of the silicon coupled waveguide layer, such that there is an overlap region between the InP coupled waveguide layer and the silicon coupled waveguide layer. The width of the first end of the silicon coupled waveguide layer is greater than that of the second end of the silicon coupled waveguide layer.

As shown in FIG. 49 and FIG. 50, the directions in which the widths of the first tapered region of the first silicon coupled waveguide layer 4601 and the second tapered region of the second silicon coupled waveguide layer 4602 decrease are the same.

As shown in FIG. 49 and FIG. 50, the directions in which the widths of the third tapered region of the quantum well coupled waveguide layer 4604 and the fourth tapered region of the p-InP coupled waveguide layer 4605 increase are the same.

As shown in FIG. 49 and FIG. 50, the directions in which the widths of the first tapered region of the first silicon coupled waveguide layer 4601 and the tapered region of the second silicon coupled waveguide layer 4602 decrease are the same as those in which the widths of the third tapered region of the quantum well coupled waveguide layer 4604 and the fourth tapered region of the p-InP coupled waveguide layer 4605 increase.

Since the height of the n-InP coupled waveguide layer 4603 is much less than that of the quantum well coupled waveguide layer 4604, the shape of the n-InP coupled waveguide layer 4603 has a small impact on the optical coupling. Therefore, in some embodiments, the shape of the n-InP coupled waveguide layer 4603 is rectangular.

In some embodiments, from the input/output waveguide to the modulation waveguide, the width of the n-InP coupled waveguide layer 4603 gradually increases, such that the n-InP coupled waveguide layer 4603 is tapered in shape.

From the input/output waveguide to the modulation waveguide, the width of the n-InP coupled waveguide layer 4603 gradually increases, that is, the direction in which the width of the n-InP coupled waveguide layer 4603 increases is the same as that in which the width of the third tapered region of the quantum well coupled waveguide layer 4604 or the fourth tapered region of the p-InP coupled waveguide layer 4605 increases, such that the interface between the n-InP coupled waveguide layer 4603 and the buffer layer 4606 is an inclined plane, thereby avoiding the return of light along the original path as much as possible.

FIG. 51 is a distribution diagram of light in an optical coupler according to some embodiments. As shown in FIG. 51, after light is coupled from the silicon coupled waveguide layer to the InP coupled waveguide layer, it is mainly concentrated in the quantum well coupled waveguide layer.

FIG. 52 is a diagram of FDTD simulation results for an optical coupler according to some embodiments. In FIG. 52, the horizontal axis represents the wavelength, and the vertical axis represents the power transmission loss. As shown in FIG. 52, the optical coupler has low optical loss (i.e., power transmission loss), mainly within the range of 0.06-0.08 dB, which indicates its excellent coupling effect.

FIG. 53 is a schematic growth diagram of an optical coupler according to some embodiments. As shown in FIG. 53, the growth process for the optical coupler is as follows: (1) after the silicon substrate 441 is bonded to the strip-shaped silicon coupled waveguide layer, the first silicon coupled waveguide layer 4601 is first etched above the silicon substrate 441 by using an etching process, and then the second silicon coupled waveguide layer 4602 is etched above the first silicon coupled waveguide layer 4601 by using the etching process again; and (2) after the second silicon coupled waveguide layer 4602 is bonded to the strip-shaped indium phosphide coupled waveguide layer, the n-InP coupled waveguide layer 4603 is first etched in the second silicon coupled waveguide layer 4602 by using the etching process, then the quantum well coupled waveguide layer 4604 is etched in the n-InP coupled waveguide layer 4603 by using the etching process, and finally the p-InP coupled waveguide layer is etched above the quantum well coupled waveguide layer 4604 by using the etching process.

The above descriptions are merely specific embodiments of the present disclosure, but the scope of protection of the present disclosure is not limited thereto. Any of those skilled in the art can think of changes or substitutions within the technical scope of the present disclosure, and these changes or substitutions shall all be included within the scope of protection of the present disclosure. Therefore, the scope of protection of the present disclosure shall be subject to the scope of protection of the claims.

1. An optical module, comprising:
a circuit board; and
a hybrid integrated optical chip, electrically connected to the circuit board and configured to modulate and generate an optical signal, wherein the hybrid integrated optical chip comprises:
a Si-based platform, comprising a substrate layer, a cladding layer located above the substrate layer, and a Si waveguide layer located between the substrate layer and the cladding layer, wherein a first heating part and a second heating part are embedded in the cladding layer;
an InP light-emitting region, disposed on the Si-based platform, wherein a plurality of lasers are arranged side by side in the InP light-emitting region; the lasers each comprise an active quantum well layer and a grating layer; the active quantum well layer is configured to output light; and the grating layer is disposed on a surface of the Si waveguide layer and configured to perform wavelength selection on the light output by the active quantum well layer; and
an InP modulation region, disposed on the Si-based platform and located on a light output path of the InP light-emitting region to receive light output by the lasers, wherein a plurality of InP modulators are arranged side by side in the InP modulation region and are linear electro-optic modulators; the InP modulators are correspondingly connected to the lasers; the InP modulators each comprise a first modulation waveguide and a second modulation waveguide, wherein each of the first modulation waveguide and the second modulation waveguide is optically coupled to each of the lasers to receive the light output by each of the lasers and performs signal modulation to generate an optical signal; the first modulation waveguide is disposed adjacent to the first heating part, such that a temperature of the first modulation waveguide is regulated via the first heating part; and the second modulation waveguide is disposed adjacent to the second heating part, such that a temperature of the second modulation waveguide is regulated via the second heating part.

2. The optical module according to claim 1, wherein a refractive index of the substrate layer is greater than a refractive index of the cladding layer;
a first thermal isolation part is formed on one side of the first heating part and penetrates downward from the cladding layer to the substrate layer to reduce heat conducted downward from the first heating part to the substrate layer; and
a second thermal isolation part is formed on one side of the second heating part and penetrates downward from the cladding layer to the substrate layer to reduce heat conducted downward from the second heating part to the substrate layer.

3. The optical module according to claim 1, wherein a first thermal isolation part is formed on one side of the first heating part, and a second thermal isolation part is formed on one side of the second heating part;
the first thermal isolation part comprises a first connection slot and a second connection slot, wherein the first connection slot extends downward, and the second connection slot extends horizontally; and
the second thermal isolation part comprises a third connection slot and a fourth connection slot, wherein the third connection slot extends downward, and the fourth connection slot extends horizontally.

4. The optical module according to claim 1, wherein a first thermal isolation part is formed on one side of the first heating part, and a second thermal isolation part is formed on one side of the second heating part;
the plurality of InP modulators are arranged side by side in the InP modulation region;
the first heating part and the second heating part corresponding to the plurality of InP modulators form a heating region of the hybrid integrated optical chip;
the first thermal isolation part and the second thermal isolation part corresponding to the plurality of InP modulators form a thermal isolation region of the hybrid integrated optical chip; and
the thermal isolation region wraps around the InP modulation region, and the InP modulation region wraps around the heating region.

5. The optical module according to claim 1, wherein the first modulation waveguide and the second modulation waveguide are respectively disposed between the first heating part and the second heating part.

6. The optical module according to claim 1, wherein an optical waveguide layer is formed between the substrate layer and the cladding layer; and
the optical waveguide layer is optically coupled to the first modulation waveguide and the second modulation waveguide respectively.

7. The optical module according to claim 2, wherein the first heating part and the second heating part corresponding to the plurality of InP modulators form a heating region of the hybrid integrated optical chip;
the first thermal isolation part and the second thermal isolation part corresponding to the plurality of InP modulators form a thermal isolation region of the hybrid integrated optical chip; and
the thermal isolation region wraps around the InP modulation region, and the InP modulation region wraps around the heating region.

8. The optical module according to claim 1, wherein the lasers each comprise, from top to bottom, a first electrode metal layer, a p-InP layer, the active quantum well layer, an n-InP layer, and the grating layer; the first electrode metal layer is disposed on a surface of the cladding layer;
both ends of the n-InP layer extend beyond the active quantum well layer to respectively form second electrode metal layers on surfaces of the both ends of the n-InP layer; and
the first electrode metal layer and the second electrode metal layers respectively provide carriers to the active quantum well layer.

9. The optical module according to claim 1, wherein the lasers each comprise, from top to bottom, a first electrode metal layer, a p-InP layer, the active quantum well layer, an n-InP layer, and the grating layer;
the first modulation waveguide comprises, from top to bottom, a p-InP layer, an active quantum well layer, and an n-InP layer;
a first P-electrode metal layer is formed on a surface of the p-InP layer, and both ends of the n-InP layer extend beyond the active quantum well layer to respectively form first N-electrode metal layers on surfaces of the both ends of the n-InP layer; and
the p-InP layer of the first modulation waveguide and the p-InP layer of the laser are located in a same layer, the n-InP layer of the first modulation waveguide and the n-InP layer of the laser are located in a same layer, and the active quantum well layer of the first modulation waveguide and the active quantum well layer of the laser are located in a same layer.

10. The optical module according to claim 1, wherein a spot size converter is disposed between each of the first modulation waveguide and the second modulation waveguide, and the Si waveguide layer.

11. The optical module according to claim 1, wherein the lasers are optically connected to the InP modulators in a one-to-one correspondence.

12. The optical module according to claim 1, wherein the InP modulators are InP-based MZ modulators.

13. The optical module according to claim 1, wherein the hybrid integrated optical chip further comprises:
a demultiplexer, disposed on one side of an optical modulator and configured to respectively output two paths of light to be modulated to the optical modulator; and
a multiplexer, disposed on the other side of the optical modulator and configured to combine two paths of modulated optical signals generated by the optical modulator via modulation; and
the optical modulator, internally provided with the InP modulation region, and comprising, from bottom to top:
a silicon waveguide layer, with a silicon contraction region formed at one end facing the demultiplexer to receive the two paths of light to be modulated, and a silicon expansion region formed at the other end facing the multiplexer to couple the two paths of modulated optical signals;
an N-type InP layer, with a first InP expansion region formed at one end facing the demultiplexer to couple the two paths of light to be modulated, and a first InP contraction region formed at the other end facing the multiplexer to couple the two paths of modulated optical signals;
a quantum well layer, with a second InP expansion region formed at one end facing the demultiplexer to couple the two paths of light to be modulated, and a second InP contraction region formed at the other end facing the multiplexer to couple the two paths of modulated optical signals; and
a P-type InP layer, with a third InP expansion region formed at one end facing the demultiplexer to couple the two paths of light to be modulated, and a third InP contraction region formed at the other end facing the multiplexer to couple the two paths of modulated optical signals,
wherein the silicon contraction region, the first InP expansion region, the second InP expansion region, and the third InP expansion region that correspond to one path of light to be modulated are stacked longitudinally in sequence to couple the light to be modulated in the silicon contraction region upward to the quantum well layer for signal modulation; and
the silicon expansion region, the first InP contraction region, the second InP contraction region, and the third InP contraction region that correspond to one path of modulated optical signal are stacked longitudinally in sequence to couple the modulated optical signal generated by the quantum well layer via modulation downward to the silicon expansion region for output.

14. The optical module according to claim 13, wherein a silicon flat region is formed between the silicon contraction region and the corresponding silicon expansion region;
a first InP flat region is formed between the first InP expansion region and the corresponding first InP contraction region;
a second InP flat region is formed between the second InP expansion region and the corresponding second InP contraction region; and
a third InP flat region is formed between the third InP expansion region and the corresponding third InP contraction region,
wherein the silicon flat region, the first InP flat region, the second InP flat region, and the third InP flat region that correspond to one path of light are stacked longitudinally in sequence to perform signal modulation in the second InP flat region.

15. The optical module according to claim 13, wherein a second InP flat region is formed between the second InP expansion region and the corresponding second InP contraction region; the second InP flat region is configured to perform signal modulation;
in a direction from the demultiplexer to the multiplexer, a waveguide width of the silicon contraction region gradually narrows, and a waveguide width of each of the first InP expansion region, the second InP expansion region, and the third InP expansion region gradually widens, such that one path of light to be modulated is coupled to the corresponding silicon contraction region, sequentially coupled upward from the silicon contraction region to the corresponding first InP expansion region in the N-type InP layer and the second InP expansion region in the quantum well layer, and then transversely coupled along the second InP expansion region to the second InP flat region, and signal modulation is performed in the second InP flat region; a generated modulated optical signal is transversely coupled to the second InP contraction region; and
in a direction from the demultiplexer to the multiplexer, a waveguide width of the silicon expansion region gradually widens, and a waveguide width of each of the first InP contraction region, the second InP contraction region, and the third InP contraction region gradually narrows, such that one path of modulated optical signal is sequentially coupled downward from the second InP contraction region to the first InP contraction region in the N-type InP layer and the silicon expansion region in the silicon waveguide layer, and output along the silicon expansion region.

16. The optical module according to claim 13, wherein a laser is formed at an input of the multiplexer;
the laser comprises a silicon waveguide layer located at a bottom and an InP light-emitting region located above the silicon waveguide layer;
a grating layer is formed on an upper surface of the silicon waveguide layer; and
the InP light-emitting region comprises, from bottom to top:
an N-type InP layer;
a stress confinement layer;
an N—InP ohmic contact layer, with an N-type electrode formed on a surface;
a quantum well layer;
a P-type InP layer; and
a P—InP ohmic contact layer, with a P-type electrode formed on a surface.

17. The optical module according to claim 13, wherein a first heating part and a second heating part are respectively formed on both sides of the P-type InP layer; and
a first thermal isolation part is formed on one side of the first heating part, and a second thermal isolation part is formed on one side of the second heating part.

18. The optical module according to claim 13, wherein the silicon waveguide layer of the optical modulator sequentially comprises, from bottom to top:
a bottom silicon layer;
a buried oxide layer; and
a first silicon ridge waveguide and a second silicon ridge waveguide respectively located on both sides of an upper surface of the buried oxide layer,
wherein an input of the first silicon ridge waveguide is configured to receive one path of light to be modulated, and an output of the first silicon ridge waveguide is configured to output one path of modulated optical signal; and
an input of the second silicon ridge waveguide is configured to receive the other path of light to be modulated, and an output of the second silicon ridge waveguide is configured to output the other path of modulated optical signal.

19. The optical module according to claim 13, wherein in a direction from one end of the optical modulator to the other end, the optical modulator comprises a first tapered coupling region, an optical modulation region, and a second tapered coupling region;
the first tapered coupling region sequentially comprises, from bottom to top: the silicon contraction region, the first InP expansion region, the second InP expansion region, and the third InP expansion region;
the optical modulation region sequentially comprises, from bottom to top: a silicon flat region, a first InP flat region, a second InP flat region, and a third InP flat region; and
the second tapered coupling region sequentially comprises, from bottom to top: the silicon expansion region, the first InP contraction region, the second InP contraction region, and the third InP contraction region.

20. The optical module according to claim 13, wherein an intermediate bonding layer is formed between the silicon waveguide layer and the InP modulation region, and the intermediate bonding layer comprises a SiO₂ layer.
